(19) United States
(12) Patent Application Publication
(10) Pub. No.: US 2026/0198004 A1
(43) Pub. Date: Jul. 9, 2026

(54) THREE-DIMENSIONAL MEMORY DEVICE WITH STACKED STAIRCASE REGIONS AND METHODS FOR FORMING THE SAME

(71) Applicant: Sandisk Technologies, Inc., Milpitas, CA (US)

(72) Inventors: Shinsuke YADA, Yokkaichi (JP); Masanori TSUTSUMI, Yokkaichi (JP); Tomohiro KUBO, Yokkaichi (JP); Tomoyuki OBU, Yokkaichi (JP)

(21) Appl. No.: 19/010,801

(22) Filed: Jan. 6, 2025

(51) Int. Cl. H10B 43/27; H01L 23/00; H01L 25/00; H01L 25/065; H01L 25/18; H10B 41/10; H10B 41/27; H10B 43/10; H10B 80/00

(52) U.S. Cl. CPC H10B 43/27; H10B 41/10; H10B 41/27; H10B 43/10; H10B 80/00; H10W 90/00; H10W 80/312; H10W 80/327; H10W 90/792

(57) ABSTRACT

A device structure includes a first alternating stack of first insulating layers and first electrically conductive layers having first stepped surfaces in a contact region, a second alternating stack of second insulating layers and second electrically conductive layers having second stepped surfaces in the contact region, and a first through-stack contact via structure vertically extending through at least a portion of the second stepped surfaces and a subset of the second electrically conductive layers and contacting a sidewall of one of the first electrically conductive layers.

### FIELD

The present disclosure relates generally to the field of semiconductor devices, and particularly to a three-dimensional memory device including stacked staircase regions and through-stack contact via structures and methods for forming the same.

### BACKGROUND

A three-dimensional memory device including three-dimensional vertical NAND strings having one bit per cell is disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a device structure comprises: a first alternating stack of first insulating layers and first electrically conductive layers and having first stepped surfaces in a contact region; a second alternating stack of second insulating layers and second electrically conductive layers and having second stepped surfaces in the contact region; and a first through-stack contact via structure vertically extending through at least a portion of the second stepped surfaces and a subset of the second electrically conductive layers and contacting a sidewall of one of the first electrically conductive layers.

According to another aspect of the present disclosure, a device structure comprises: a first alternating stack of first insulating layers and first electrically conductive layers and having first stepped surfaces in a contact region; a second alternating stack of second insulating layers and second electrically conductive layers and having second stepped surfaces in the contact region; a first through-stack contact via structure vertically extending through at least a portion of the second stepped surfaces and a subset of the second electrically conductive layers and contacting of one of the first electrically conductive layers; and a second through-stack contact via structure vertically extending through at least a portion of the first stepped surfaces and a subset of the second electrically conductive layers and contacting one of the second electrically conductive layers.

According to another aspect of the present disclosure, a method of forming a device structure is provided, which comprises: forming a first alternating stack of first insulating layers and first sacrificial material layers over a substrate; forming first stepped surfaces by patterning the first alternating stack in a contact region; forming a second alternating stack of second insulating layers and second sacrificial material layers over the first alternating stack; forming second stepped surfaces by patterning the second alternating stack in the contact region such that the second stepped surfaces have an areal overlap with the first stepped surfaces in a plan view along a vertical direction; replacing the first sacrificial material layers and the second sacrificial material layers with first electrically conductive layers and second electrically conductive layers, respectively; and forming a first through-stack contact via structure, wherein the first through-stack contact via structure vertically extends at least from a first horizontal plane including a topmost surface of the second alternating stack and at least to a second horizontal plane including a bottommost surface of the first alternating stack, and contacts one of the first electrically conductive layers.

### BRIEF DESCRIPTION OF THE DRAWINGS

FIG. 1 is a vertical cross-sectional view of a first exemplary structure after formation of an insulating etch-stop layer and a first alternating stack of first insulating layers and first sacrificial material layers according to a first embodiment of the present disclosure.

FIG. 2 is a vertical cross-sectional view of the first exemplary structure after formation of first stepped surfaces according to the first embodiment of the present disclosure.

FIGS. 3A-3C are sequential vertical cross-sectional views of a region of the first stepped surfaces during local thickening of physically exposed portions of the first sacrificial material layers according to the first embodiment of the present disclosure.

FIG. 4 is a vertical cross-sectional view of the first exemplary structure after local thickening of exposed portions of the first sacrificial material layers according to the first embodiment of the present disclosure.

FIG. 5 is a vertical cross-sectional view of the first exemplary structure after formation of a first retro-stepped dielectric material portion according to the first embodiment of the present disclosure.

FIG. 6A is a vertical cross-sectional view of the first exemplary structure after formation of first-tier openings according to the first embodiment of the present disclosure. FIG. 6B is a top-down view of the first exemplary structure of FIG. 6A. The hinged vertical plane A-A′ is the cut plane of the vertical cross-sectional view of FIG. 6A.

FIG. 7 is a vertical cross-sectional view of the first exemplary structure after formation of first-tier sacrificial opening fill material portions according to the first embodiment of the present disclosure.

FIG. 8A is a vertical cross-sectional view of the first exemplary structure after formation of voids in the first-tier contact openings according to the first embodiment of the present disclosure. FIG. 8B is a top-down view of the first exemplary structure of FIG. 8A. The hinged vertical plane A-A′ is the cut plane of the vertical cross-sectional view of FIG. 8A.

FIG. 9A is a vertical cross-sectional view of the first exemplary structure after formation of first masking patterns that covers a first subset of the first-tier contact openings according to the first embodiment of the present disclosure. FIG. 9B is a top-down view of the first exemplary structure of FIG. 9A. The hinged vertical plane A-A′ is the cut plane of the vertical cross-sectional view of FIG. 9A.

FIG. 10 is a vertical cross-sectional view of the first exemplary structure after formation of a first dielectric spacer material layer according to the first embodiment of the present disclosure.

FIG. 11 is a vertical cross-sectional view of the first exemplary structure after formation of first dielectric spacers and first-tier pillar-shaped sacrificial via fill material portions according to the first embodiment of the present disclosure.

FIG. 12 is a vertical cross-sectional view of the first exemplary structure after removal of the first masking patterns and formation of voids in a second subset of the first-tier contact openings according to the first embodiment of the present disclosure.

FIG. 13 is a vertical cross-sectional view of the first exemplary structure after formation of finned first-tier contact openings according to the first embodiment of the present disclosure.

FIG. 14 is a vertical cross-sectional view of the first exemplary structure after formation of first-tier annular insulating spacers according to the first embodiment of the present disclosure.

FIG. 15 is a vertical cross-sectional view of the first exemplary structure after formation of first-tier finned sacrificial via fill material portions according to the first embodiment of the present disclosure.

FIG. 16 is a vertical cross-sectional view of the first exemplary structure after formation of a second alternating stack of second insulating layers and second sacrificial material layers and second stepped surfaces according to the first embodiment of the present disclosure.

FIG. 17 is a vertical cross-sectional view of the first exemplary structure after local thickening of physically exposed portions of the second sacrificial material layers according to the first embodiment of the present disclosure.

FIG. 18 is a vertical cross-sectional view of the first exemplary structure after formation of a second retro-stepped dielectric material portion and drain-select-level isolation structures according to the first embodiment of the present disclosure.

FIG. 19A is a vertical cross-sectional view of the first exemplary structure after formation of second-tier openings according to the first embodiment of the present disclosure. FIG. 19B is a top-down view of the first exemplary structure of FIG. 19A. The hinged vertical plane A-A′ is the cut plane of the vertical cross-sectional view of FIG. 19A.

FIG. 20 is a vertical cross-sectional view of the first exemplary structure after formation of second-tier sacrificial opening fill material portions according to the first embodiment of the present disclosure.

FIG. 21A is a vertical cross-sectional view of the first exemplary structure after formation of voids in the second-tier contact openings according to the first embodiment of the present disclosure. FIG. 21B is a top-down view of the first exemplary structure of FIG. 21A. The hinged vertical plane A-A′ is the cut plane of the vertical cross-sectional view of FIG. 21A.

FIG. 22A is a vertical cross-sectional view of the first exemplary structure after formation of second masking patterns that covers a first subset of the second-tier contact openings according to the first embodiment of the present disclosure. FIG. 22B is a top-down view of the first exemplary structure of FIG. 22A. The hinged vertical plane A-A′ is the cut plane of the vertical cross-sectional view of FIG. 22A.

FIG. 23 is a vertical cross-sectional view of the first exemplary structure after formation of second dielectric spacers according to the first embodiment of the present disclosure.

FIG. 24A is a vertical cross-sectional view of the first exemplary structure after formation of second-tier pillar-shaped sacrificial via fill material portions according to the first embodiment of the present disclosure. FIG. 24B is a top-down view of the first exemplary structure of FIG. 24A. The hinged vertical plane A-A′ is the cut plane of the vertical cross-sectional view of FIG. 24A.

FIG. 25 is a vertical cross-sectional view of the first exemplary structure after removal of the second masking patterns and formation of voids in a second subset of the second-tier contact openings according to the first embodiment of the present disclosure.

FIG. 26 is a vertical cross-sectional view of the first exemplary structure after formation of finned second-tier contact openings according to the first embodiment of the present disclosure.

FIG. 27 is a vertical cross-sectional view of the first exemplary structure after formation of second-tier annular insulating spacers according to the first embodiment of the present disclosure.

FIG. 28A is a vertical cross-sectional view of the first exemplary structure after formation of second-tier finned sacrificial via fill material portions according to the first embodiment of the present disclosure. FIG. 28B is a top-down view of the first exemplary structure of FIG. 28A. The hinged vertical plane A-A′ is the cut plane of the vertical cross-sectional view of FIG. 28A.

FIG. 29A is a vertical cross-sectional view of the first exemplary structure after formation of a patterned photoresist layer according to the first embodiment of the present disclosure. FIG. 29B is a top-down view of the first exemplary structure of FIG. 29A. The hinged vertical plane A-A′ is the cut plane of the vertical cross-sectional view of FIG. 29A.

FIG. 30 is a vertical cross-sectional view of the first exemplary structure after removal of sacrificial fill materials from support openings according to the first embodiment of the present disclosure.

FIG. 31 is a vertical cross-sectional view of the first exemplary structure after formation of support pillar structures according to the first embodiment of the present disclosure.

FIG. 32A is a vertical cross-sectional view of the first exemplary structure after formation of memory openings according to the first embodiment of the present disclosure. FIG. 32B is a top-down view of the first exemplary structure of FIG. 32A. The hinged vertical plane A-A′ is the cut plane of the vertical cross-sectional view of FIG. 32A.

FIGS. 33A-33E illustrate sequential vertical cross-sectional views of a memory opening during formation of a memory opening fill structure according to the first embodiment of the present disclosure.

FIG. 34A is a schematic vertical cross-sectional view of the first exemplary structure after formation of memory opening fill structures according to the first embodiment of the present disclosure. FIG. 34B is a top-down view of the first exemplary structure of FIG. 34A. The hinged vertical plane A-A′ is the cut plane of the vertical cross-sectional view of FIG. 34A.

FIG. 35A is a schematic vertical cross-sectional view of the first exemplary structure after formation of a contact-level dielectric layer and lateral isolation trenches according to the first embodiment of the present disclosure. FIG. 35B is a top-down view of the first exemplary structure of FIG. 35A. The hinged vertical plane A-A′ is the cut plane of the vertical cross-sectional view of FIG. 35A.

FIG. 36 is a schematic vertical cross-sectional view of the first exemplary structure after formation of laterally-extending cavities according to the first embodiment of the present disclosure.

FIG. 37A is a schematic vertical cross-sectional view of the first exemplary structure after formation of electrically conductive layers according to the first embodiment of the present disclosure. FIG. 37B is a top-down view of the first exemplary structure of FIG. 37A. The hinged vertical plane A-A′ is the cut plane of the vertical cross-sectional view of FIG. 37A.

FIG. 38 is a schematic vertical cross-sectional view of the first exemplary structure after formation of lateral isolation trench fill structures and contact through-holes according to the first embodiment of the present disclosure.

FIG. 39 is a schematic vertical cross-sectional view of the first exemplary structure after removal of sacrificial via fill material portions according to the first embodiment of the present disclosure.

FIG. 40 is a schematic vertical cross-sectional view of the first exemplary structure after formation of through-stack contact via structures according to the first embodiment of the present disclosure.

FIG. 41A is a schematic vertical cross-sectional view of the first exemplary structure after formation of drain contact via structures according to the first embodiment of the present disclosure. FIG. 41B is a top-down view of the first exemplary structure of FIG. 41A. The hinged vertical plane A-A′ is the cut plane of the vertical cross-sectional view of FIG. 41A.

FIG. 42 is a schematic vertical cross-sectional view of the first exemplary structure after formation of a memory die according to the first embodiment of the present disclosure.

FIG. 43 is a schematic vertical cross-sectional view of a logic die according to the first embodiment of the present disclosure.

FIG. 44 is a schematic vertical cross-sectional view of the first exemplary structure after bonding the logic die to the memory die according to the first embodiment of the present disclosure.

FIG. 45 is a schematic vertical cross-sectional view of the first exemplary structure after removal of the carrier substrate according to the first embodiment of the present disclosure.

FIG. 46 is a schematic vertical cross-sectional view of the first exemplary structure after formation of a source layer and a source contact structure according to the first embodiment of the present disclosure.

FIG. 47 is a vertical cross-sectional view of a second exemplary structure after formation of a first retro-stepped dielectric material portion, first-tier openings, first-tier openings, first-tier sacrificial memory opening fill structures, first-tier sacrificial opening fill structures, first-tier pillar-shaped sacrificial via fill material portions, and first-tier sacrificial support opening fill material portions according to an embodiment of the present disclosure.

FIG. 48 is a vertical cross-sectional view of the second exemplary structure after formation of additional first-tier pillar-shaped sacrificial via fill material portions according to the second embodiment of the present disclosure.

FIG. 49 is a vertical cross-sectional view of the second exemplary structure after formation of a second alternating stack of second insulating layers and second sacrificial material layers and second stepped surfaces according to the second embodiment of the present disclosure.

FIG. 50 is a vertical cross-sectional view of the second exemplary structure after local thickening of physically exposed portions of the second sacrificial material layers according to the second embodiment of the present disclosure.

FIG. 51 is a vertical cross-sectional view of the second exemplary structure after formation of a second retro-stepped dielectric material portion and drain-select-level isolation structures according to the second embodiment of the present disclosure.

FIG. 52A is a vertical cross-sectional view of the second exemplary structure after formation of second-tier openings according to the second embodiment of the present disclosure. FIG. 52B is a top-down view of the second exemplary structure of FIG. 52A. The hinged vertical plane A-A′ is the cut plane of the vertical cross-sectional view of FIG. 52A.

FIG. 53 is a vertical cross-sectional view of the second exemplary structure after formation of second-tier sacrificial opening fill material portions according to the second embodiment of the present disclosure.

FIG. 54A is a vertical cross-sectional view of the second exemplary structure after formation of voids in the second-tier contact openings according to the second embodiment of the present disclosure. FIG. 54B is a top-down view of the second exemplary structure of FIG. 54A. The hinged vertical plane A-A′ is the cut plane of the vertical cross-sectional view of FIG. 54A.

FIG. 55 is a vertical cross-sectional view of the second exemplary structure after formation of masking patterns that covers a first subset of the second-tier contact openings according to the second embodiment of the present disclosure.

FIG. 56 is a vertical cross-sectional view of the second exemplary structure after formation of second dielectric spacers according to the second embodiment of the present disclosure.

FIG. 57 is a vertical cross-sectional view of the second exemplary structure after removal of the masking patterns according to the second embodiment of the present disclosure.

FIG. 58A is a vertical cross-sectional view of the second exemplary structure after removal of the first-tier sacrificial contact opening fill material portions according to the second embodiment of the present disclosure. FIG. 58B is a top-down view of the second exemplary structure of FIG. 58A. The hinged vertical plane A-A′ is the cut plane of the vertical cross-sectional view of FIG. 58A.

FIG. 59 is a vertical cross-sectional view of the second exemplary structure after removal of fin-shaped lateral recesses according to the second embodiment of the present disclosure.

FIG. 60 is a vertical cross-sectional view of the second exemplary structure after annular insulating spacers according to the second embodiment of the present disclosure.

FIG. 61A is a vertical cross-sectional view of the second exemplary structure after formation of a masking material layer according to the second embodiment of the present disclosure. FIG. 61B is a top-down view of the second exemplary structure of FIG. 61A. The hinged vertical plane A-A′ is the cut plane of the vertical cross-sectional view of FIG. 61A.

FIG. 62A is a vertical cross-sectional view of the second exemplary structure after formation of sacrificial via fill structures according to the second embodiment of the present disclosure. FIG. 62B is a top-down view of the second exemplary structure of FIG. 62A. The hinged vertical plane A-A′ is the cut plane of the vertical cross-sectional view of FIG. 62A.

FIG. 63 is a vertical cross-sectional view of the second exemplary structure after removal of the masking material layer according to the second embodiment of the present disclosure.

FIG. 64 is a vertical cross-sectional view of the second exemplary structure after formation of support pillar structures according to the second embodiment of the present disclosure.

FIG. 65A is a vertical cross-sectional view of the second exemplary structure after formation of memory openings according to the second embodiment of the present disclosure. FIG. 65B is a top-down view of the second exemplary structure of FIG. 65A. The hinged vertical plane A-A′ is the cut plane of the vertical cross-sectional view of FIG. 65A.

FIG. 66A is a schematic vertical cross-sectional view of the second exemplary structure after formation of memory opening fill structures according to the second embodiment of the present disclosure. FIG. 66B is a top-down view of the second exemplary structure of FIG. 66A. The hinged vertical plane A-A′ is the cut plane of the vertical cross-sectional view of FIG. 66A.

FIG. 67A is a schematic vertical cross-sectional view of the second exemplary structure after formation of a contact-level dielectric layer and lateral isolation trenches according to the second embodiment of the present disclosure. FIG. 67B is a top-down view of the second exemplary structure of FIG. 67A. The hinged vertical plane A-A′ is the cut plane of the vertical cross-sectional view of FIG. 67A.

FIG. 68 is a schematic vertical cross-sectional view of the second exemplary structure after formation of laterally-extending cavities according to the second embodiment of the present disclosure.

FIG. 69A is a schematic vertical cross-sectional view of the second exemplary structure after formation of electrically conductive layers according to the second embodiment of the present disclosure. FIG. 69B is a top-down view of the second exemplary structure of FIG. 69A. The hinged vertical plane A-A′ is the cut plane of the vertical cross-sectional view of FIG. 69A.

FIG. 70 is a schematic vertical cross-sectional view of the second exemplary structure after formation of lateral isolation trench fill structures and contact through-holes according to the second embodiment of the present disclosure.

FIG. 71 is a schematic vertical cross-sectional view of the second exemplary structure after removal of the sacrificial via fill structures according to the second embodiment of the present disclosure.

FIG. 72 is a schematic vertical cross-sectional view of the second exemplary structure after removal of through-stack contact via structures according to the second embodiment of the present disclosure.

FIG. 73A is a schematic vertical cross-sectional view of the second exemplary structure after formation of drain contact via structures according to the second embodiment of the present disclosure. FIG. 73B is a top-down view of the second exemplary structure of FIG. 73A. The hinged vertical plane A-A′ is the cut plane of the vertical cross-sectional view of FIG. 73A.

FIG. 74 is a schematic vertical cross-sectional view of the second exemplary structure after formation of a memory die, bonding the memory die to a logic die, removal of the carrier substrate, and formation of a source layer and a source contact structure according to the second embodiment of the present disclosure.

### DETAILED DESCRIPTION

As discussed above, embodiments of the present disclosure are directed to a three-dimensional memory device including stacked staircase regions and through-stack contact via structures and methods for forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements. The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

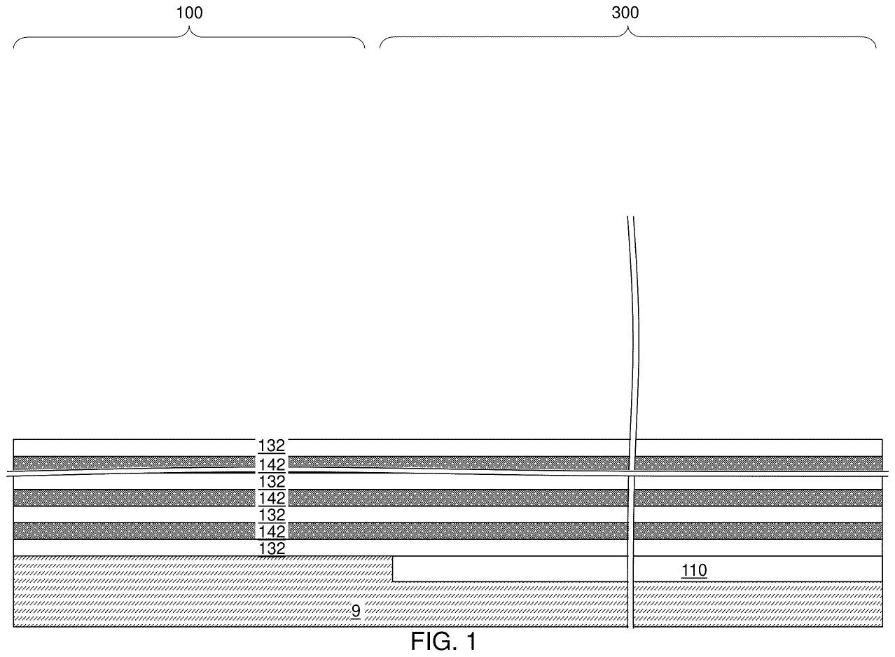

Referring to FIG. 1, a first exemplary structure is illustrated, which comprises a substrate 9, which may be a semiconductor substrate and/or a carrier substrate. For example, the substrate 9 may comprise a commercially available silicon wafer. If the substrate 9 comprises a carrier substrate, the substrate 9 may comprise any material that may be removed selectively to the materials of overlying materials which are subsequently formed. An insulating etch-stop layer 110 can be formed in a contact region 300 in or on an upper portion of the substrate 9. The insulating etch-stop layer 110 comprises an insulating material, such as silicon oxide, and may have a thickness in a range from 50 nm to 300 nm, although lesser or greater thicknesses may also be employed. In one embodiment, the insulating etch-stop layer 110 may be formed such that the top surface of the insulating etch-stop layer 110 is formed within a horizontal plane including a top surface of the substrate 9 located in a memory array region 100. The memory array region 100 is a region in which a memory array is to be subsequently formed, and the contact region 300 is a region in which contact via structures are to be subsequently formed.

A first alternating stack of first insulating layers 132 and first sacrificial material layers 142 can be formed over a substrate 9. As used herein, an alternating stack refers to a sequence of multiple instances of a first element and multiple instances of a second element that is arranged such that an instance of a second element is located between each vertically neighboring pair of instances of the first element, and an instance of a first element is located between each vertically neighboring pair of instances of the second element.

The first insulating layers 132 can be composed of the first material, and the first sacrificial material layers 142 can be composed of the second material, which is different from the first material. Each of the first insulating layers 132 is an insulating layer that continuously extends over the entire area of the substrate 8, and may have a uniform thickness throughout. Each of the first sacrificial material layers 142 includes a sacrificial material (which may comprise a dielectric material), and continuously extends over the entire area of the substrate 8, and may have a uniform thickness throughout. Insulating materials that may be used for the first insulating layers 132 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the first insulating layers 132 may be silicon oxide.

The second material of the first sacrificial material layers 142 is a dielectric material, which is a sacrificial material that may be removed selectively to the first material of the first insulating layers 132. As used herein, removal of a first material is “selective to” a second material if the removal process removes the first material at a removal rate that is at least twice the removal rate for the second material. The ratio of the rate of removal of the first material to the rate of removal of the second material is herein referred to as a “selectivity” of the removal process for the first material with respect to the second material.

The thickness of each first insulating layer 132 may be in a range from 12 nm to 50 nm, such as from 15 nm to 30 nm, although lesser and greater thicknesses may also be employed. The thickness of each first sacrificial material layer 142 may be in a range from 15 nm to 50 nm, such as from 20 nm to 30 nm, although lesser and greater thicknesses may also be employed. The second material of the first sacrificial material layers 142 may be subsequently replaced with electrically conductive electrodes which may function, for example, as control gate electrodes of a vertical NAND device. In one embodiment, the first sacrificial material layers 142 may comprise silicon nitride.

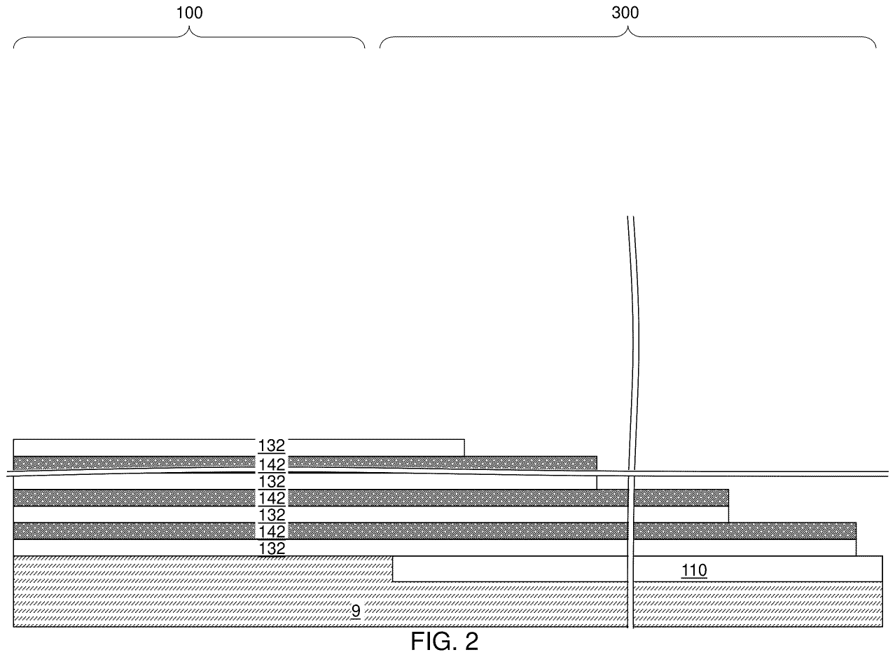

Referring to FIG. 2, first stepped surfaces can be formed in the contact region 300. The first stepped surfaces may comprise first horizontally-extending surface segments and first vertically-extending surface segments that are interconnected to each other. The first stepped surfaces may vertically extend from a bottommost surface of the first alternating stack (132, 142) to a topmost surface of the first alternating stack (132, 142).

Subsequently, physically exposed portions of the first sacrificial material layers 142 may be locally thickened. The local thickening of the physically exposed portions of the first sacrificial material layers 142 may comprise any suitable selective local thickening method for the material of the first sacrificial material layers 142.

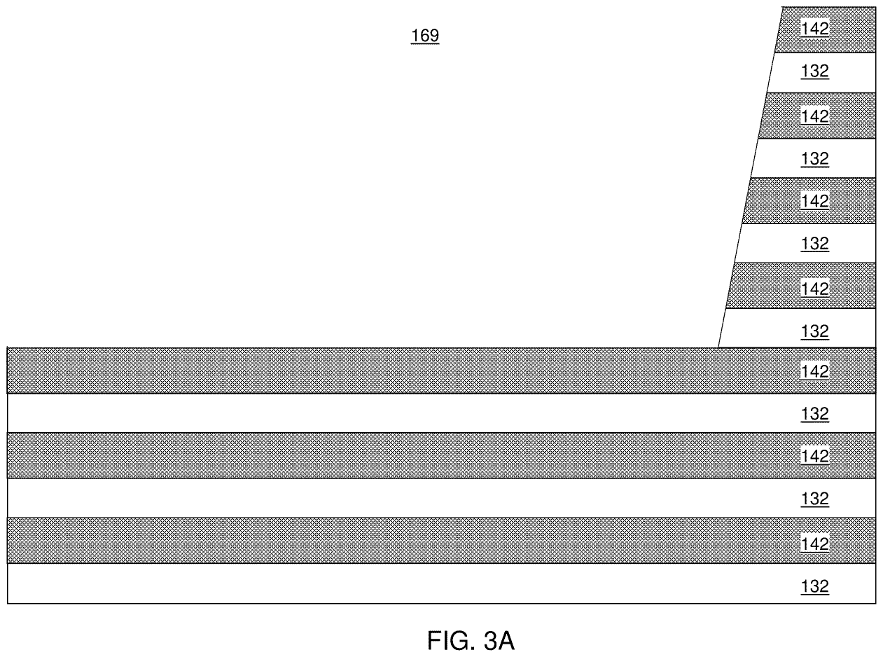

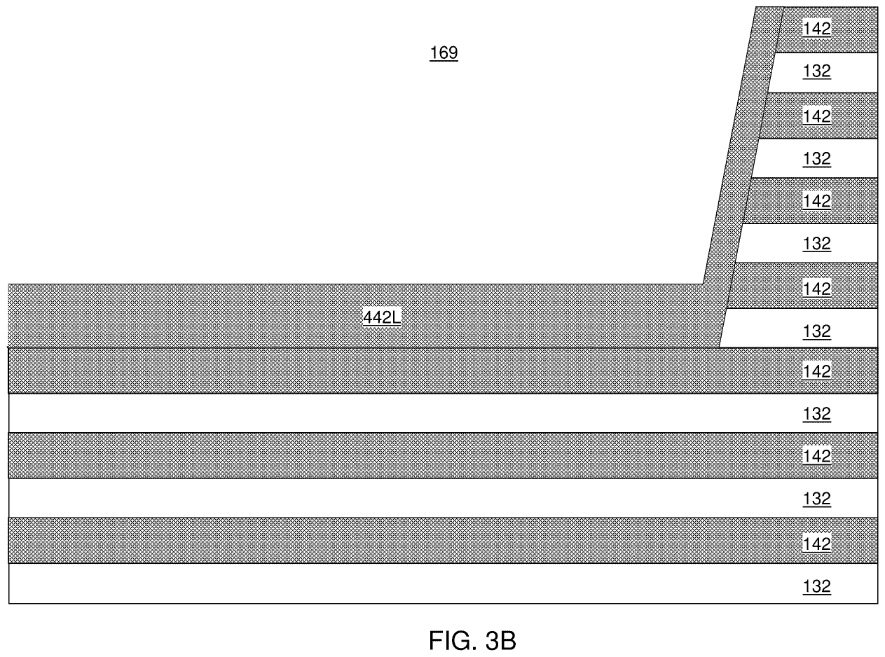

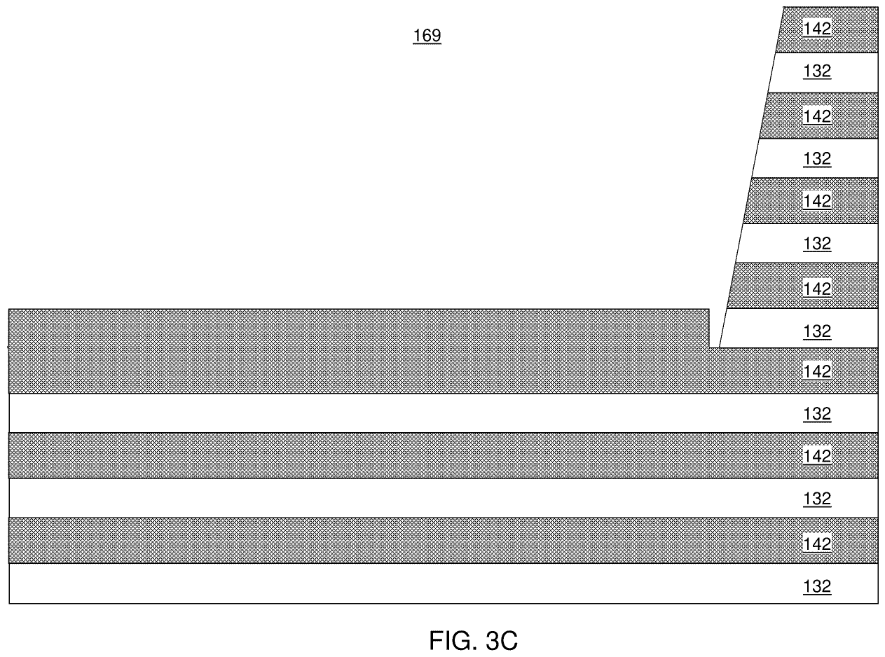

FIGS. 3A-3C are sequential vertical cross-sectional views of a region of the first stepped surfaces during local thickening of physically exposed portions of the first sacrificial material layers 142 according to the first embodiment of the present disclosure.

Referring to FIG. 3A, a region of the first stepped surfaces after the processing steps of FIG. 2 is illustrated. A first stepped cavity 169 is located over the first stepped surfaces.

Referring to FIG. 3B, an anisotropic material deposition process can be performed to anisotropically deposit a same material as the material of the first sacrificial material layers 142 to form a non-conformal sacrificial material layer 442L. In one embodiment, the first sacrificial material layers 142 comprise silicon nitride, and the anisotropic material deposition process may deposit a silicon nitride material anisotropically. The non-conformal sacrificial material layer 442L is deposited by a non-conformal deposition process such as a plasma-enhanced chemical vapor deposition (PECVD) process.

Preferably, the deposition of the sacrificial material of the non-conformal sacrificial material layer 442L is highly anisotropic such that the thickness of each horizontally-extending portion of the non-conformal sacrificial material layer 442L is greater than (e.g., at least twice) the thickness of non-horizontally-extending portions of the non-conformal sacrificial material layer 442L. In one embodiment the thickness of the horizontally-extending portions of the non-conformal sacrificial material layer 442L may be in a range from 50% to 300% of the thickness of each first sacrificial material layer 142.

Referring to FIG. 3C, an isotropic etch process can be performed to isotropically recess the non-conformal sacrificial material layer 442L. The duration of the isotropic etch process can be selected such that the non-horizontally-extending portions of the non-conformal sacrificial material layer 442L are removed by the isotropic etch process. Remaining horizontally-extending portions of the non-conformal sacrificial material layer 442L overlying a top surface segment of a respective one of the first sacrificial material layers 142 can be incorporated into the respective one of the first sacrificial material layers 142.

Thus, physically-exposed portions of the first sacrificial material layers 142 in the contact region (e.g., staircase region) 300 can be thickened, such that the thickened portions of the sacrificial material layers 142 has a thickness in a range from 125% to 250%, such as from 150% to 200%, of the unthickened portion of the first sacrificial material layers 142 (which is the same as the original thickness of each first sacrificial material layers 142). While an embodiment is described in which physically exposed portions of the first sacrificial material layers 142 are locally thickened by anisotropic deposition and isotropic etch-back of a sacrificial material, the physically exposed portions of the first sacrificial material layers 142 may be locally thickened by alternative methods that can selectively increase the thickness of physically exposed portions of the first sacrificial material layers 142. Any remaining portions of the non-conformal sacrificial material layer 442L that are located outside the areas of the first stepped cavities 169 can be removed, for example, by covering the areas of the first stepped cavities 169 with patterned photoresist materials, and by performing an etch process that etches unmasked portions of the material of the non-conformal sacrificial material layer 442L.

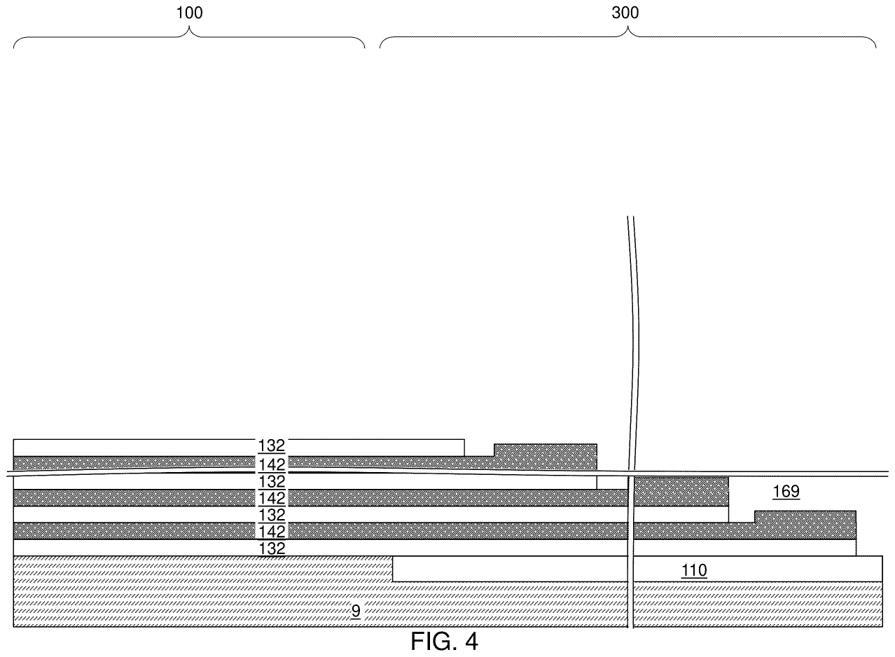

Referring to FIG. 4, the first exemplary structure is illustrated after the processing steps of FIG. 3C.

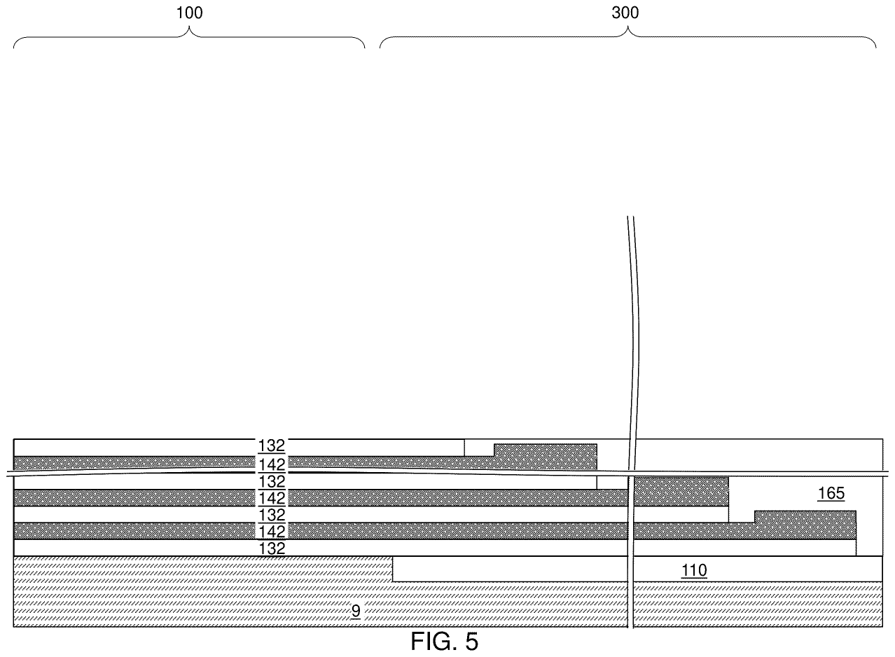

Referring to FIG. 5, a first dielectric fill material (such as undoped silicate glass (i.e., silicon oxide) or a doped silicate glass) can be deposited in the first stepped cavities 169 over the first stepped surfaces which include the surfaces of the thickened portions of the first sacrificial material layers 142. The first dielectric fill material can be planarized to remove excess portions of the first dielectric fill material from above the horizontal plane including the topmost surface of the first alternating stack (132, 142). A remaining portion of the first dielectric fill material that overlies the first stepped surfaces constitutes a first-tier retro-stepped dielectric material portion 165. Generally, the first stepped surfaces can be formed by patterning the first alternating stack (132, 142) and locally thickening the first sacrificial material layers 142 in the contact region (e.g., staircase region) 300. The first retro-stepped dielectric material portion 165 can be formed over the first stepped surfaces.

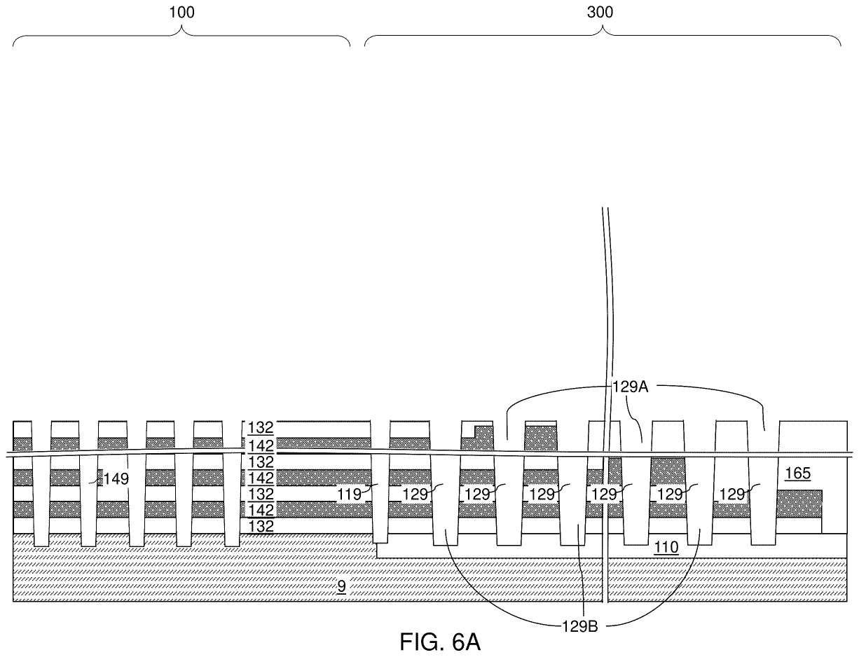

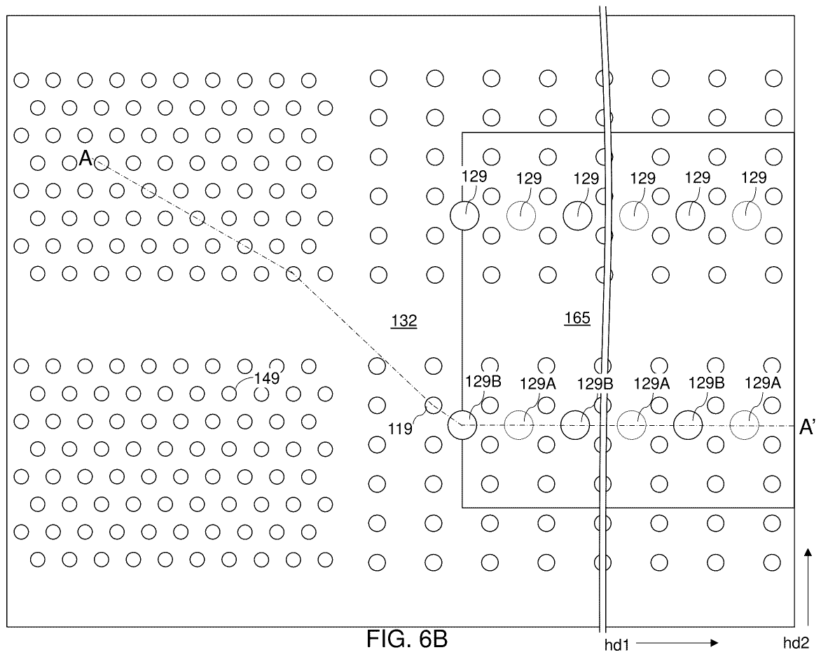

Referring to FIGS. 6A and 6B, various first-tier openings may be formed through the first alternating stack (132, 142) and into the insulating etch-stop layer 110 and the substrate 9. A photoresist layer (not shown) may be applied over the first alternating stack (132, 142), and may be lithographically patterned to form various openings therethrough. The pattern of openings in the photoresist layer may be transferred through the first alternating stack (132, 142) and into the insulating etch-stop layer 110 and the substrate 9 by a first anisotropic etch process to form the various first-tier openings concurrently. The various first-tier openings may include first-tier memory openings 149 formed in the memory array regions 100, first-tier support openings 119 formed in the contact region 300, and first-tier contact openings 129 formed in the contact region 300. Each cluster of first-tier memory openings 149 may be formed as a two-dimensional array of first-tier memory openings 149. The first-tier support openings 119 are openings that are formed in the contact region 300, and are subsequently employed to form support pillar structures. Each first-tier contact opening 129 is formed in a respective area in which a respective through-stack contact via structure is to be subsequently formed. Each first sacrificial material layer 142 may comprise a respective locally thickened portion underneath the first-tier retro-stepped dielectric material portion 165. A first subset of the first-tier contact openings 129A can be formed through a locally thickened portion of a respective first sacrificial material layer 142. A second subset of the first-tier contact openings 129B can be formed through a respective vertically-extending surface segment of the first stepped surfaces of the first alternating stack (132, 142) or through unthickened portions of the first sacrificial material layers 142.

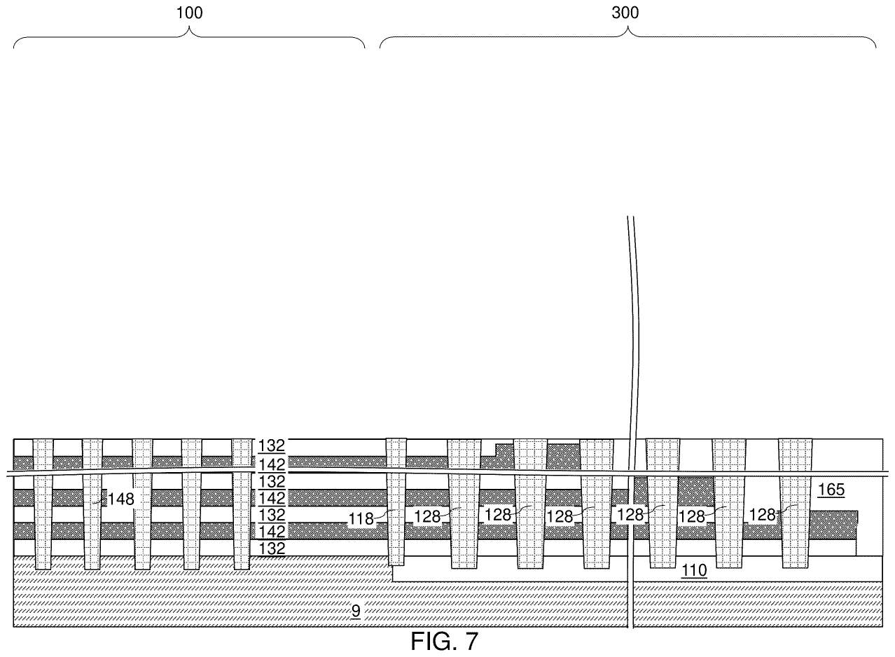

Referring to FIG. 7, a first-tier sacrificial fill material can be deposited in the first-tier openings (149, 119, 129). The first-tier sacrificial fill material includes a material that may be subsequently removed selectively to the materials of the first insulating layers 132 and the first sacrificial material layers 142. In one embodiment, the first-tier sacrificial fill material may include a semiconductor material, such as amorphous silicon, or a carbon-based material, such as amorphous carbon. Optionally, a thin etch stop liner (such as a silicon oxide layer or a silicon nitride layer having a thickness in a range from 1 nm to 3 nm) may be used prior to depositing the first-tier sacrificial fill material. The first-tier sacrificial fill material may be deposited by a non-conformal deposition or a conformal deposition method. Excess portions of the first-tier sacrificial fill material can be removed from above the horizontal plane including the topmost surface of the first alternating stack (132, 142) by performing a planarization process such as a chemical mechanical polishing process or a recess etch process.

First-tier sacrificial opening fill structures (148, 118, 128) may be formed in the various first-tier openings (149, 119, 129). The first-tier sacrificial opening fill structures (148, 118, 128) may comprise first-tier sacrificial memory opening fill structures 148, first-tier sacrificial support opening fill structures 118, and first-tier sacrificial contact opening fill structures 128.

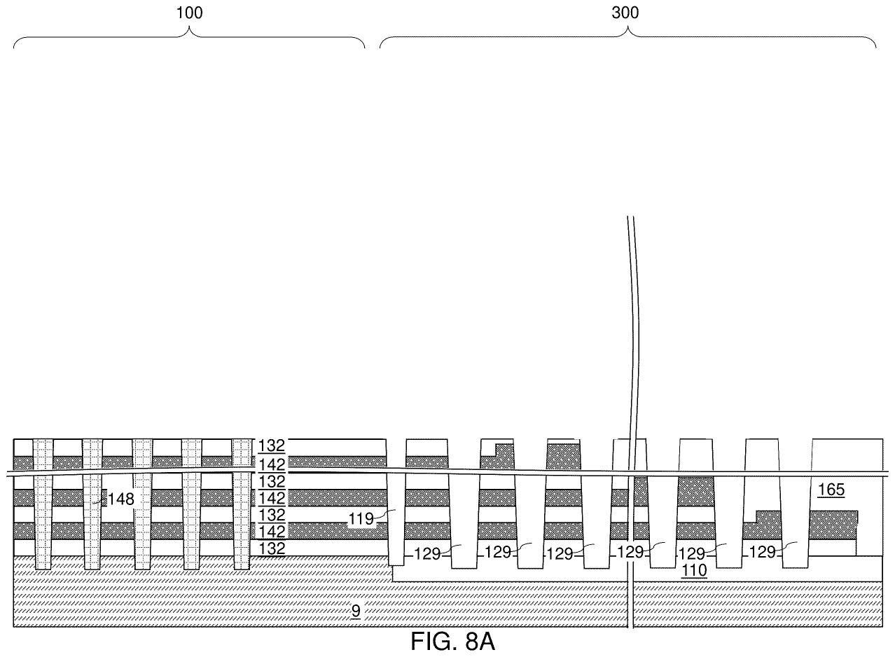

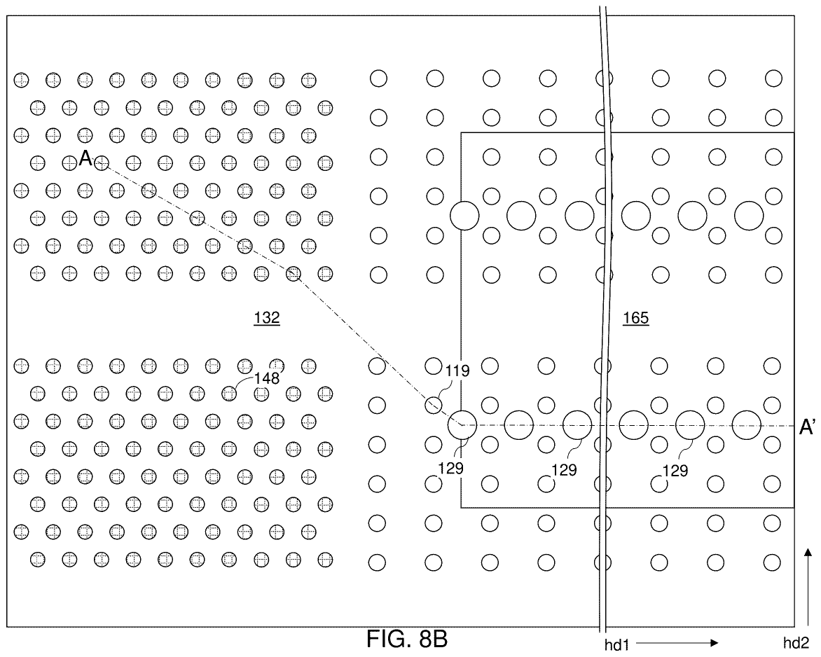

Referring to FIGS. 8A and 8B, an etch mask layer (not shown) such as a photoresist layer can be applied over the first exemplary structure, and can be patterned to cover the memory array region 100 without covering the contact region 300. The first-tier sacrificial support opening fill structures 118 and first-tier sacrificial contact opening fill structures 128 can be removed without removing the first-tier sacrificial memory opening fill structures 148. The etch mask layer can be subsequently removed. First-tier voids are formed in the volumes from which the first-tier sacrificial support opening fill structures 118 and first-tier sacrificial contact opening fill structures 128 are removed.

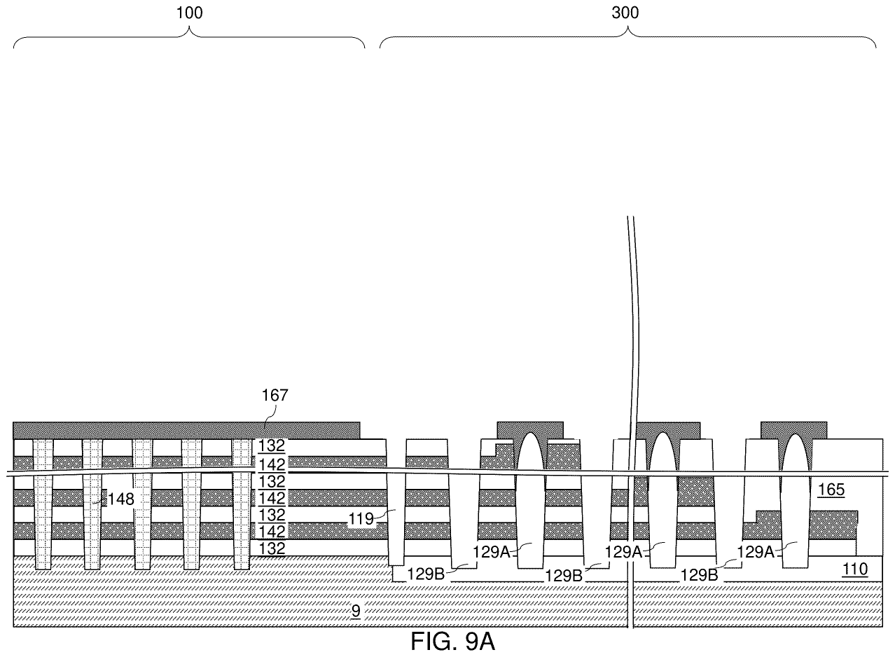

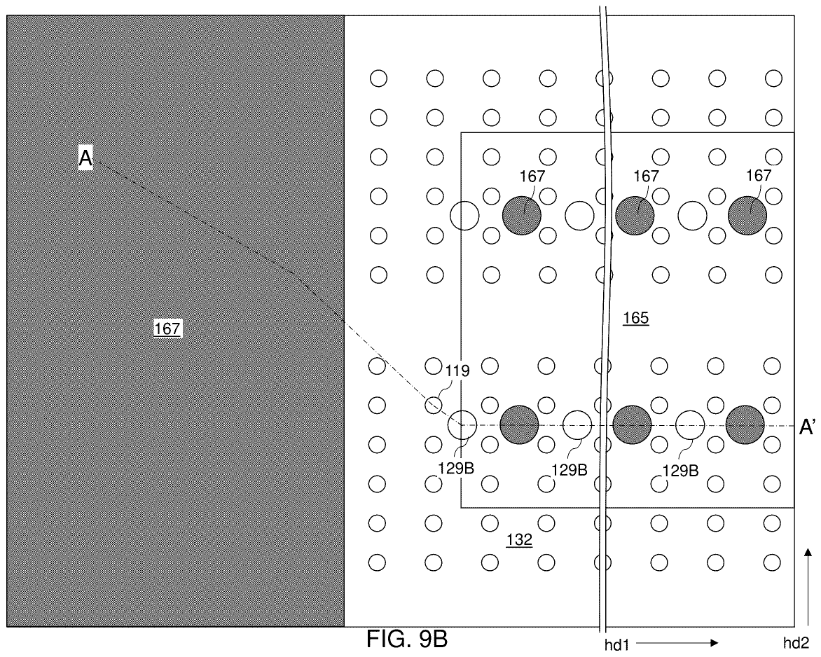

Referring to FIGS. 9A and 9B, first masking patterns 167 can be formed, for example, by anisotropically depositing a masking material, and by patterning the deposited masking material. The masking material may comprise a hard mask material that may be subsequently removed selectively to the materials of the first insulating layers 132 and the first retro-stepped dielectric material portion 165. For example, the masking material may comprise silicon nitride. The anisotropic deposition process that deposits the masking material may comprise a directional deposition process, such as a plasma-enhanced chemical vapor deposition process. The masking material may be patterned, for example, by applying and patterning a photoresist layer over the masking material, and by performing an anisotropic etch process that etches unmasked portions of the masking material. The first masking patterns 167 may cover the entirety of the memory array region 100 and a first subset of the first-tier contact openings 129A, without covering a second subset of the first-tier contact openings 129B or the first-tier support openings 119. The first subset of the first-tier contact openings 129A may vertically extend through a center region of the thickened portion of a respective first sacrificial material layer 142. The second subset of the first-tier contact openings 129B may vertically extend through a respective vertically-extending surface segment of the first stepped surfaces such as segments of sidewalls of the first insulating layer 132 in contact with the first retro-stepped dielectric material portion 165 and/or through unthickened portions of the first sacrificial material layers.

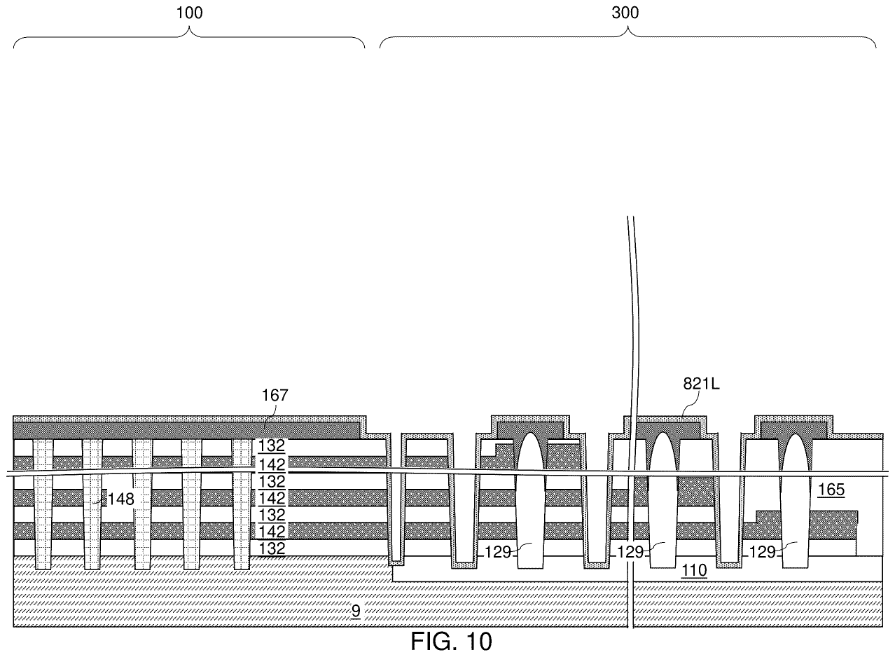

Referring to FIG. 10, a first dielectric spacer material layer 821L can be conformally deposited in peripheral regions of the second subset of the first-tier contact openings 129 and the first-tier support openings 119 and over the first masking patterns 167. The first dielectric spacer material layer 821L comprises a dielectric material that is different from the material of the first sacrificial material layers 142. In one embodiment, the first dielectric spacer material layer 821L comprises silicon oxide. The thickness of the first dielectric spacer material layer 821L may be in a range from 5 nm to 30 nm, such as from 10 nm to 20 nm, although lesser or greater thicknesses may also be employed.

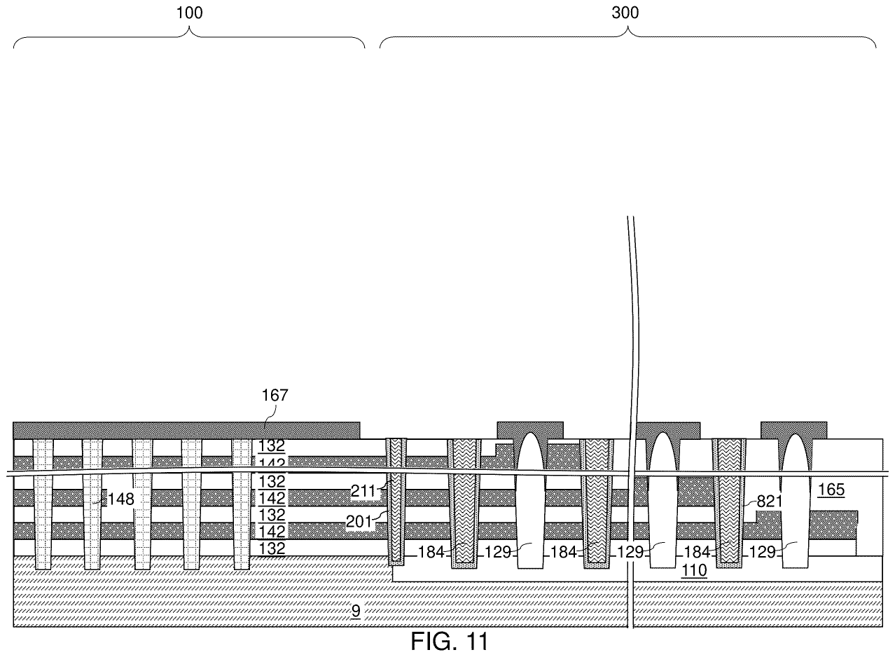

Referring to FIG. 11, a first sacrificial via fill material can be deposited in the remaining volumes of the second subset of the first-tier contact openings 129 and the first-tier support openings 119 and over the first dielectric spacer material layer 821L. The first sacrificial via fill material comprises a material that may be subsequently removed selectively to the material of the first dielectric spacer material layer 821L and the first insulating layers 132. For example, the first sacrificial via fill material may comprise amorphous silicon or polysilicon. Excess portions of the first sacrificial via fill material and portions of the first dielectric spacer material layer 821L may be removed from above the horizontal plane including the topmost surface of the first alternating stack (132, 142) by performing a recess etch process. Remaining portions of the first dielectric spacer material layer 821L that are formed in peripheral regions of the second subset of the first-tier contact openings 129B comprise first-tier contact opening dielectric spacers 821. Remaining portions of the first sacrificial via fill material that fill the second subset of the first-tier contact openings 129B comprise first-tier pillar-shaped sacrificial via fill material portions 184. Remaining portions of the first dielectric spacer material layer 821L that are formed in peripheral regions of the first-tier support openings 119 comprise first-tier support opening dielectric spacers 201. Remaining portions of the first sacrificial via fill material that fill the first-tier support openings 119 comprise first-tier sacrificial support opening fill material portions 211.

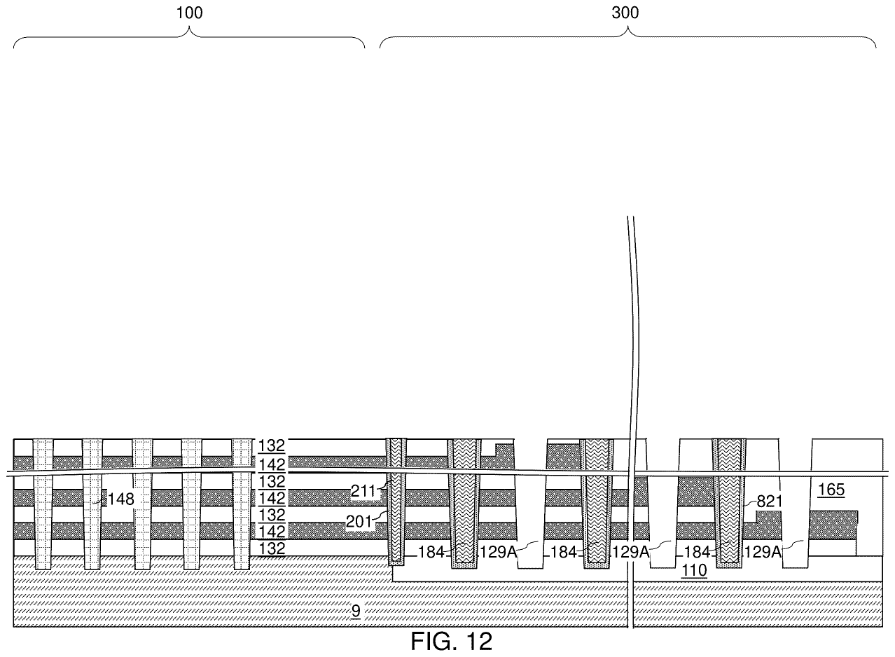

Referring to FIG. 12, an anisotropic etch process can be performed to remove the first masking patterns 167 selectively to the materials of the first insulating layers 132 and the first retro-stepped dielectric material portion 165. For example, if the first masking patterns 167 comprise silicon nitride and if the first insulating layers 132 and the first retro-stepped dielectric material portion 165 comprise silicon oxide, an anisotropic etch process that etches silicon nitride selectively to silicon oxide can be performed to remove the first masking patterns 167. The first subset of the first-tier contact openings 129A is reopened.

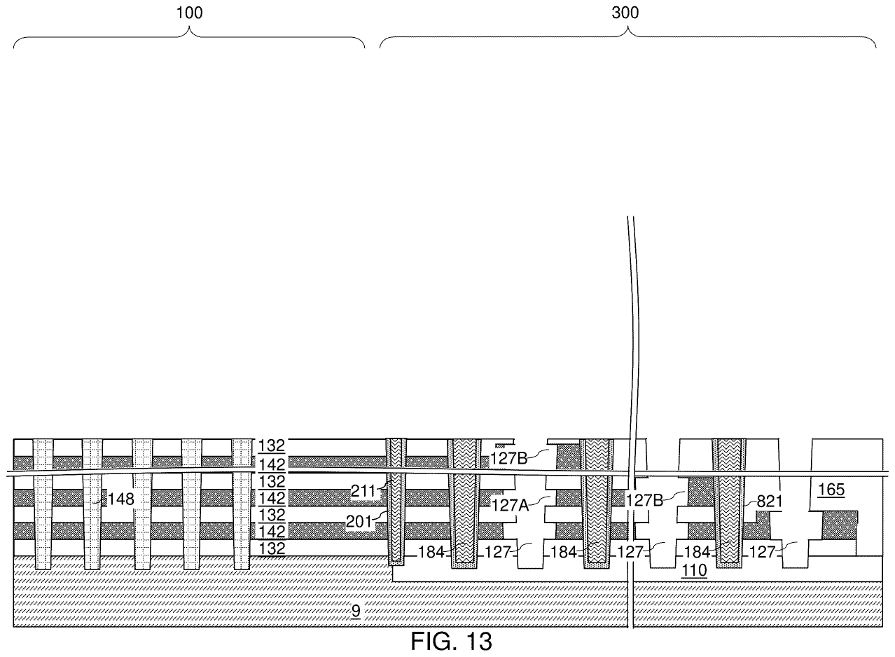

Referring to FIG. 13, an isotropic etch process can be performed to laterally recess the physically exposed sidewalls of the first sacrificial material layers 142 selectively to the materials of the first insulating layers 132 and the first retro-stepped dielectric material portion 165. Fin-shaped annular voids (127A, 127B) are formed around the first subset of the first-tier contact openings 129A. Each contiguous volume of a void including a volume of a first-tier contact opening 129 within the first subset of the first-tier contact openings 129A and at least one annular void (127A, 127B) constitutes a first-tier fin-containing void 127.

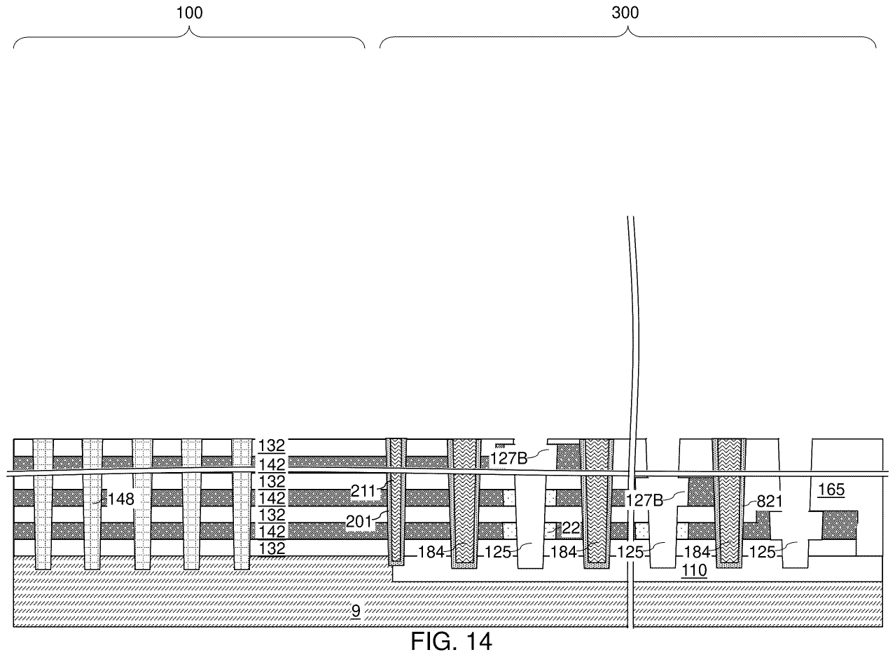

Referring to FIG. 14, a first insulating spacer material layer, such as a silicon oxide layer, can be conformally deposited in peripheral regions of the first-tier fin-containing voids 127 and in the annular voids (127A, 127B). The thickness of the first insulating spacer material layer can be greater than one half of the thickness of unthickened portions of the first sacrificial material layers 142, and is less than one half of the thickness of the thickened portions of the first sacrificial material layers 142. A first subset of shorter annular voids 127A having the same vertical extent as the unthickened portions of the first sacrificial material layers 142 is completely filled with portions of the first insulating spacer material layer, while another subset of taller annular voids 127B having the same vertical extent as the thickened portions of the first sacrificial material layers 142 is only partially filled with portions of the first insulating spacer material layer.

An isotropic recess etch process can be performed to isotropically etch portions of the first insulating spacer material layer. The duration of the isotropic recess etch process can be selected such that the etch distance of the isotropic etch process for the material of the first insulating spacer material layer is in a range from 100% to 120% of the thickness of the first insulating spacer material layers 142. Portions of first insulating spacer material layer located in the taller annular voids 127B adjacent to the thickened portions of the first sacrificial material layers 142 can be removed. Remaining portions of the first insulating spacer material layer that fill a respective shorter annular void 127A adjacent to the unthickened portions of the sacrificial material layers 142 comprise first annular insulating spacers 22. Each remaining unfilled volume of the first-tier fin-containing void 127 including the taller annular void 127B constitutes a first-tier finned contact via opening 125. At least one first annular insulating spacer 22 can be formed around the first-tier finned contact via opening 125 through the first alternating stack (132, 142).

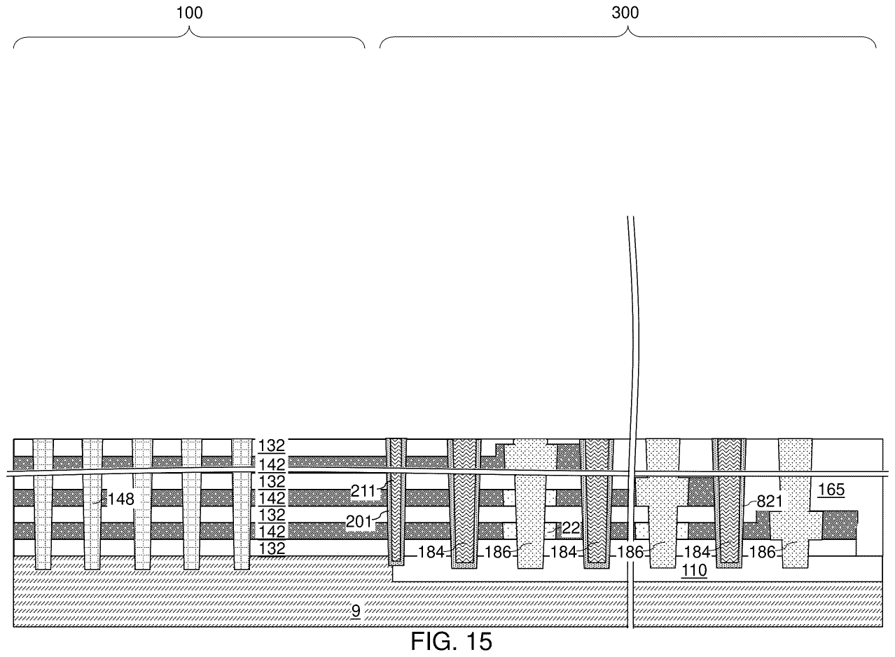

Referring to FIG. 15, a second sacrificial via fill material can be deposited in the first-tier finned contact via openings 125, which comprise remaining volumes of the first subset of the first-tier contact openings 129A. The second sacrificial via fill material comprises a material that may be subsequently removed selectively to the material of the first insulating layers 132. For example, the second sacrificial via fill material may comprise amorphous silicon or polysilicon. Excess portions of the second sacrificial via fill material may be removed from above the horizontal plane including the topmost surface of the first alternating stack (132, 142) by performing a planarization process, which may comprise a recess etch process or a chemical mechanical polishing process. Remaining portions of the second sacrificial via fill material that fill the first subset of the first-tier contact openings 129A comprise first-tier finned sacrificial via fill material portions 186. Therefore, the first subset of the first-tier contact openings 129A are filled with the first-tier finned sacrificial via fill material portions 186 and first annular insulating spacers (i.e., insulating fins) 22, while the second subset of the first-tier contact openings 129B are filled with vertical contact opening dielectric spacers 821 and first-tier pillar-shaped sacrificial via fill material portions 184. Thus, a first-tier structure is formed.

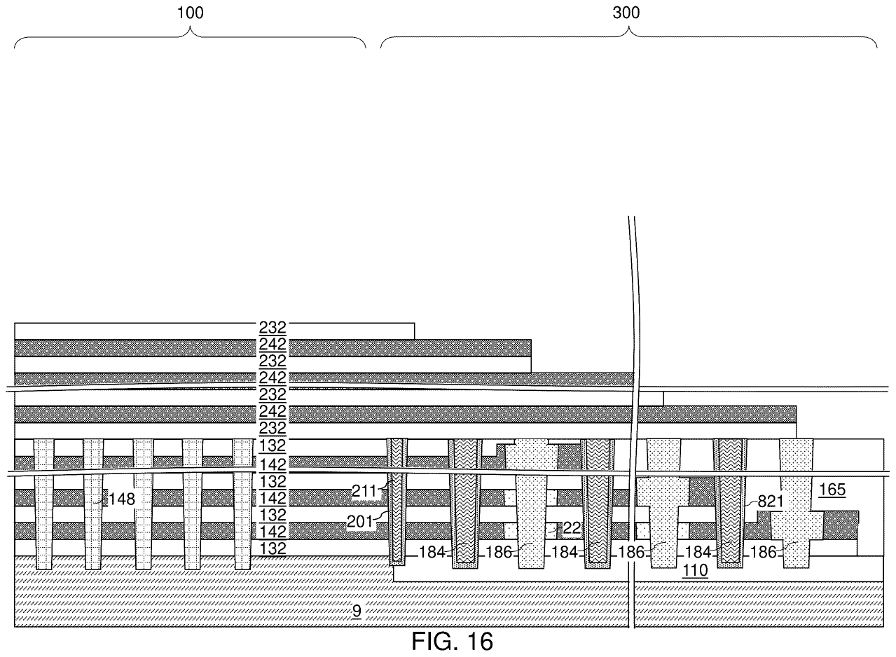

Referring to FIG. 16, a second alternating stack of second insulating layers 232 and second sacrificial material layers 242 having second stepped surfaces can be formed over the first-tier structure by performing with any needed changes the processing steps described with reference to FIGS. 1 and 2. According to an aspect of the present disclosure, the second stepped surfaces are formed in the contact region 300 in the areas overlying (i.e., overhanging) of the first stepped surfaces. The second stepped surfaces have an areal overlap with the first stepped surfaces in a plan view along a vertical direction. In other words, the areas of the horizontally-extending surface segments of the second stepped surfaces overlap with the areas of the horizontally-extending surface segments of the first stepped surfaces in the plan view. In one embodiment, the locations of the vertically-extending surfaces of the second stepped surfaces may overlap with the first-tier finned sacrificial via fill material portions 186 that are formed in the first subset of the first-tier contact openings 129A, and with the first-tier pillar-shaped sacrificial via fill material portions 184 that are formed in the second subset of the first-tier contact openings 129B.

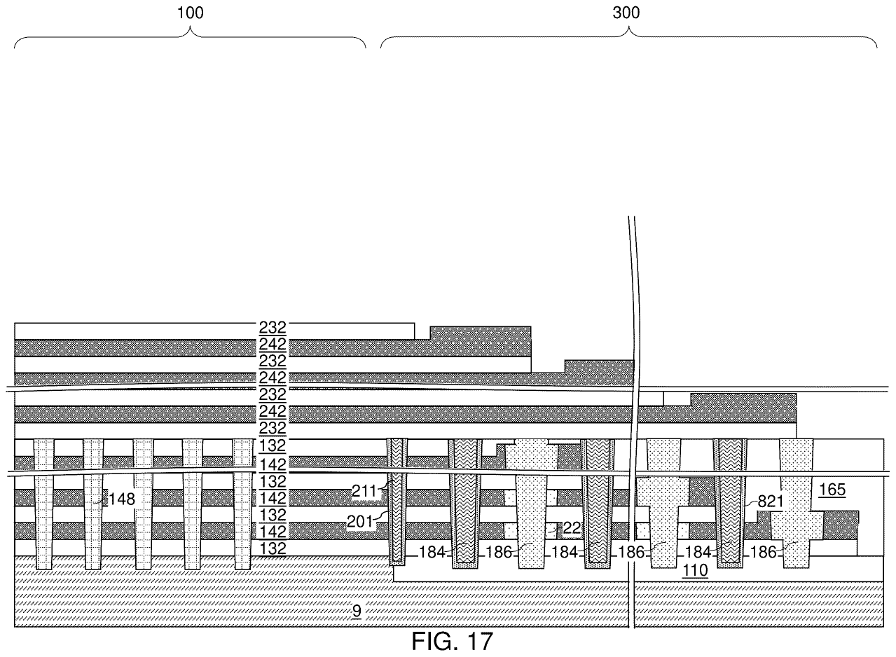

Referring to FIG. 17, the processing steps described with reference to FIGS. 3A-3C can be performed with any needed changes to locally thicken physically exposed portions of the second sacrificial material layers 242.

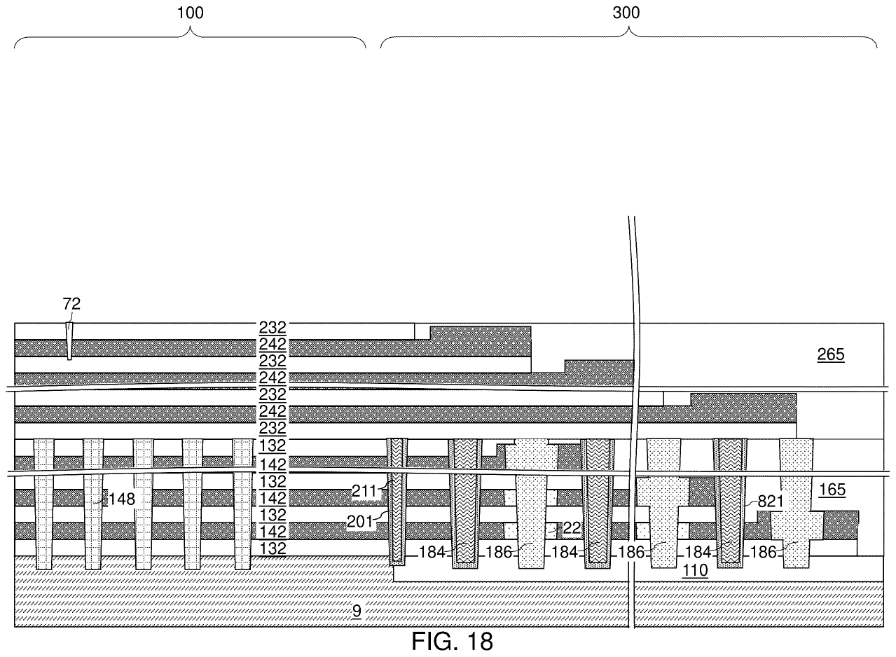

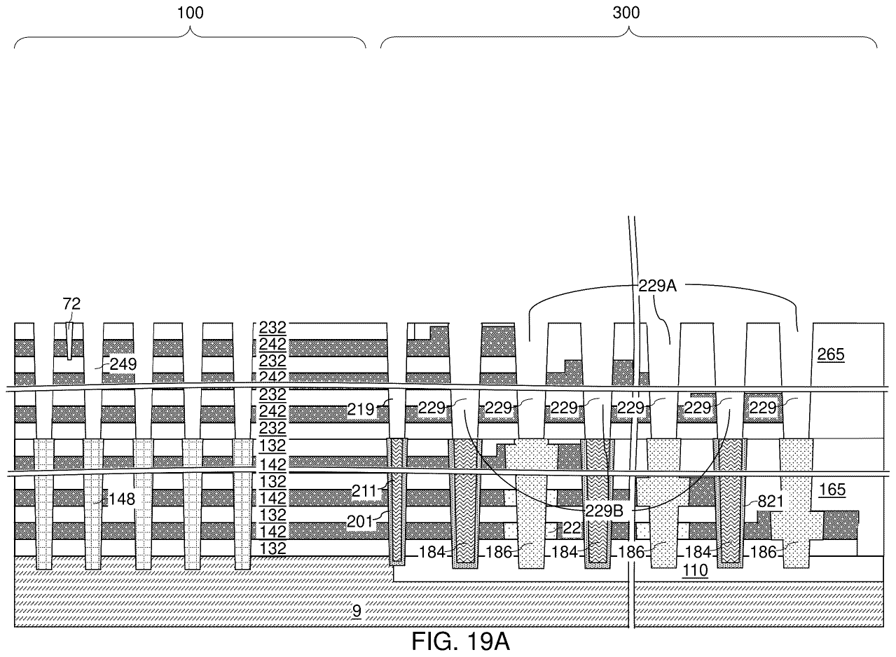

Referring to FIG. 18, the processing steps described with reference to FIG. 5 can be performed with any needed changes to form a second retro-stepped dielectric material portion 265. Optionally, drain-select-level isolation structures 72 can be formed in an upper portion of the second alternating stack (232, 242). While two tiers with two alternating stacks (132, 142) and (232, 242) are illustrated in FIG. 18, in an alternative embodiment, three or more alternating stacks may be formed over the substrate 9. In the alternative embodiment, the steps described above with reference to FIGS. 1-5 may be repeated to form additional alternating stacks over the second alternating stack (232, 242).

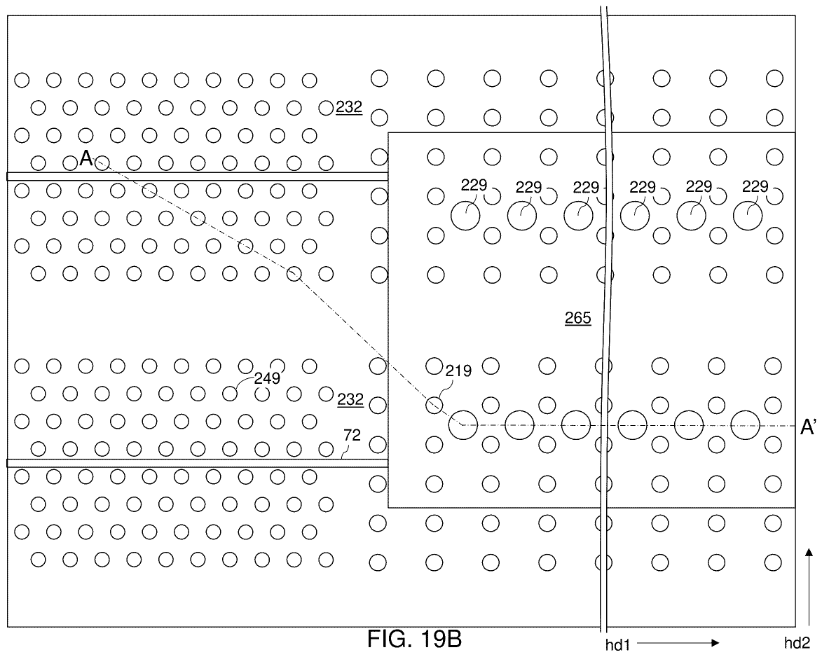

Referring to FIGS. 19A and 19B, various second-tier openings may be formed through the second alternating stack (232, 242). A photoresist layer (not shown) may be applied over the second alternating stack (232, 242), and may be lithographically patterned to form various openings therethrough. The pattern of openings in the photoresist layer may be the same as the various first-tier openings (149, 119, 129) described with reference to FIGS. 6A and 6B. The pattern of the opening in the photoresist layer can be transferred through the second alternating stack (232, 242) by a second anisotropic etch process to form the various second-tier openings concurrently. The various second-tier openings may include second-tier memory openings 249 formed in the memory array regions 100, second-tier support openings 219 formed in the contact region 300, and second-tier contact openings 229 formed in the contact region 300. Each of the second-tier memory openings 249 can be formed directly on a top surface of a first-tier sacrificial memory opening fill structure 148. Each of the second-tier support openings 219 can be formed directly on a top surface of a first-tier sacrificial support opening fill structure 118. Each of the second-tier contact opening 219 may be formed directly on a respective one of the first-tier sacrificial via fill material portions (184, 186). A first subset of the second-tier contact openings 229A may vertically extend through unthickened portions of the second sacrificial material layers 242 and/or a respective vertically-extending surface segment of the second stepped surfaces, such as segments of sidewalls of the second insulating layer 232 in contact with the second retro-stepped dielectric material portion 265. A second subset of the second-tier contact openings 229B may vertically extend through a center region of the thickened portion of a respective second sacrificial material layer 242.

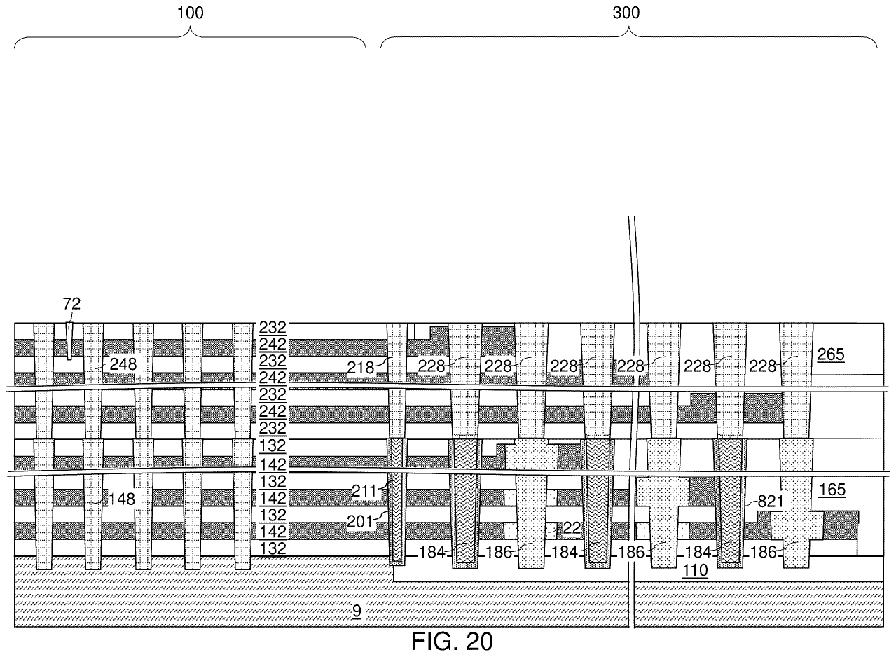

Referring to FIG. 20, a second-tier sacrificial fill material can be deposited in the second-tier openings (249, 219, 229). The second-tier sacrificial fill material includes a material that may be subsequently removed selectively to the materials of the second insulating layers 232 and the second sacrificial material layers 242. In one embodiment, the second-tier sacrificial fill material may include a semiconductor material, such as amorphous silicon, or a carbon-based material such as amorphous carbon. Optionally, a thin etch stop liner (such as a silicon oxide layer or a silicon nitride layer having a thickness in a range from 2 nm to 3 nm) may be used prior to depositing the second-tier sacrificial fill material. The second-tier sacrificial fill material may be deposited by a non-conformal deposition or a conformal deposition method. Excess portions of the second-tier sacrificial fill material can be removed from above the horizontal plane including the topmost surface of the second alternating stack (232, 242) by performing a planarization process such as a chemical mechanical polishing process or a recess etch process.

Second-tier sacrificial opening fill structures (248, 218, 228) may be formed in the various respective second-tier openings (249, 219, 229). The second-tier sacrificial opening fill structures (248, 218, 228) may comprise second-tier sacrificial memory opening fill structures 248, second-tier sacrificial support opening fill structures 218, and second-tier sacrificial contact opening fill structures 228.

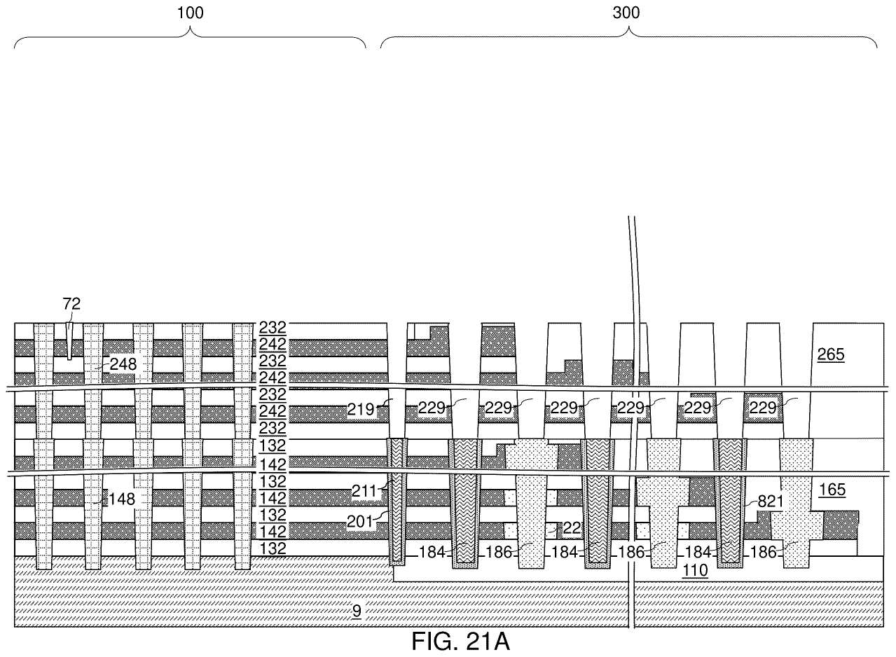

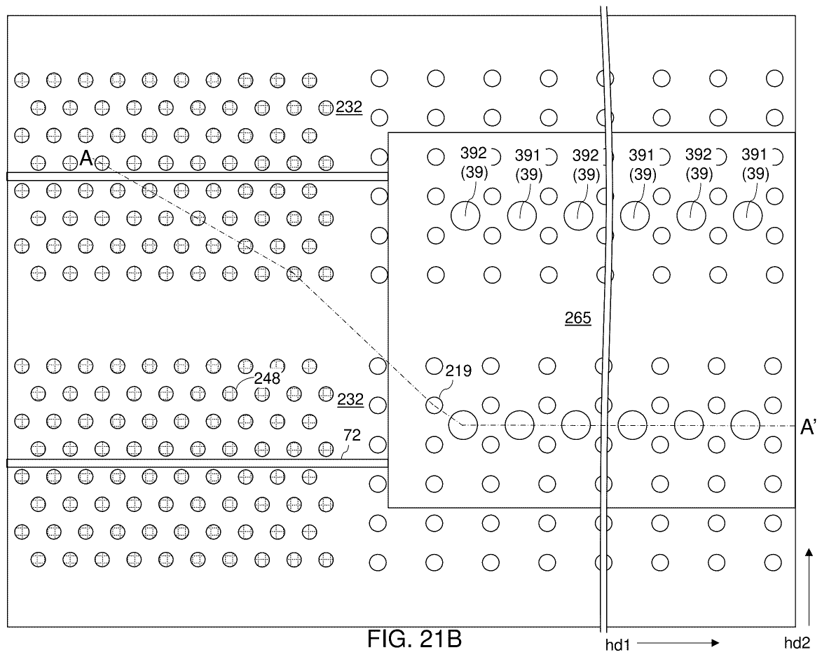

Referring to FIGS. 21A and 21B, an etch mask layer (not shown), such as a photoresist layer, can be applied over the first exemplary structure, and can be patterned to cover the memory array region 100 without covering the contact region 300. The second-tier sacrificial support opening fill structures 218 and the second-tier sacrificial contact opening fill structures 228 can be removed without removing the second-tier sacrificial memory opening fill structures 248. The etch mask layer can be subsequently removed. Second-tier voids are formed in the volumes of the various respective second-tier openings (219, 229) from which the second-tier sacrificial support opening fill structures 218 and the second-tier sacrificial contact opening fill structures 228 are removed.

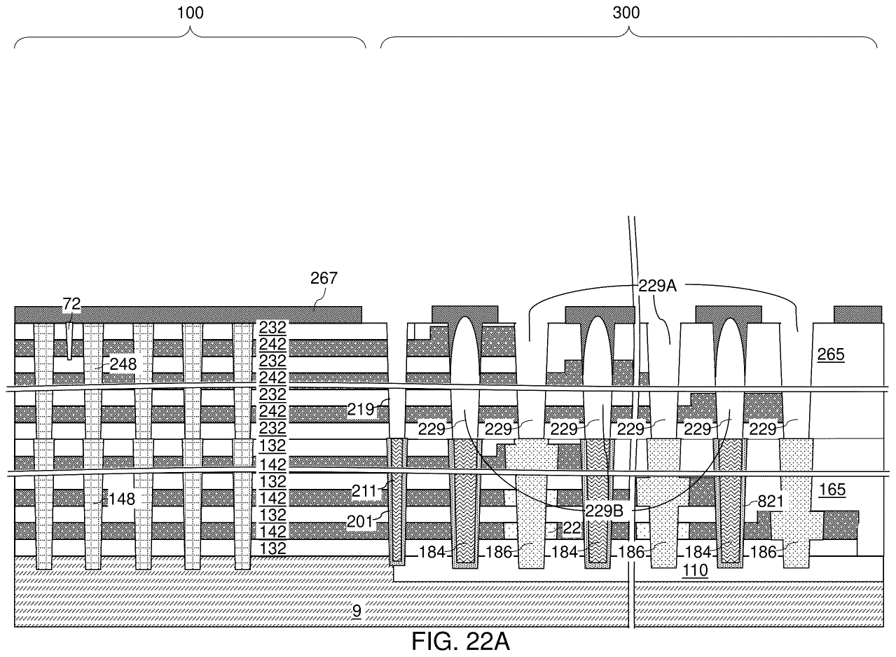

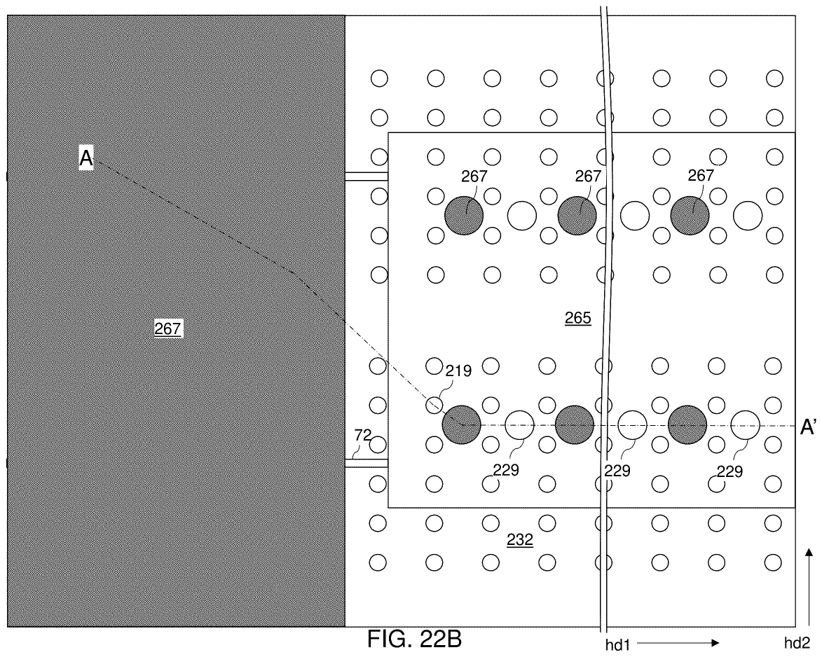

Referring to FIGS. 22A and 22B, second masking patterns 267 can be formed, for example, by anisotropically depositing a masking material, and by patterning the deposited masking material. The masking material may comprise a hard mask material that may be subsequently removed selectively to the materials of the second insulating layers 232 and the second retro-stepped dielectric material portion 265. For example, the masking material may comprise silicon nitride. The anisotropic deposition process that deposits the masking material may comprise a directional deposition process. such as a plasma-enhanced chemical vapor deposition process. The masking material may be patterned, for example, by applying and patterning a photoresist layer over the masking material, and by performing an anisotropic etch process that etches unmasked portions of the masking material. The second masking patterns 267 do not cover the second-tier support openings 219 or a first subset of the second-tier contact openings 229A that overlies a respective one of the first-tier finned sacrificial via fill material portions 186. The second masking patterns 267 cover the entirety of the memory array region 100 and a second subset of the second-tier contact openings 229B that overlie the first-tier pillar-shaped sacrificial via fill material portions 184.

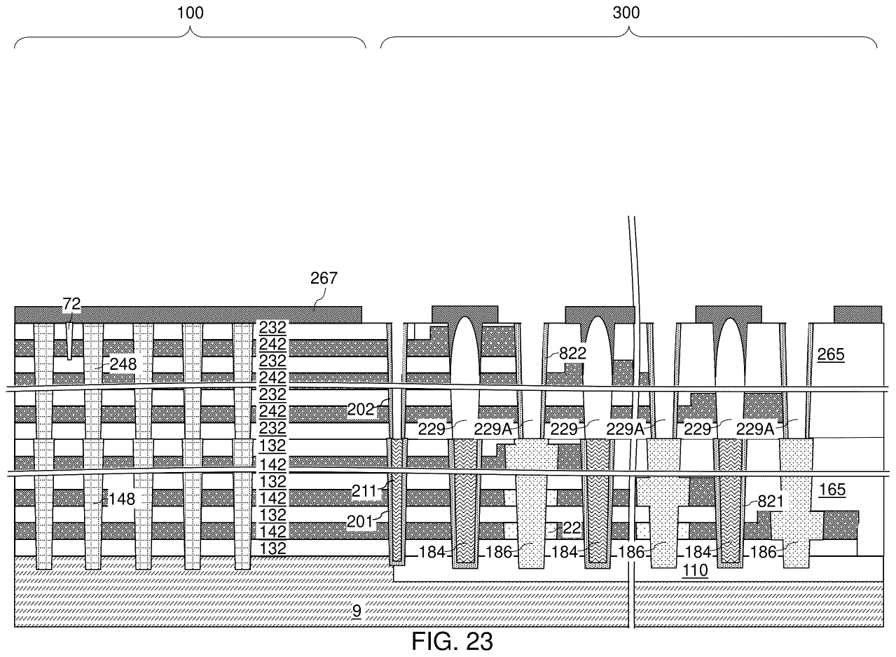

Referring to FIG. 23, a second dielectric spacer material layer can be formally deposited in peripheral regions of the first subset of the second-tier contact openings 229A and the second-tier support openings 219 and over the second masking patterns 267. The second dielectric spacer material layer comprises a dielectric material that is different from the material of the second sacrificial material layers 242. In one embodiment, the second dielectric spacer material layer comprises silicon oxide. An anisotropic etch process can be performed to remove horizontally-extending portions of the second dielectric spacer material layer. Remaining portions of the second dielectric spacer material layer that are formed in peripheral regions of the second-tier support openings 219 comprise second-tier support opening dielectric spacers 202. Remaining portions of the second dielectric spacer material layer that are formed in peripheral regions of the first subset of the second-tier contact openings 229A comprise second-tier contact opening dielectric spacers 822.

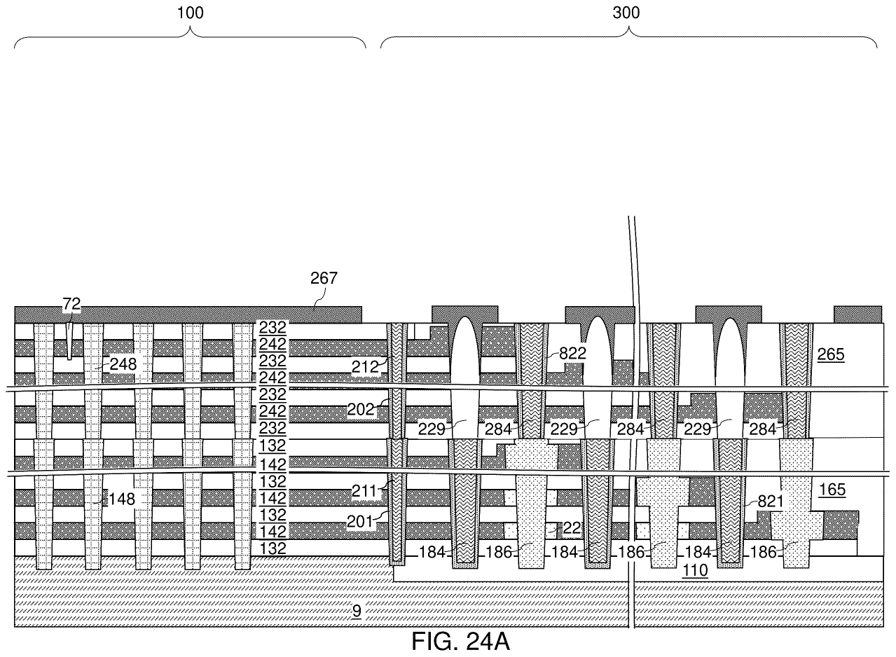

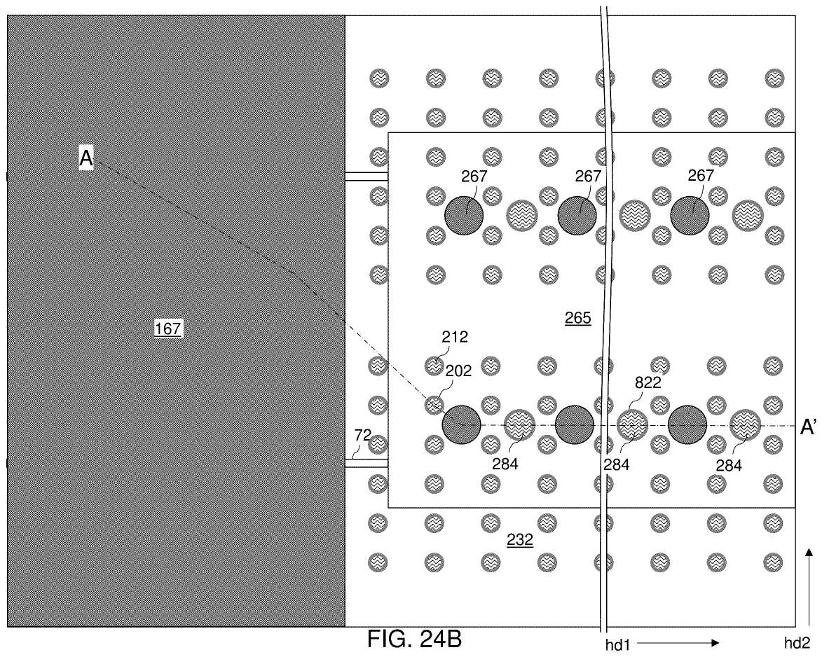

Referring to FIGS. 24A and 24B, a second sacrificial via fill material can be deposited in the remaining volumes of the first subset of the second-tier contact openings 229A and the second-tier support openings 219. The second sacrificial via fill material comprises a material that may be subsequently removed selectively to the materials of the second dielectric spacers 822 and the second insulating layers 232. For example, the second sacrificial via fill material may comprise amorphous silicon or polysilicon. Excess portions of the second sacrificial via fill material may be removed from above the horizontal plane including the topmost surface of the second alternating stack (232, 242) by performing a recess etch processes. Remaining portions of the second sacrificial via fill material that fill the first subset of the second-tier contact openings 229A comprise second-tier pillar-shaped sacrificial via fill material portions 284. Remaining portions of the second sacrificial via fill material that are located in the second-tier support openings 219 comprise second-tier sacrificial support opening fill material portions 212.

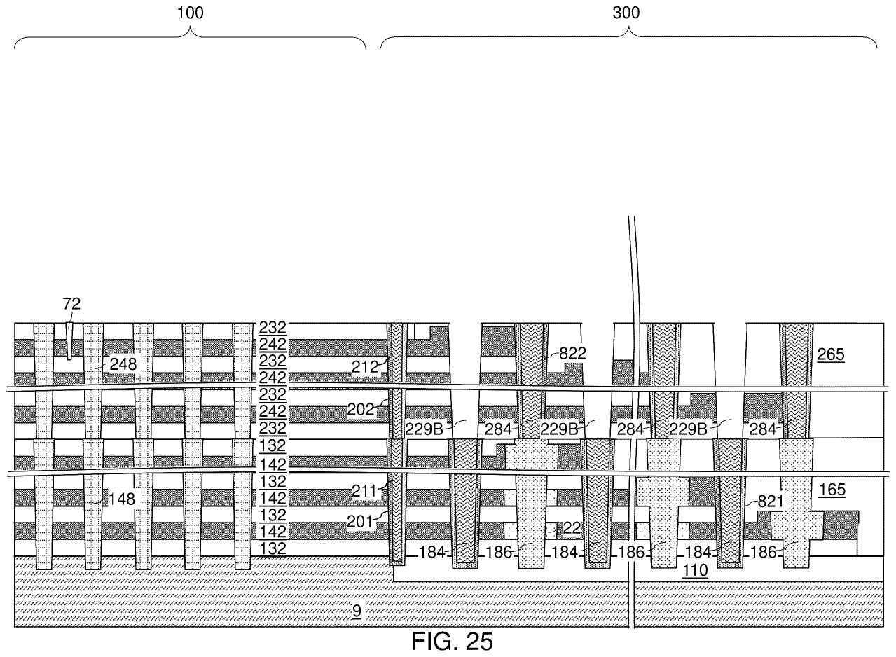

Referring to FIG. 25, an anisotropic etch process can be performed to remove the second masking patterns 267 selectively to the materials of the second insulating layers 232 and the second retro-stepped dielectric material portion 265. For example, if the second masking patterns 267 comprise silicon nitride and if the second insulating layers 232 and the second retro-stepped dielectric material portion 265 comprise silicon oxide, an anisotropic etch process that etches silicon nitride selectively to silicon oxide can be performed to remove the second masking patterns 267. The second subset of the second-tier contact openings 229B are reopened.

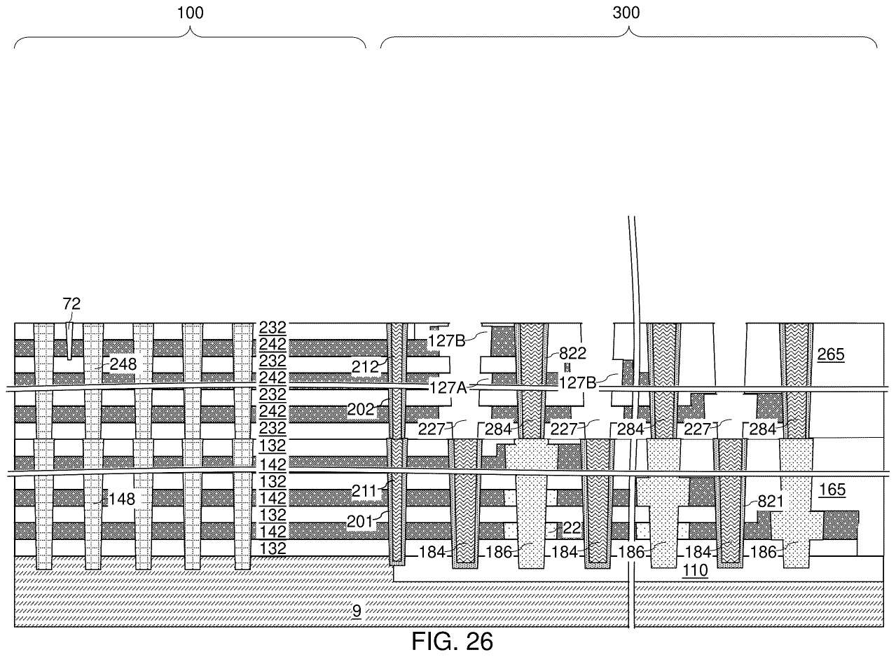

Referring to FIG. 26, an isotropic etch process can be performed to laterally recess the physically exposed sidewalls of the second sacrificial material layers 242 selectively to the materials of the second insulating layers 232 and the second retro-stepped dielectric material portion 265. Fin-shaped annular voids (227A, 227B) are formed around the second subset of the second-tier contact openings 229B. Each contiguous volume of a void including a volume of a second-tier contact opening 229B within the second subset of the second-tier contact openings 229 and at least one annular void (227A, 227B) constitutes a second-tier fin-containing void 227.

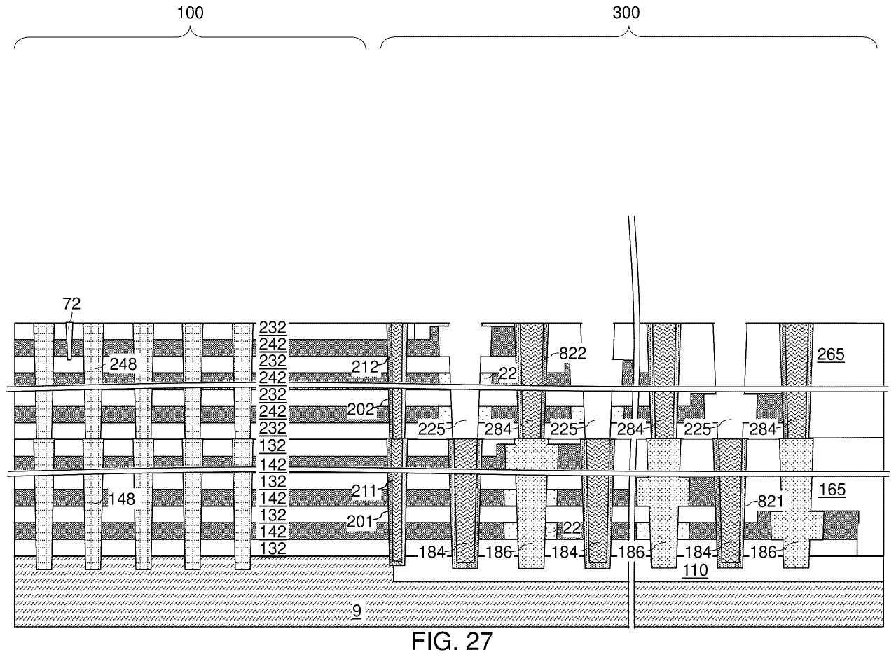

Referring to FIG. 27, a second insulating spacer material layer, such as a silicon oxide layer, can be conformally deposited in peripheral regions of the second-tier fin-containing voids 227 and in the annular voids (227A, 227B). The thickness of the second insulating spacer material layer can be greater than one half of the thickness of unthickened portions of the second sacrificial material layers 242, and is less than one half of the thickness of the thickened portions of the second sacrificial material layers 242. A first subset of shorter annular voids 227A having the same vertical extent as the unthickened portions of the second sacrificial material layers 242 is completely filled with portions of the second insulating spacer material layer, while another subset of taller annular voids 227B having the same vertical extent as the thickened portions of the second sacrificial material layers 242 is only partially filled with portions of the second insulating spacer material layer.

An isotropic recess etch process can be performed to isotropically etch portions of the second insulating spacer material layer. The duration of the isotropic recess etch process can be selected such that the etch distance of the isotropic etch process for the material of the second insulating spacer material layer is in a range from 100% to 120% of the thickness of the second insulating spacer material layers 242. Portions of second insulating spacer material layer located in the taller annular voids 227B adjacent to the thickened portions of the second sacrificial material layers 242 can be removed. Remaining portions of the second insulating spacer material layer that fill a respective shorter annular void 227A adjacent to the unthickened portions of the sacrificial material layers 242 comprise second annular insulating spacers 22. Each remaining unfilled volume of the second-tier fin-containing void 227 including the taller annular void 227B constitutes a second-tier finned contact via opening 225. At least one second annular insulating spacer 22 can be around the second-tier finned contact via opening 225 through the second alternating stack (232, 242).

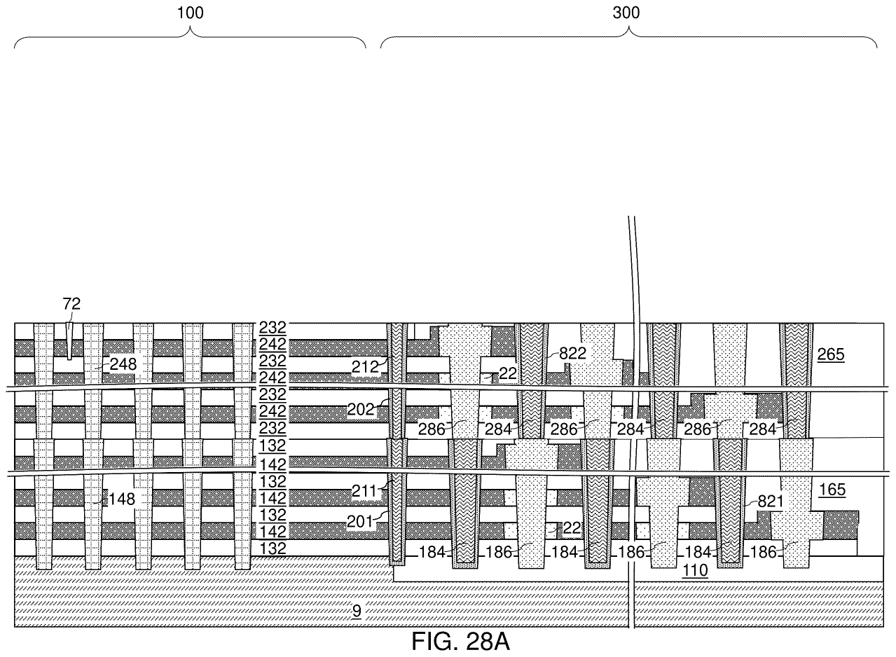

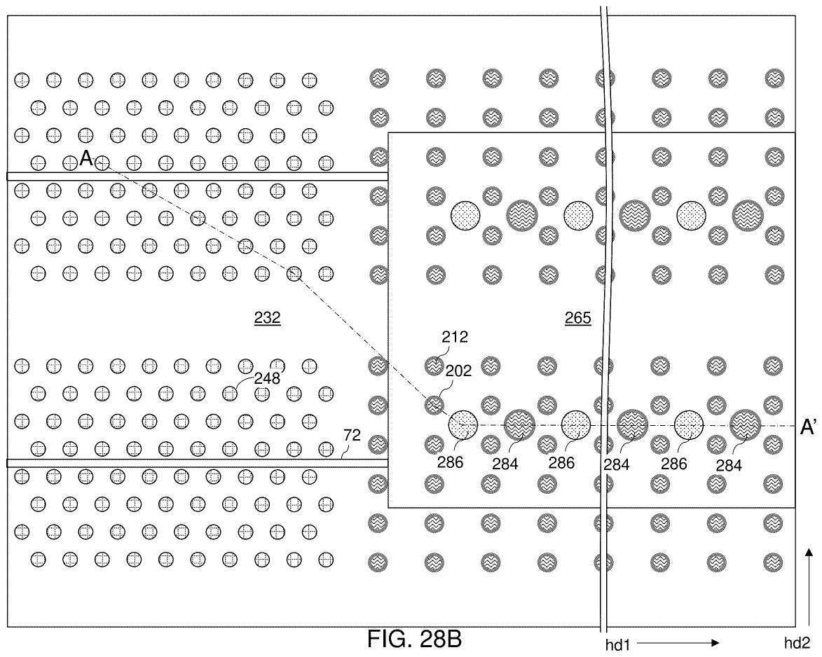

Referring to FIGS. 28A and 28B, a second sacrificial via fill material can be deposited in the second-tier finned contact via openings 225, which comprise remaining volumes of the second subset of the second-tier contact openings 229B. The second sacrificial via fill material comprises a material that may be subsequently removed selectively to the material of the second insulating layers 232. For example, the second sacrificial via fill material may comprise amorphous silicon or polysilicon. Excess portions of the second sacrificial via fill material may be removed from above the horizontal plane including the topmost surface of the second alternating stack (232, 242) by performing a planarization process, which may comprise a recess etch process or a chemical mechanical polishing process. Remaining portions of the second sacrificial via fill material that fill the second subset of the second-tier contact openings 229B comprise second-tier finned sacrificial via fill material portions 286. Thus, a second-tier structure is formed.

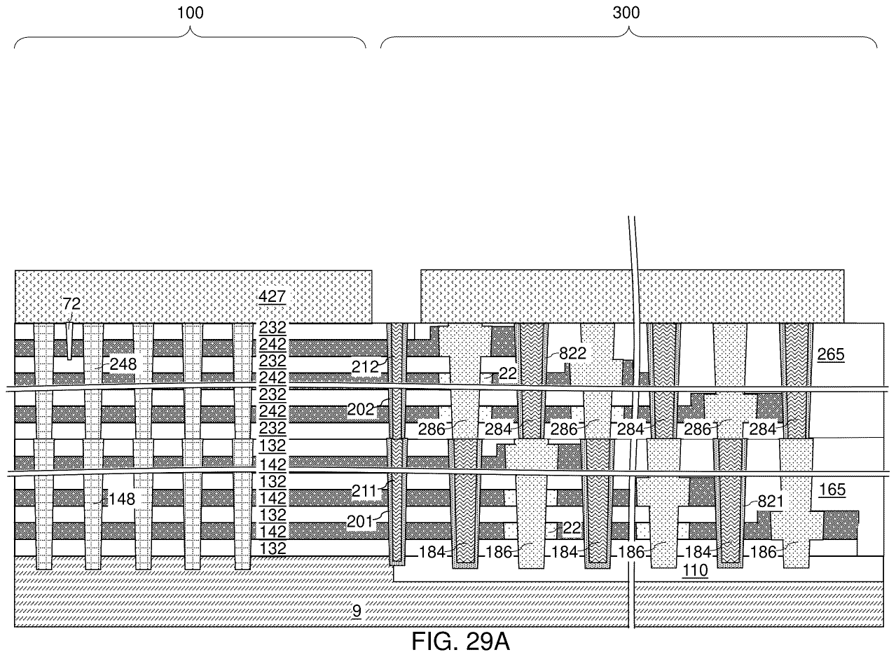

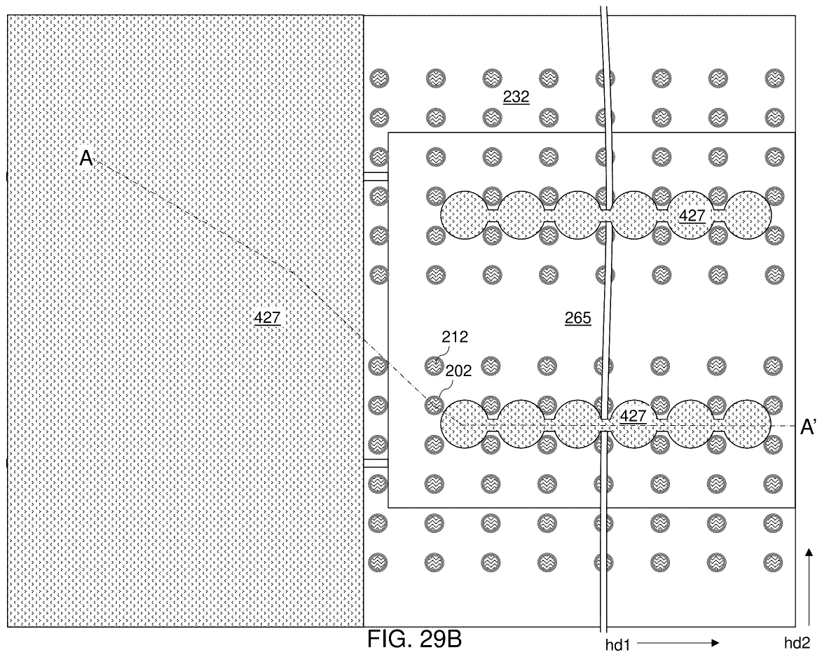

Referring to FIGS. 29A and 29B, a photoresist layer 427 can be applied over the second alternating stack (232, 242), and can be lithographically patterned to cover the memory array region 100 and the second-tier sacrificial via fill material portions (284, 286).

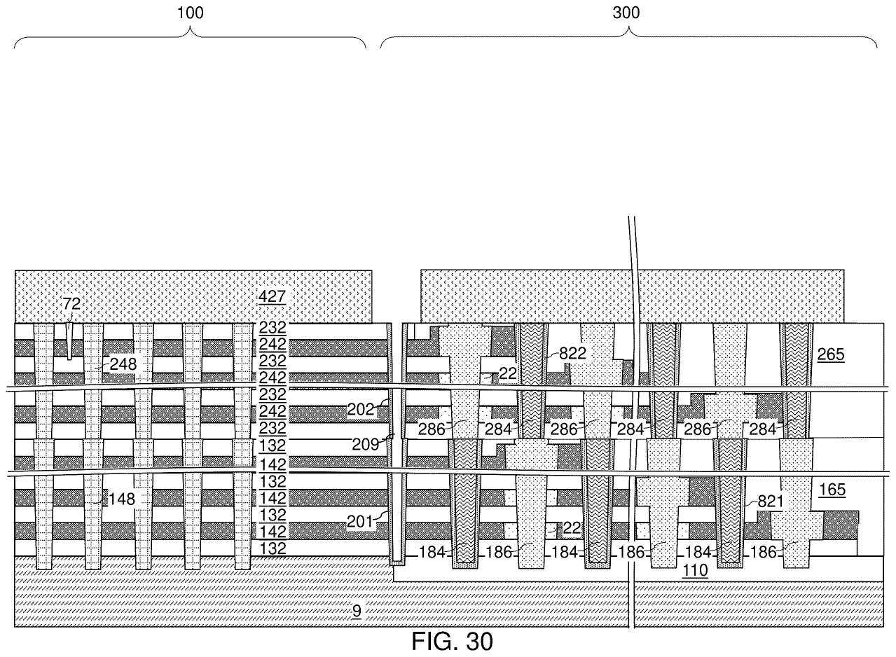

Referring to FIG. 30, an optional selective etch process can be performed to remove the second-tier sacrificial support opening fill material portions 212 and the first-tier sacrificial support opening fill material portions 211 without removing the second-tier support opening dielectric spacers 202 and the first-tier support opening dielectric spacers 201. Voids are formed in the volumes from which the second-tier sacrificial support opening fill material portions 212 and the first-tier sacrificial support opening fill material portions 211 are removed.

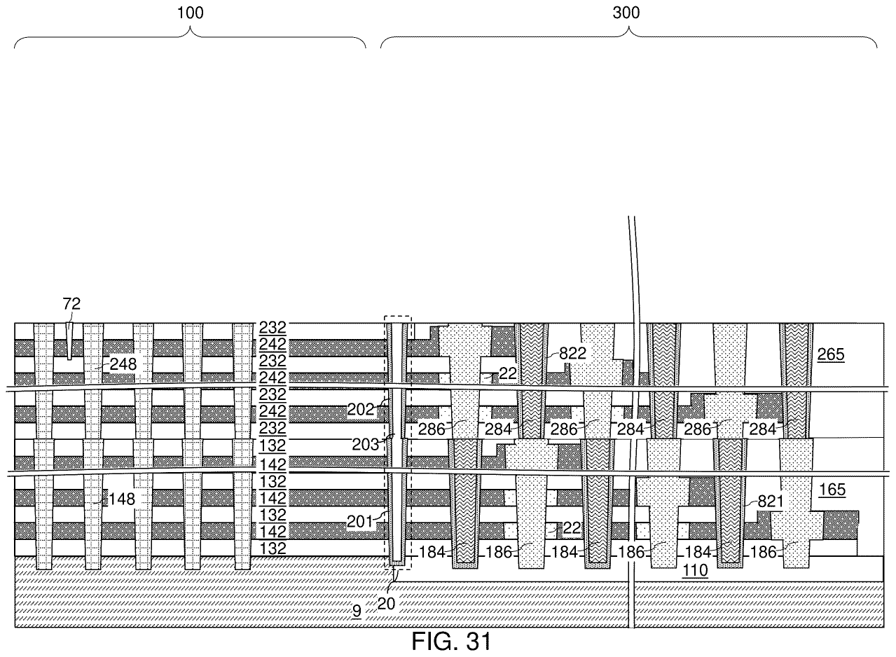

Referring to FIG. 31, an optional dielectric fill material, such as silicon oxide, can be deposited in the voids located in the vertically connected pair of support openings (119, 219) that are laterally surrounded by the second-tier support opening dielectric spacers 202 and the first-tier support opening dielectric spacers 201. Excess portions of the dielectric fill material can be removed from above the horizontal plane including the topmost surface of the second alternating stack (232, 242). A dielectric fill material 203 fills the void in the vertically connected pair of support openings (119, 219). Each contiguous set of a first-tier support opening dielectric spacer 201, a second-tier support opening dielectric spacer 202, and a dielectric fill material 203 constitutes a support pillar structure 20.

Alternatively, the steps illustrated in FIGS. 30 and 31 may be omitted. In this case, the support pillar structures 20 each comprise the first-tier support opening dielectric spacer 201, the second-tier support opening dielectric spacer 202, the first-tier sacrificial support opening fill material portion 211 and the second-tier sacrificial support opening fill material portion 212.

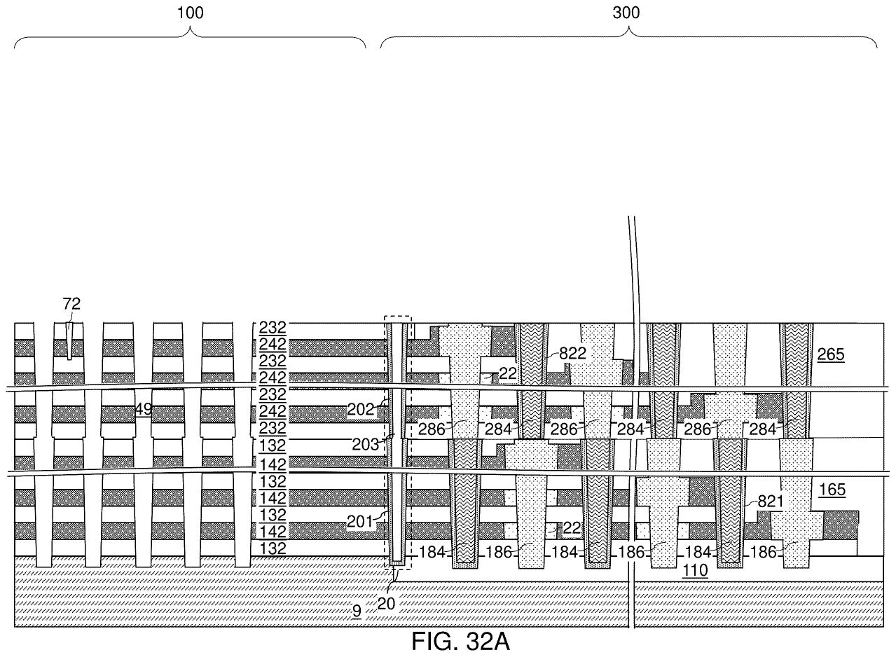

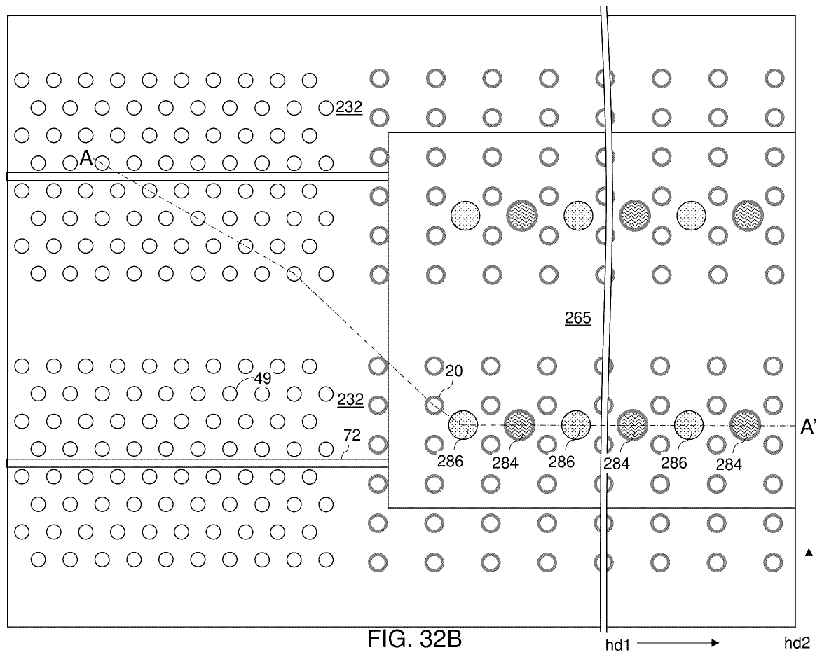

Referring to FIGS. 32A and 32B, the second-tier sacrificial memory opening fill structures 248 and the first-tier sacrificial memory opening fill structure 148 can be removed selectively to the materials of the first alternating stack (132, 242), the second alternating stack (232, 242), the first retro-stepped dielectric material portion 165, the second retro-stepped dielectric material portion 265, the second-tier sacrificial via fill material portions (284, 286), and the first-tier sacrificial via fill material portions (184, 186). For example, if the second-tier sacrificial memory opening fill structures 248 and the first-tier sacrificial memory opening fill structure 148 comprise a carbon-based material such as amorphous carbon, an ashing process can be performed to remove the second-tier sacrificial memory opening fill structures 248 and the first-tier sacrificial memory opening fill structure 148. If the second-tier sacrificial memory opening fill structures 248 and the first-tier sacrificial memory opening fill structure 148 comprise a semiconductor material such as silicon, a masked etch process employing an etch mask that covers the second-tier sacrificial memory opening fill structures 248 and the first-tier sacrificial memory opening fill structure 148 can be employed. Memory openings 49 are formed in the volumes from which the materials of the second-tier sacrificial memory opening fill structures 248 and the first-tier sacrificial memory opening fill structure 148 are removed.

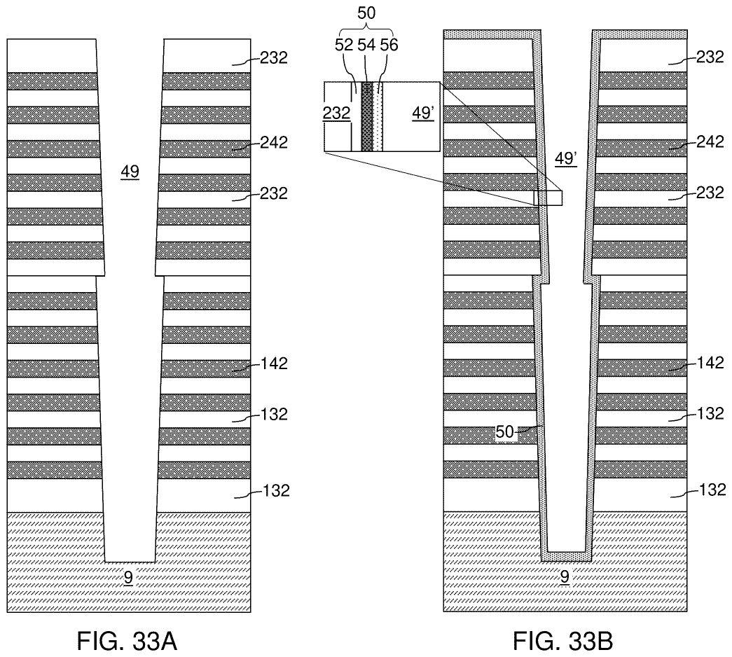

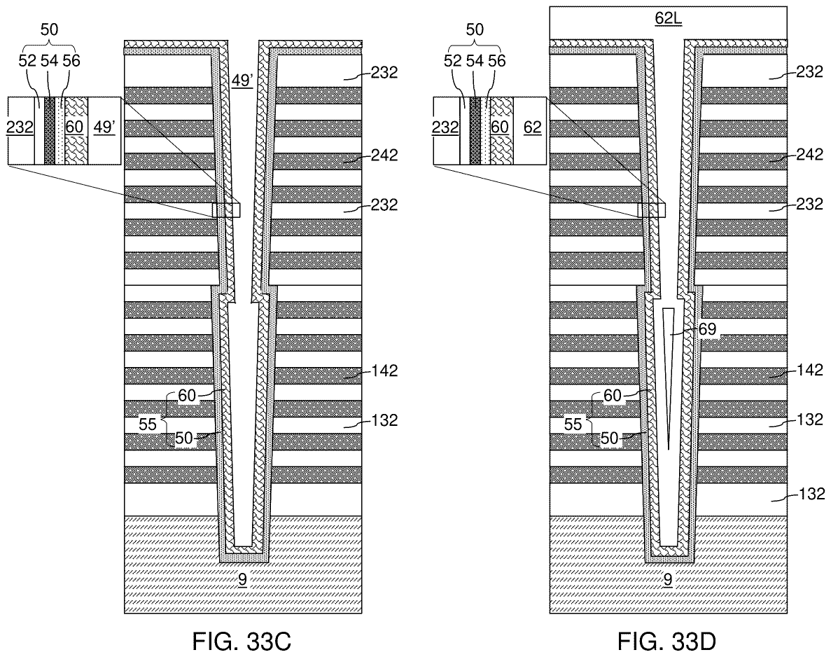

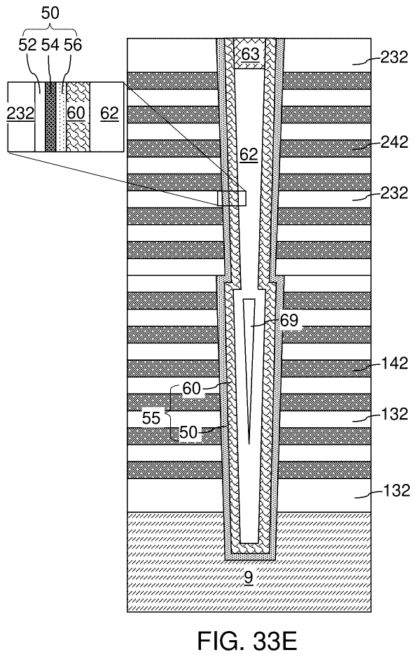

FIGS. 33A-33E illustrate sequential vertical cross-sectional views of a memory opening during formation of a memory opening fill structure according to the first embodiment of the present disclosure.

Referring to FIG. 33A, a memory opening 49 in the first exemplary structure of FIG. 32 is illustrated.

Referring to FIG. 33B, a stack of layers including a blocking dielectric layer 52, a memory material layer 54, a dielectric liner 56, and an optional sacrificial cover layer 57 may be sequentially deposited in the inter-tier memory openings 49. The blocking dielectric layer 52 may include a single dielectric material layer or a stack of a plurality of dielectric material layers. In one embodiment, the blocking dielectric layer 52 may include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 may include a dielectric metal oxide having a dielectric constant higher than 7.9, i.e., having a dielectric constant higher than the dielectric constant of silicon nitride. The thickness of the dielectric metal oxide layer may be in a range from 1 nm to 20 nm, although lesser and greater thicknesses may also be used. The dielectric metal oxide layer may subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 may include a dielectric semiconductor compound such as silicon oxide, silicon oxynitride, silicon nitride, or a combination thereof.

Subsequently, the memory material layer 54 may be formed. Generally, the memory material layer 54 may comprise any memory material known in the art. In one embodiment, the memory material layer 54 may be a continuous layer or patterned discrete portions of a charge trapping material including a dielectric charge trapping material, which may be, for example, silicon nitride. Alternatively, the memory material layer 54 may include a continuous layer or patterned discrete portions of a conductive material such as doped polysilicon or a metallic material that is patterned into multiple electrically isolated portions (e.g., floating gates), for example, by being formed within lateral recesses into sacrificial material layers (142, 242). In one embodiment, the memory material layer 54 includes a silicon nitride layer. In one embodiment, the sacrificial material layers (142, 242) and the insulating layers (132, 232) may have vertically coincident sidewalls, and the memory material layer 54 may be formed as a single continuous layer. Alternatively, the sacrificial material layers (142, 242) may be laterally recessed with respect to the sidewalls of the insulating layers (132, 232), and a combination of a deposition process and an anisotropic etch process may be used to form the memory material layer 54 as a plurality of memory material portions that are vertically spaced apart. The thickness of the memory material layer 54 may be in a range from 2 nm to 20 nm, although lesser and greater thicknesses may also be used.

The dielectric liner 56 includes a dielectric material. In one embodiment, the dielectric liner 56 may comprise a tunneling dielectric layer through which charge tunneling may be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric liner 56 may include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric liner 56 may include a stack of a first silicon oxide layer, a silicon oxynitride layer, and a second silicon oxide layer, which is commonly known as an ONO stack. In one embodiment, the dielectric liner 56 may include a silicon oxide layer that is substantially free of carbon or a silicon oxynitride layer that is substantially free of carbon. The thickness of the dielectric liner 56 may be in a range from 2 nm to 20 nm, although lesser and greater thicknesses may also be used. The stack of the blocking dielectric layer 52, the memory material layer 54, and the dielectric liner 56 constitutes a memory film 50 that stores memory bits.

Referring to FIG. 33C, a semiconductor channel material layer 60L can be deposited by a conformal deposition process. The semiconductor channel material layer 60L includes a p-doped semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L may have a uniform doping. In one embodiment, the semiconductor channel material layer 60L has a p-type doping in which p-type dopants (such as boron atoms) are present at an atomic concentration in a range from 1.0×10¹²/cm³ to 1.0×10¹⁸/cm³, such as from 1.0×10¹⁴/cm³ to 1.0×10¹⁷/cm³. In one embodiment, the semiconductor channel material layer 60L includes, and/or consists essentially of, boron-doped amorphous silicon or boron-doped polysilicon. In another embodiment, the semiconductor channel material layer 60L has an n-type doping in which n-type dopants (such as phosphor atoms or arsenic atoms) are present at an atomic concentration in a range from 1.0×10¹²/cm³ to 1.0×10¹⁸/cm³, such as from 1.0×10¹⁴/cm³ to 1.0×10¹⁷/cm³. The semiconductor channel material layer 60L may be formed by a conformal deposition method such as a low pressure chemical vapor deposition (LPCVD) process. The thickness of the semiconductor channel material layer 60L may be in a range from 2 nm to 10 nm, although lesser and greater thicknesses may also be used. A cavity 49′ is formed in the volume of each inter-tier memory opening 49 that is not filled with the deposited material layers (52, 54, 56, 60L).

Referring to FIG. 33D, if the cavity 49′ in each memory opening 49 is not completely filled by the semiconductor channel material layer 60L, a dielectric core layer 62L may be deposited in the cavity 49′ to fill any remaining portion of the cavity 49′ within each memory opening 49. The dielectric core layer 62L includes a dielectric material such as silicon oxide or organosilicate glass. The dielectric core layer 62L may be deposited by a conformal deposition method such as a low pressure chemical vapor deposition (LPCVD) process, or by a self-planarizing deposition process such as spin coating.

Referring to FIG. 33E, the horizontal portion of the dielectric core layer 62L overlying the third insulating cap layer 370 may be removed, for example, by a recess etch. The recess etch continues until top surfaces of the remaining portions of the dielectric core layer are recessed to a height between the top and bottom surfaces of the third insulating cap layer 370. Each remaining portion of the dielectric core layer constitutes a dielectric core 62.

A doped semiconductor material having a doping of a second conductivity type may be deposited in cavities overlying the dielectric cores 62. The second conductivity type is the opposite of the first conductivity type. For example, if the first conductivity type is p-type, the second conductivity type is n-type, and vice versa. Portions of the deposited doped semiconductor material, the semiconductor channel material layer 60L, the dielectric liner 56, the memory material layer 54, and the blocking dielectric layer 52 that overlie the horizontal plane including the top surface of the third insulating cap layer 370 may be removed by a planarization process such as a chemical mechanical planarization (CMP) process.

Each remaining portion of the doped semiconductor material of the second conductivity type constitutes a drain region 63. The dopant concentration in the drain regions 63 may be in a range from 5.0×10¹⁸/cm³ to 2.0×10²¹/cm³, although lesser and greater dopant concentrations may also be used. The doped semiconductor material may be, for example, doped polysilicon.

Each remaining portion of the semiconductor channel material layer 60L constitutes a vertical semiconductor channel 60 through which electrical current may flow when a vertical NAND device including the vertical semiconductor channel 60 is turned on. A dielectric liner 56 is surrounded by a memory material layer 54, and laterally surrounds a vertical semiconductor channel 60. Each adjoining set of a blocking dielectric layer 52, a memory material layer 54, and a dielectric liner 56 collectively constitute a memory film 50, which may store electrical charges with a macroscopic retention time. In some embodiments, a blocking dielectric layer 52 may not be present in the memory film 50 at this step, and a blocking dielectric layer may be subsequently formed after formation of lateral recesses. As used herein, a macroscopic retention time refers to a retention time suitable for operation of a memory device as a permanent memory device such as a retention time in excess of 24 hours.

Each combination of a memory film 50 and a vertical semiconductor channel 60 within an inter-tier memory opening 49 constitutes a memory stack structure 55. The memory stack structure 55 is a combination of a vertical semiconductor channel 60, a dielectric liner 56, a plurality of memory elements comprising portions of the memory material layer 54, and an optional blocking dielectric layer 52. The memory stack structures 55 can be formed through memory array regions 100 of the first and second alternating stacks in which all layers of the first and second alternating stacks are present. Each combination of a memory stack structure 55, a dielectric core 62, and a drain region 63 within an inter-tier memory opening 49 constitutes a memory opening fill structure 58. Generally, memory opening fill structures 58 are formed within the memory openings 49. Each of the memory opening fill structures 58 comprises a respective memory film 50 and a respective vertical semiconductor channel 60.

In one embodiment, each of the memory stack structures 55 comprises vertical NAND string including the respective vertical stack of memory elements (comprising portions of a memory material layer 54 located at levels of the sacrificial material layers (142, 242)) and a vertical semiconductor channel 60 that vertically extend through the sacrificial material layers (142, 242).

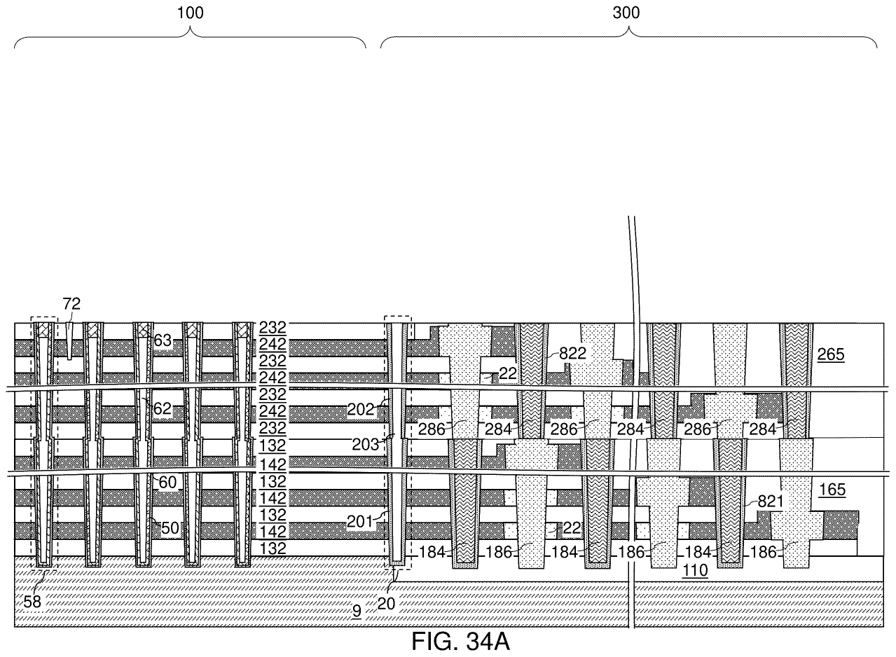

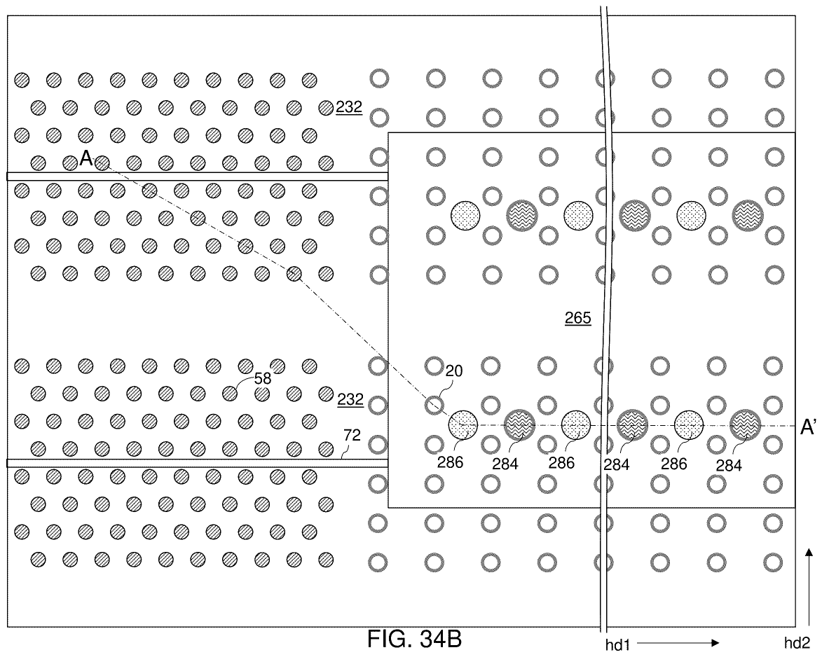

Referring to FIGS. 34A and 34B, the first exemplary structure is illustrated after formation of the memory opening fill structures 58.

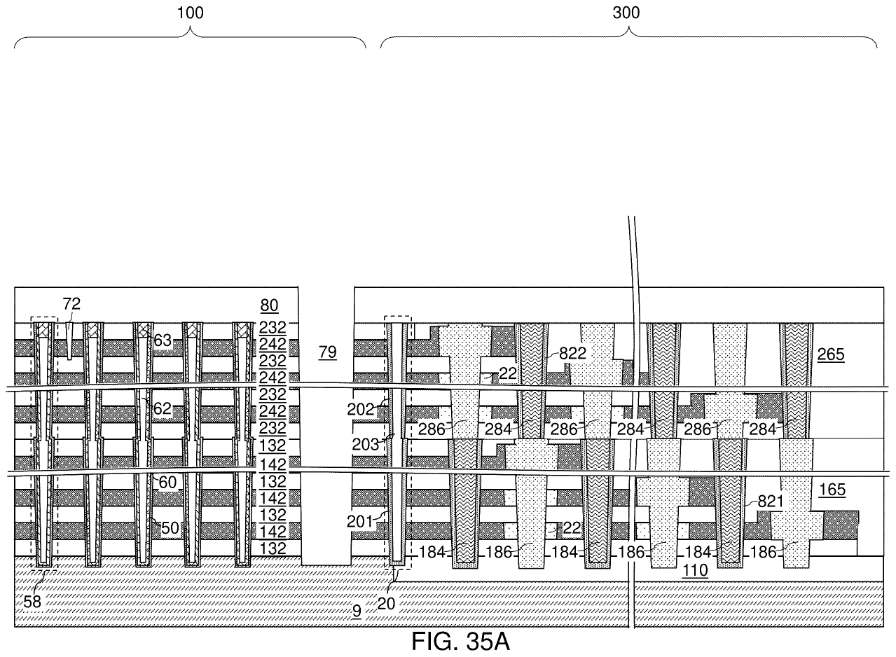

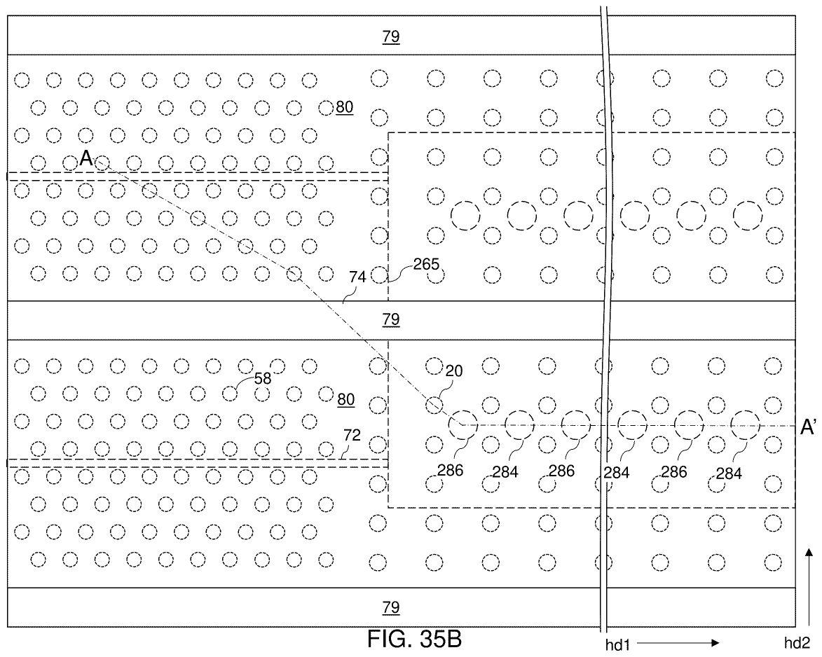

Referring to FIGS. 35A and 35B, a contact-level dielectric layer 80 can be formed over the second alternating stack (232, 242). The contact-level dielectric layer 80 comprises a dielectric material such as silicon oxide. A photoresist layer (not shown) can be applied over the contact-level dielectric layer 80, and can be lithographically patterned to form slit-shaped openings laterally extending along the first horizontal direction hd1. The slit-shaped openings can be formed between clusters of memory opening fill structures 58. An anisotropic etch process can be performed to transfer the pattern of the slit-shaped openings in the photoresist layer through the contact-level dielectric layer 80, the second-tier structure, and the first-tier structure. Lateral isolation trenches 79 vertically extending through patterned portions of the contact-level dielectric layer 80, the second-tier structure, and the first-tier structure can be formed.

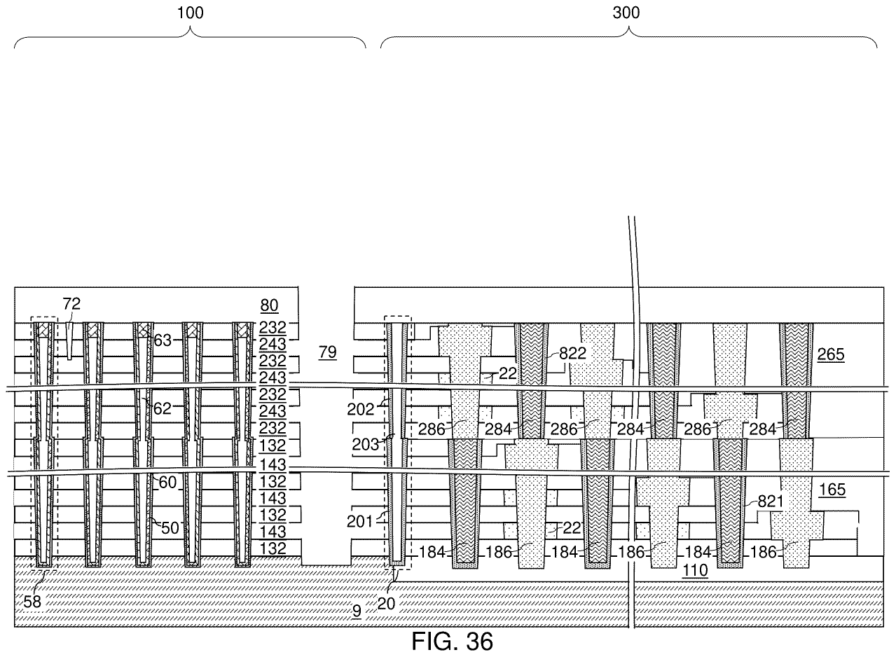

Referring to FIG. 36, an etchant that selectively etches the material of the sacrificial material layers (142, 242) with respect to the material of the insulating layers (132, 232), the contact-level dielectric layer 80, the retro-stepped dielectric material portions (165, 265) can be introduced into the lateral isolation trenches 79, for example, employing an isotropic etch process. Lateral recesses (143, 243) are formed in volumes from which the sacrificial material layers (142, 242) are removed. The lateral recesses (143, 243) comprise first lateral recesses 143 that are formed in volumes from which the first sacrificial material layers 142 are removed, and second lateral recesses 243 that are formed in volumes from which the second sacrificial material layers 243 are removed. The removal of the sacrificial material layers (142, 242) can be selectively to the materials of the insulating layers (132, 232), the contact-level dielectric layer 80, the retro-stepped dielectric material portions (165, 265), and the material of the outermost layer of the memory films 50. In one embodiment, the sacrificial material layers (142, 242) can include silicon nitride, and the materials of the insulating layers (132, 232) and the retro-stepped dielectric material portions (165, 265) can include silicon oxide.

The etch process that removes the second material selectively to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers (142, 242) include silicon nitride, the etch process can be a wet etch process in which the exemplary structure is immersed within a wet etch tank including phosphoric acid, which etches silicon nitride selectively to silicon oxide, silicon, and various other materials employed in the art. Generally, the lateral recesses (143, 243) can be formed by performing an isotropic etch process that etches the sacrificial material layers (142, 242) without etching the insulating layers (132, 232). The support pillar structure 20, the retro-stepped dielectric material portions (165, 265), and the memory opening fill structures 58 provide structural support while the lateral recesses (143, 243) are present within volumes previously occupied by the sacrificial material layers (142, 242).

Each lateral recess (143, 243) can be a laterally extending cavity having a lateral dimension that is greater than the vertical extent of the cavity. In other words, the lateral dimension of each lateral recess (143, 243) can be greater than the height of the lateral recess (143, 243). A plurality of lateral recesses (143, 243) can be formed in the volumes from which the second material of the sacrificial material layers (142, 242) is removed. Each of the plurality of lateral recesses (143, 243) can extend substantially parallel to the top surface of the substrate 9. A lateral recess (143, 243) can be vertically bounded by a top surface of an underlying insulating layer (132, 232) and a bottom surface of an overlying insulating layer (132, 232). In one embodiment, each lateral recess (143, 243) can have a respective first region formed by removal of an unthickened portion of a respective sacrificial material layer (142, 242) and having a first thickness, and a respective second region formed by removal of a thickened portion of the respective sacrificial material layer (142, 242) and having a second thickness that is greater than the first thickness.

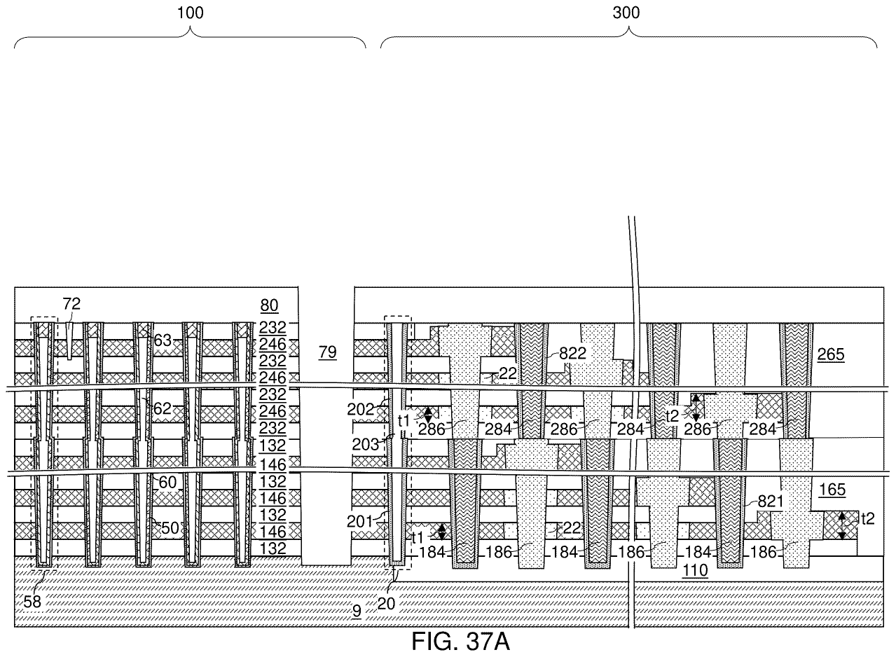

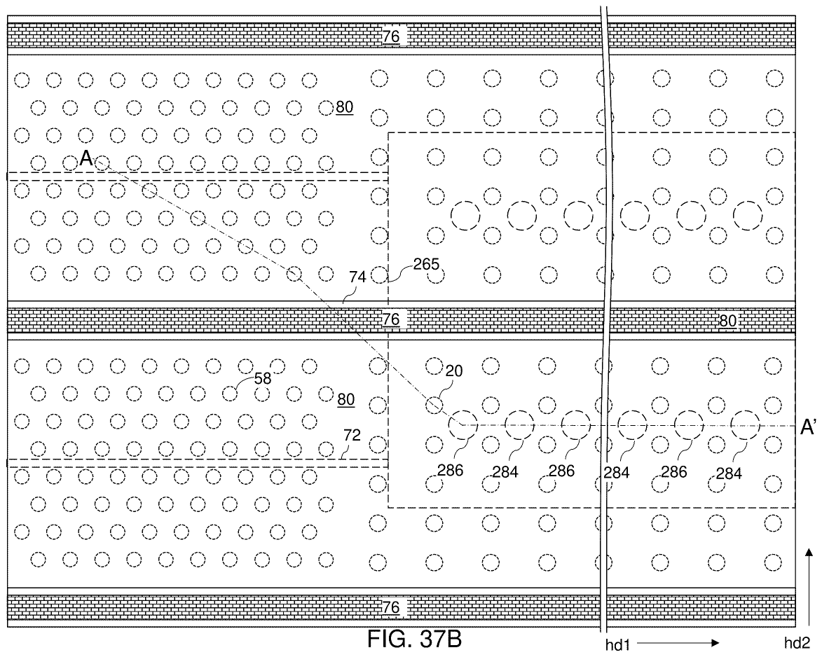

Referring to FIGS. 37A and 37B, an outer blocking dielectric layer (not shown) can be optionally formed in the lateral recesses (143, 243). The outer blocking dielectric layer, if present, comprises a dielectric material that functions as a control gate dielectric for the control gates to be subsequently formed in the lateral recesses (143, 243). In case the blocking dielectric layer 52 is present within each memory opening, the outer blocking dielectric layer is optional. In case the blocking dielectric layer 52 is omitted, the outer blocking dielectric layer is present.

At least one conductive material can be deposited in the lateral recesses (143, 243) by providing at least one reactant gas into the lateral recesses (143, 243) through the lateral isolation trenches 79. A metallic barrier layer can be deposited in the lateral recesses (143, 243). The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, MoN or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride, such as TiN.

A metal fill material is deposited in the plurality of lateral recesses (143, 243), on the sidewalls of each lateral isolation trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers (132, 232) and the memory stack structures 55 by the metallic barrier layer, which blocks diffusion of fluorine atoms therethrough.

Generally, electrically conductive layers (146, 246) are formed within the volumes of the lateral recesses (143, 243) by performing a conformal deposition process during which the lateral isolation trenches 79 are employed as conduits for providing a reactant that forms the electrically conductive layers (146, 246) upon decomposition. A plurality of electrically conductive layers (146, 246) can be formed in the plurality of lateral recesses (143, 243), and a continuous metallic material layer can be formed on the sidewalls of each lateral isolation trench 79 and over the contact-level dielectric layer 80. Each electrically conductive layer (146, 246) includes a portion of the metallic barrier layer and a portion of the metallic fill material layer that are located between a vertically neighboring pair of dielectric material layers such as a pair of insulating layers (132, 232). The continuous metallic material layer includes a continuous portion of the metallic barrier layer and a continuous portion of the metallic fill material layer that are located in the lateral isolation trenches 79 or above the contact-level dielectric layer 80.

The continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited continuous electrically conductive material layer within the lateral recesses (143, 243) constitutes an electrically conductive layer (146, 246). The electrically conductive layers (146, 246) comprise first electrically conductive layers 146 that replace the first sacrificial material layers 142 and second electrically conductive layers 246 that replace the second sacrificial material layers 242. Each electrically conductive layer (146, 246) can be a conductive line structure. Thus, the sacrificial material layers (142, 242) are replaced with the electrically conductive layers (146, 246). Generally, the electrically conductive layers (146, 246) can be formed by providing a metallic precursor gas into the lateral isolation trenches 79 and into the lateral recesses (143, 243).

Each electrically conductive layer (146, 246) may be embedded within a respective outer blocking dielectric layer, which may comprise a dielectric metal oxide material, such as aluminum oxide. Each outer blocking dielectric layer may have a pair of horizontally-extending portions in contact with a respective one of the insulating layers (132, 232), and a plurality of tubular portions laterally surrounding a respective one of the memory opening fill structures 58 and connecting the pair of horizontally-extending portions. The thickness of each outer blocking dielectric layer may be in a range from 1 nm to 6 nm, although lesser and greater thicknesses may also be employed.

Generally, an assembly of an alternating stack {(132, 146), (232, 246)} and memory opening fill structures 58 can be formed. The alternating stack {(132, 146), (232, 246)} comprises a vertically alternating sequence of insulating layers (132, 232) and electrically conductive layers (146, 246). The memory opening fill structures 58 vertically extend through the alternating stack {(132, 146), (232, 246)}. Each of the memory opening fill structures 58 comprises a respective vertical stack of memory elements (which may comprise portions of a memory material layer 54 located at levels of the electrically conductive layers (146, 246)), a respective vertical semiconductor channel 60, and a respective drain region 63. At least one uppermost electrically conductive layer (146, 246) may comprise a drain side select gate electrode. At least one bottommost electrically conductive layer (146, 246) may comprise a source side select gate electrode. The remaining electrically conductive layers (146, 246) may comprise word lines. Each word line functions as a common control gate electrode for the plurality of vertical NAND strings (e.g., memory opening fill structures 58).

In one embodiment, each of the electrically conductive layers (146, 246) has a first thickness t1 in the memory array region 100 and in a respective area of the contact region 300 that is distal from a respective vertical stack of a first-tier sacrificial via fill material portion (184, 186) and a second-tier sacrificial via fill material portion (284, 286). Each of the electrically conductive layers (146, 246) has a second thickness t2 that is greater than the first thickness t1 in a respective area that is proximal to the respective vertical stack of the first-tier sacrificial via fill material portion (184, 186) and the second-tier sacrificial via fill material portion (284, 286).

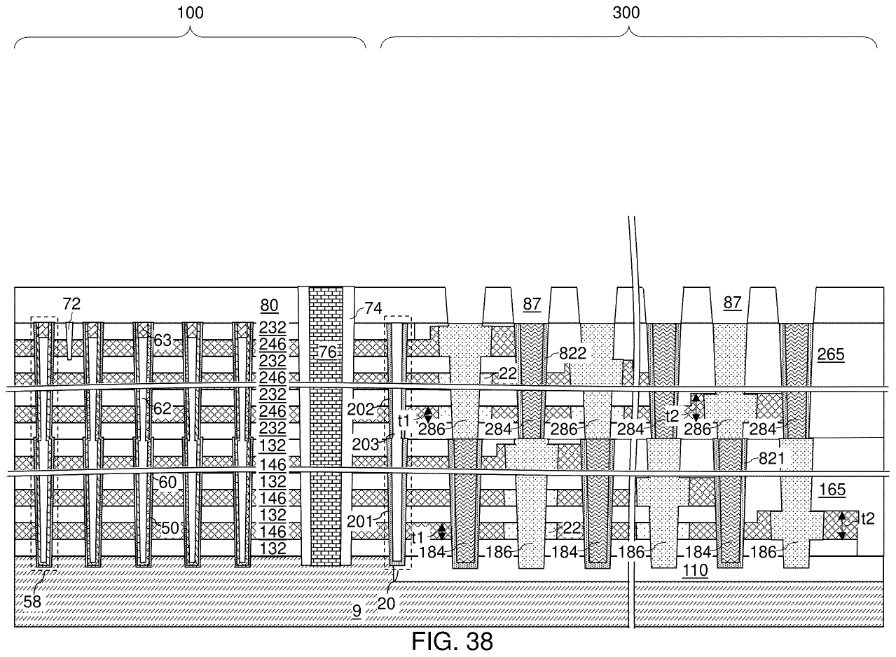

Referring to FIG. 38, at least one lateral isolation trench fill material can be deposited in the lateral isolation trenches 79 to form lateral isolation trench fill structures (74, 76). For example, each lateral isolation trench fill structure (74, 76) may comprise a respective combination of an isolation trench insulating spacer 74 and an isolation trench fill material portion 74, which may comprise a fill material such as at least one metallic material and/or at least one semiconductor material.

A photoresist layer (not shown) can be applied over the contact-level dielectric layer 80, and can be lithographically patterned to form discrete openings over the areas of the vertical stacks of a respective first-tier sacrificial via fill material portion (184, 186) and a respective second-tier sacrificial via fill material portion (284, 286). An anisotropic etch process can be performed to transfer the pattern of the openings in the photoresist layer through the contact-level dielectric layer 80. Contact through-holes 87 can be formed through the contact-level dielectric layer 80 over the vertical stacks of a respective first-tier sacrificial via fill material portion (184, 186) and a respective second-tier sacrificial via fill material portion (284, 286).

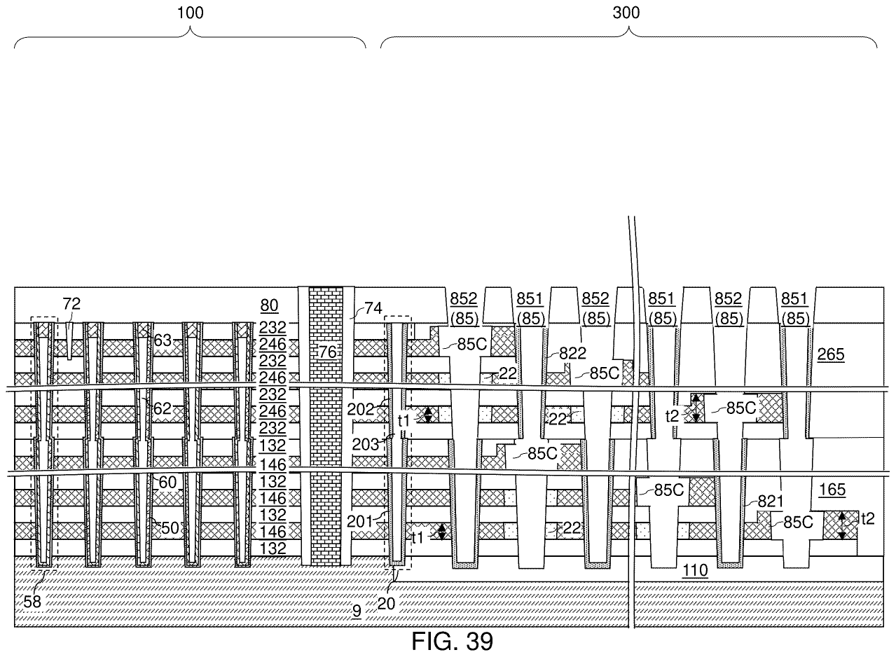

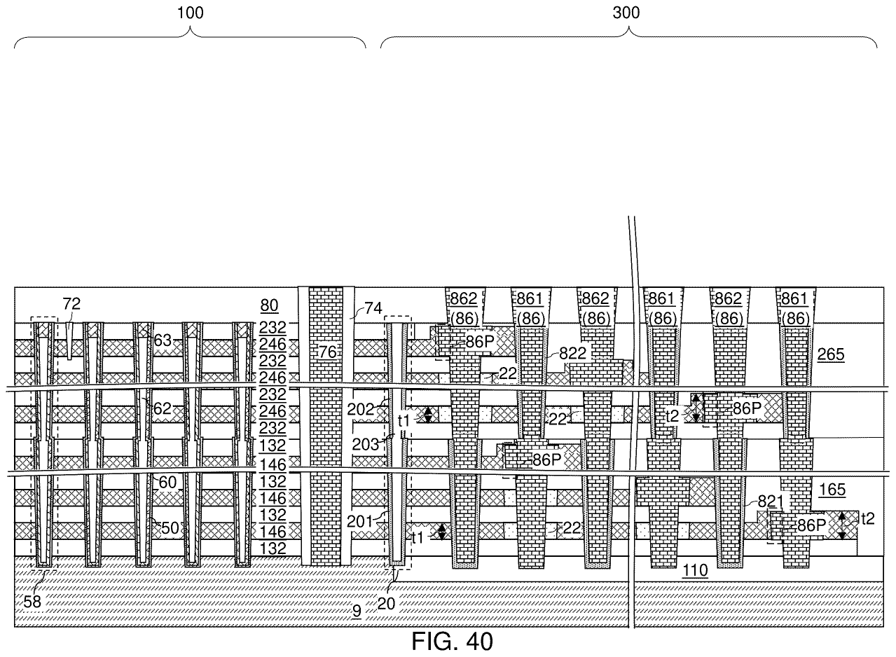

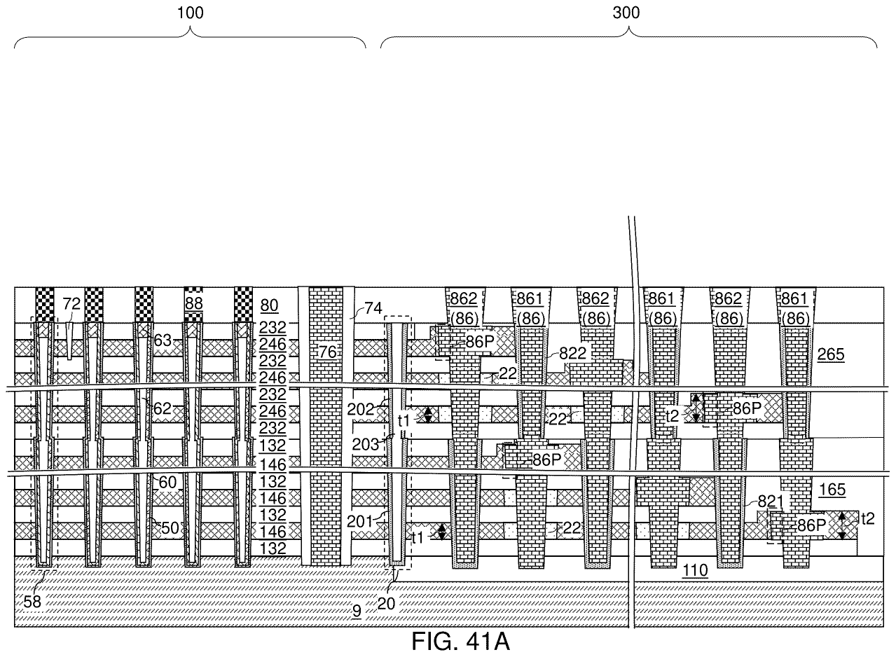

Referring to FIG. 39, a selective etch process can be performed to remove the second-tier sacrificial via fill material portions (284, 286) and the first-tier sacrificial via fill material portion (184, 186) without removing the second dielectric spacers 822, the first dielectric spacers 821, the contact-level dielectric layer 80, the insulating layers (132, 232), the electrically conductive layers (146, 246), or the retro-stepped dielectric material portions (165, 265). For example, if the second-tier sacrificial via fill material portions (284, 286) and the first-tier sacrificial via fill material portion (184, 186) comprise amorphous silicon, then the selective etch process may comprise a selective hot trimethyl-2 hydroxyethyl ammonium hydroxide (“hot TMY”) or tetramethyl ammonium hydroxide (TMAH) etch process. Through-stack contact via cavities 85 are formed in the volumes of the contact through-holes 87 and in the voids formed by removal of the second-tier sacrificial via fill material portions (284, 286) and the first-tier sacrificial via fill material portion (184, 186). The through-stack contact via cavities 85 comprise first-type through-stack contact via cavities 851 formed by removal of a respective combination of a first-tier finned sacrificial via fill material portion 186 and a second-tier pillar-shaped sacrificial via fill material portion 284, and second-type through-stack contact via cavities 852 formed by removal of a respective combination of a first-tier pillar-shaped sacrificial via fill material portion 184 and a second-tier finned sacrificial via fill material portion 286.

Each of the through-stack contact via cavities 85 comprises a respective first cylindrical cavity portion that vertically extends through the first alternating stack (132, 146), a second cylindrical cavity portion that vertically extends through the second alternating stack (232, 246), and a respective annular cavity portion 85C that laterally protrudes outward from the first cylindrical cavity portion or from the second cylindrical cavity portion. A cylindrical surface of a respective first electrically conductive layer 146 is physically exposed around the annular cavity portion 85C of each first-type through-stack contact via cavity 851. A cylindrical surface of a respective second electrically conductive layer 246 is physically exposed around the annular cavity portion 85C of each second-type through-stack contact via cavity 852.

A predominant fraction of the first-type through-stack contact via cavities 851 may be laterally surrounded by a respective set of at least one first annular insulating spacer 22 located at levels of a respective subset of the first electrically conductive layers 146. Each of the first-type through-stack via cavities 851 may be laterally surrounded by a respective second dielectric spacer 822, which can be a tubular dielectric spacer having a tubular configuration and vertically extending from a bottommost surface of the second-tier structure to a topmost surface of the second-tier structure. A predominant fraction of the second-type through-stack contact via cavities 852 may be laterally surrounded by a respective set of at least one second annular insulating spacer 22 located at levels of a respective subset of the second electrically conductive layers 246. Each of the second-type through-stack via cavities 852 may be laterally surrounded by a respective first dielectric spacer 821, which can be a tubular dielectric spacer having a tubular configuration and vertically extending from a bottommost surface of the first-tier structure to a topmost surface of the first-tier structure.

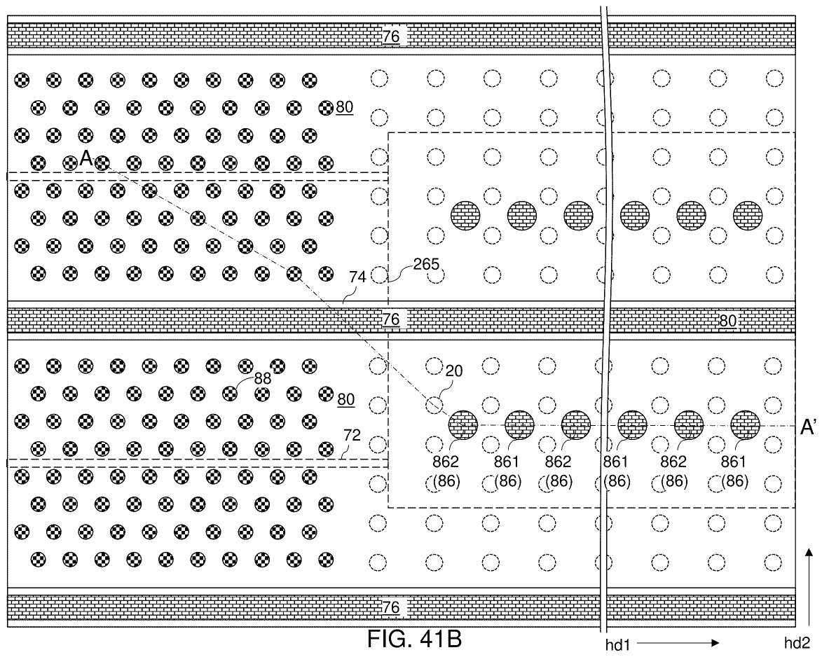

Referring to FIG. 40, at least one electrically conductive material can be deposited in the through-stack contact via cavities 85. The at least one electrically conductive material may comprise a combination of a metallic barrier material (such as TiN, TaN, WN, or MoN) and a metallic fill material (such as W, Co, Mo, Ru, Cu, Ti, Ta, etc.). Excess portions of the at least one electrically conductive material can be removed from above the horizontal plane including the top surface of the contact-level dielectric layer 80 by performing a planarization process such as a chemical vapor deposition process. Remaining portions of the at least one electrically conductive material filling the through-stack contact via cavities 85 constitute through-stack contact via structures 86. The through-stack contact via structures 86 comprise first through-stack contact via structures 861 that are formed in the first-type through-stack contact via cavities 851, and second through-stack contact via structures 862 that are formed in the second-type through-stack contact via cavities 852. Each first through-stack contact via structure 861 contacts a respective cylindrical sidewall of a respective one of the first electrically conductive layers 146. Each second through-stack contact via structure 862 contacts a respective cylindrical sidewall of a respective one of the second electrically conductive layer 246. Each first through-stack contact via structure 861 includes an annular lateral protrusion portion 86P that laterally protrudes into the cavity 85C from a pillar portion of the first through-stack contact via structure 861 and contacts a sidewall of the thicker portion of the respective one of the first electrically conductive layers 146 having the thickness t2. Each second through-stack contact via structure 862 also includes an annular lateral protrusion portion 86P that laterally protrudes into the cavity 85C from a pillar portion of the second through-stack contact via structure 862 and contacts a sidewall of the thicker portion of the respective one of the second electrically conductive layers 142 having the thickness t2.

Each first through-stack contact via structure 861 vertically extends at least from a first horizontal plane including a topmost surface of the second alternating stack (232, 246) and at least to a second horizontal plane including a bottommost surface of the first alternating stack (132, 146), and contacts a respective one of the first electrically conductive layers 146. A plurality of first through-stack contact via structures 861 can be formed on the inner cylindrical sidewall(s) of a set of at least one annular insulating spacer 22. Each first through-stack contact via structure 861 can be formed through the second retro-stepped dielectric material portion 265 and the first retro-stepped dielectric material portion 165.

The first exemplary structure comprises a first alternating stack (132, 146) of first insulating layers 132 and first electrically conductive layers 146 and having first stepped surfaces in a contact region 300; a second alternating stack (232, 246) of second insulating layers 232 and second electrically conductive layers 246 and having second stepped surfaces in the contact region 300; and a first through-stack contact via structure 861 vertically extending through the second stepped surfaces and a subset of the second electrically conductive layers 246 and contacting one of the first electrically conductive layers 146. In one embodiment, the first through-stack contact via structure 861 is electrically isolated from each of the second electrically conductive layers 246. In one embodiment, the first through-stack contact via structure 861 is electrically isolated from all of the first electrically conductive layers 146 except said one of the first electrically conductive layers 146. In one embodiment, the first through-stack contact via structure 861 is in contact with a cylindrical sidewall of said one of the first electrically conductive layers 146. In one embodiment, the first through-stack contact via structure 861 vertically extends at least from a horizontal plane including a topmost surface of the second alternating stack (232, 246) to a horizontal plane including a bottommost surface of the first alternating stack (132, 146).

Referring to FIGS. 41A and 41B, drain contact via structures 88 can be formed through the contact-level dielectric layer 80 on top surfaces of the drain regions 63 of the memory opening fill structures 58.

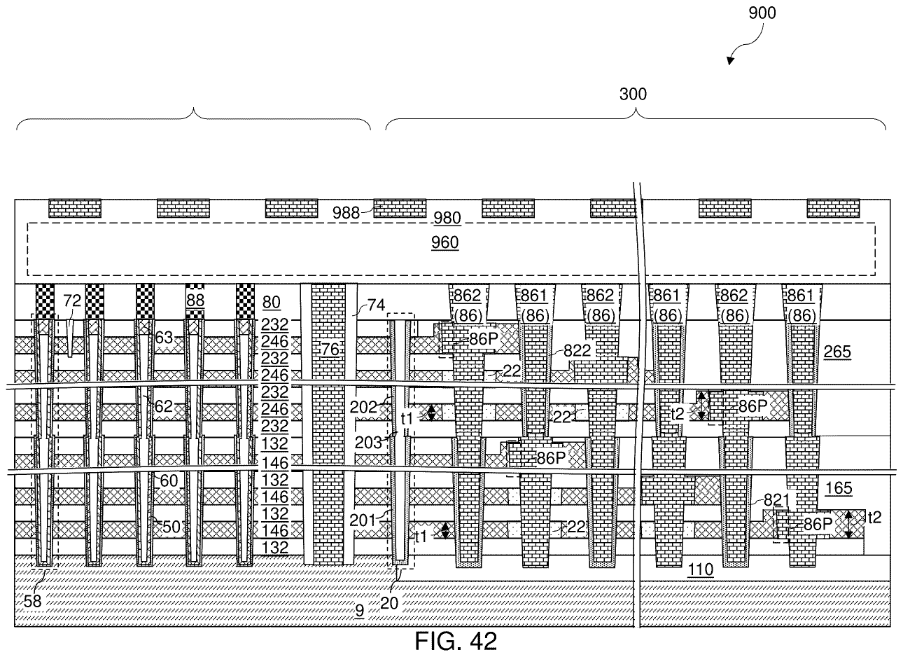

Referring to FIG. 42, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-die dielectric material layers 960. The additional metal interconnect structures are collectively referred to as memory-die metal interconnect structures 980. The memory-die dielectric material layers 960 comprise a bit-line-level dielectric material layer embedding bit lines, which are a subset of the memory-die metal interconnect structures 980.

Metal bonding pads, which are herein referred to as memory-die bonding pads 988, may be formed at the topmost level of the memory-die dielectric material layers 960. The memory-die bonding pads 988 may be electrically connected to the memory-die metal interconnect structures 980 and various nodes of the three-dimensional memory array including the electrically conductive layers (146, 246) and the memory opening fill structures 58. A memory die 900 can thus be provided.

The memory-die dielectric material layers 960 are formed over the alternating stacks {(132, 146), (232, 246)}. The memory-die metal interconnect structures 980 are embedded in the memory-die dielectric material layers 960. The memory-die bonding pads 988 can be embedded within the memory-die dielectric material layers 960, and specifically, within the topmost layer of the memory-die dielectric material layers 960. The memory-die bonding pads 988 can be electrically connected to the memory-die metal interconnect structures 980.

In one embodiment, the memory die 900 may comprise: a three-dimensional memory array comprising an alternating stack {(132, 146), (232, 246)} of insulating layers (132, 232) and electrically conductive layers (146, 246), a two-dimensional array of memory openings 49 vertically extending through the alternating stack {(132, 146), (232, 246)}, and a two-dimensional array of memory opening fill structures 58 located in the two-dimensional array of memory openings 49 and comprising a respective vertical stack of memory elements (e.g., portions of the memory film 50) and a respective vertical semiconductor channel 60; and a two-dimensional array of contact via structures (such as the drain contact via structures 88) overlying the three-dimensional memory array and electrically connected to a respective one of the vertical semiconductor channels 60.

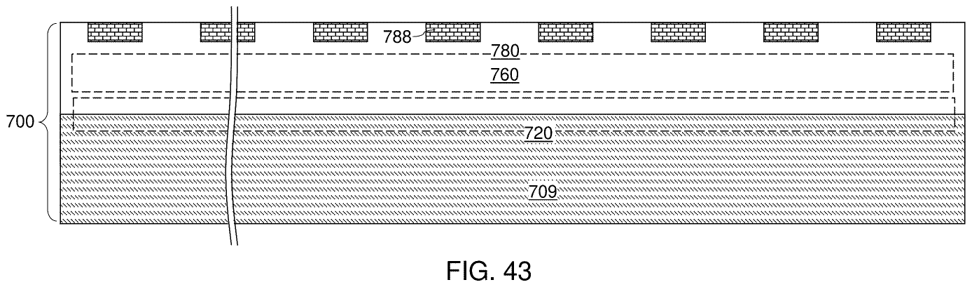

Referring to FIG. 43, a logic die 700 can be provided. The logic die 700 includes a logic-die substrate 709, a peripheral circuit 720 located on the logic-die substrate 709 and comprising logic-die semiconductor devices (such as field effect transistors), logic-die metal interconnect structures 780 embedded within logic-die dielectric material layers 760, and logic-die bonding pads 788. The peripheral circuit 720 can be configured to control operation of the memory array within the memory die 900. Specifically, the peripheral circuit 720 can be configured to drive various electrical components within the memory array including, but not limited to, the electrically conductive layers (146, 246), the drain regions 63, and a source contact structure to be subsequently formed. The peripheral circuit 720 can be configured to control operation of the vertical stack of memory elements in the memory array in the memory die 900.

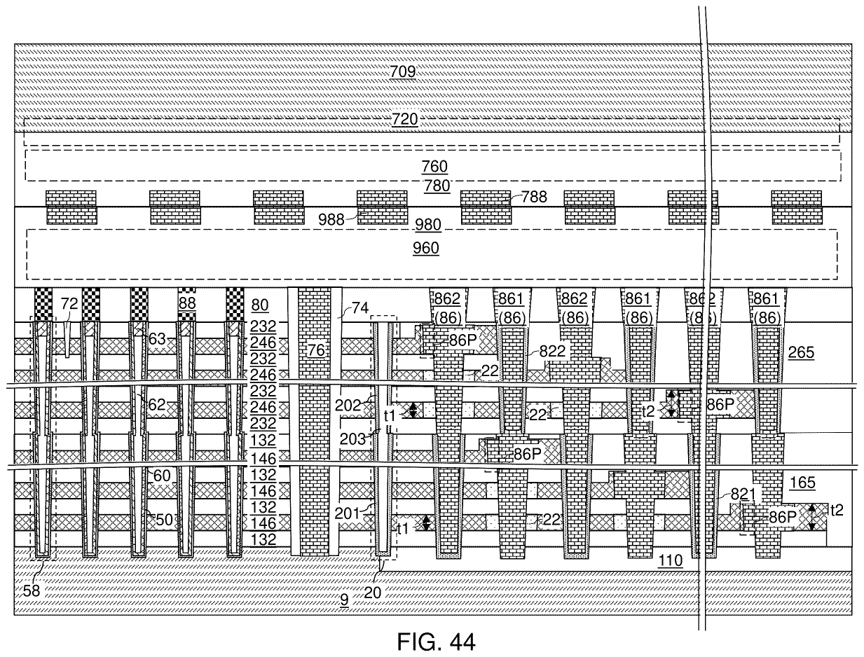

Referring to FIG. 44, the logic die 700 can be attached to the memory die 900, for example, by bonding the logic-die bonding pads 788 to the memory-die bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-wafer bonding process, or by a die-to-die bonding process. The logic-die bonding pads 788 within each logic die 700 can be bonded to the memory-die bonding pads 988 within a respective memory die 900.

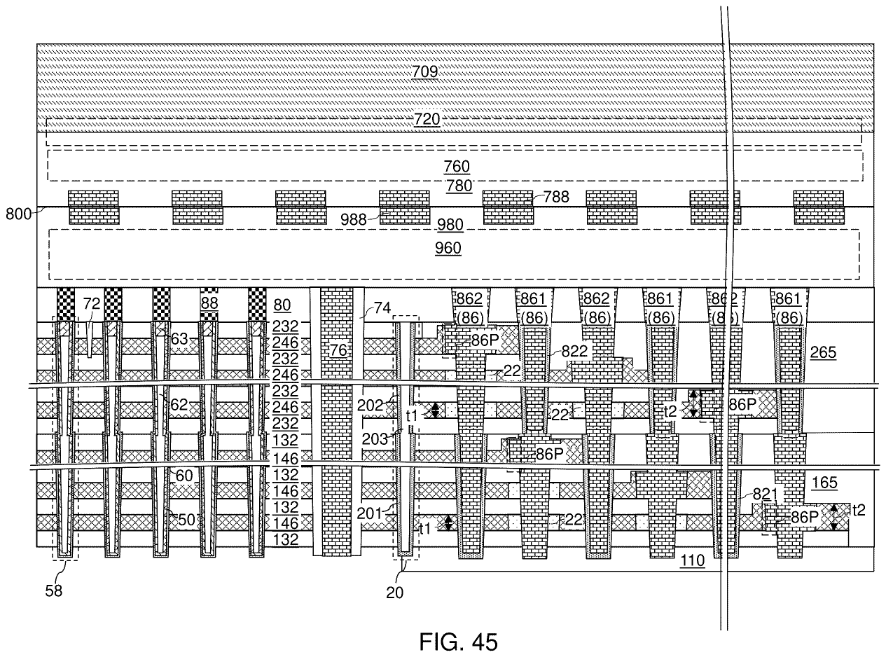

Referring to FIG. 45, the substrate 9 can be removed, for example, by grinding, polishing, cleaving, an isotropic etch process, an anisotropic etch process, and/or a combination thereof. If a chemical mechanical polishing process or an etch process is employed as a terminal step for removing the substrate 9, the bottommost first insulating layer 132 and the insulating etch-stop layer 110 may be employed as a polish stop or etch stop, respectively.

In one embodiment, at least a terminal step of at least one removal process that is employed to remove the substrate 9 may comprise a selective wet etch process that etches the material of the substrate 9 (such as a semiconductor material of the substrate 9) selectively to dielectric materials of the memory films 50. In an illustrative example, if the substrate 9 comprises silicon, the terminal step of the at least one removal process may comprise a wet etch process using hot trimethyl-2 hydroxyethyl ammonium hydroxide (“hot TMY”) or tetramethyl ammonium hydroxide (TMAH). The entirety of the substrate 9 can be removed by the selective wet etch process. Backside end surfaces of the support pillar structures 20 can be physically exposed upon removal of the substrate 9.

A sequence of wet etch steps can be performed to sequentially remove portions of the memory film 50 that are exposed on the backside of the alternating stack {(132, 146), (232, 246)}. For example, the inner blocking dielectric layer 52, the memory material layer 54, and the optional dielectric liner 56 (which may be, for example, a tunneling dielectric layer) of each memory film 50 can be removed from a region that is more distal from the bonding interface 800 between the memory die 900 and the logic die 700 than a physically exposed planar surface of the bottommost first insulating layer 132 is from the bonding interface 800. The blocking dielectric layer 52, the memory material layer 54, and the optional dielectric liner 56 (which may be, for example, a tunneling dielectric layer) of each memory film 50 can be removed from below the horizontal plane including the bottom surface of the bottommost first insulating layer 132.

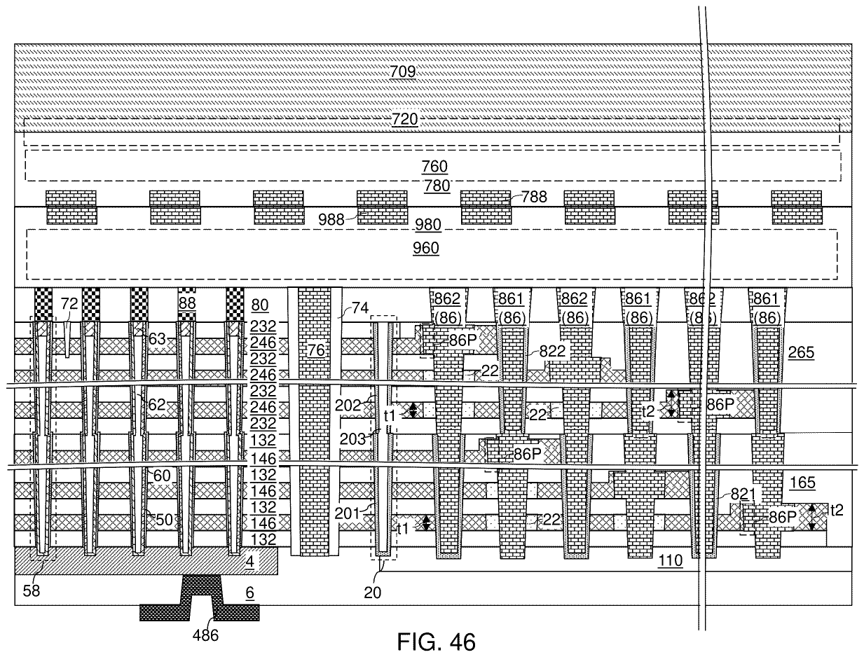

Referring to FIG. 46, source structures 4 (such as at least one heavily doped semiconductor and/or metallic source layer), a backside dielectric layer 5, and backside contact via structures 486 can be subsequently formed.

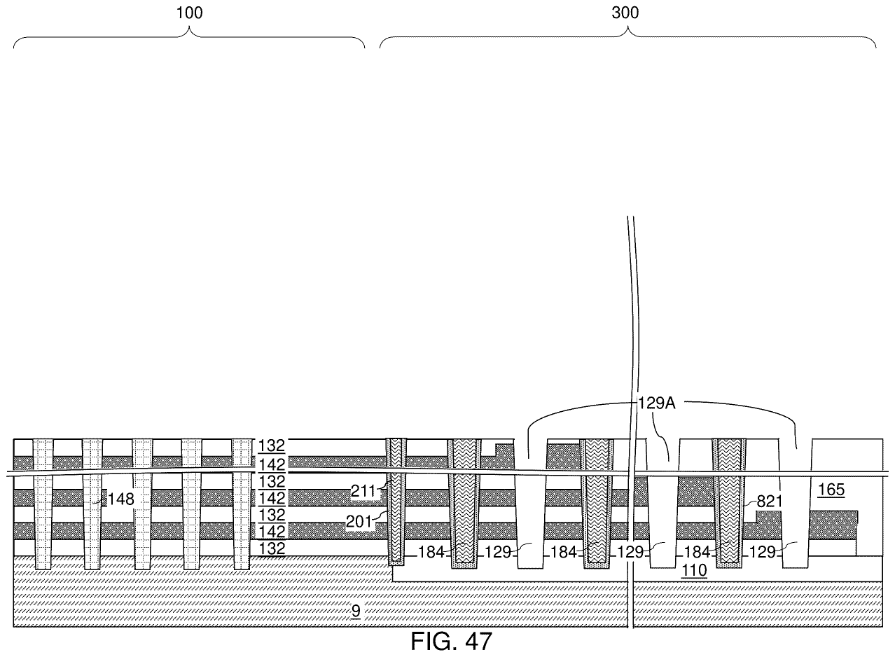

Referring to FIG. 47, a second exemplary structure according to a second embodiment of the present disclosure is illustrated. In the second embodiment, the fin-shaped annular voids (127A, 127B, 227A, 227B) are formed in both tiers at the same time instead of in separate etching steps as in the first embodiment. The second exemplary structure illustrated in FIG. 47 may be the same as the first exemplary structure illustrated in FIG. 12. In this embodiment, the first dielectric spacer 821 may comprise an insulating material that is different from the material of the first insulating layers 132 and the first retro-stepped dielectric material portion 165. For example, the first dielectric spacer 821 may comprise silicon oxycarbide.

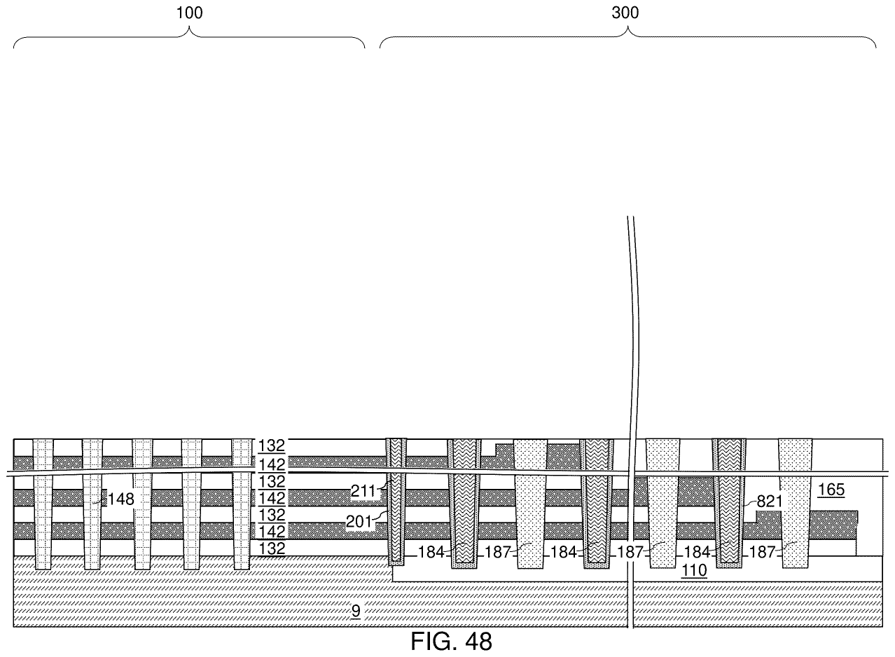

Referring to FIG. 48, a second sacrificial via fill material can be deposited in the first subset of the first-tier contact openings 129A. The second sacrificial via fill material comprises a material that may be subsequently removed selectively to the material of the first insulating layers 132. For example, the second sacrificial via fill material may comprise amorphous silicon or polysilicon. Excess portions of the second sacrificial via fill material may be removed from above the horizontal plane including the topmost surface of the first alternating stack (132, 142) by performing a planarization process, which may comprise a recess etch process or a chemical mechanical polishing process. Remaining portions of the second sacrificial via fill material that fill the first subset of the first-tier contact openings 129A comprise additional first-tier pillar-shaped sacrificial via fill material portions 187. The first-tier pillar-shaped sacrificial via fill material portions (184, 187) comprise first-type first-tier pillar-shaped sacrificial via fill material portions 184 that are formed in a second subset of the first-tier contact openings 129B and laterally surrounded by a respective first dielectric spacer 821, and second-type first-tier pillar-shaped sacrificial via fill material portions 187 that are formed in a first subset of the first-tier contact openings 129A and contacting the first insulating layers 132 and the first sacrificial material layers 142. A first-tier structure is thus formed.

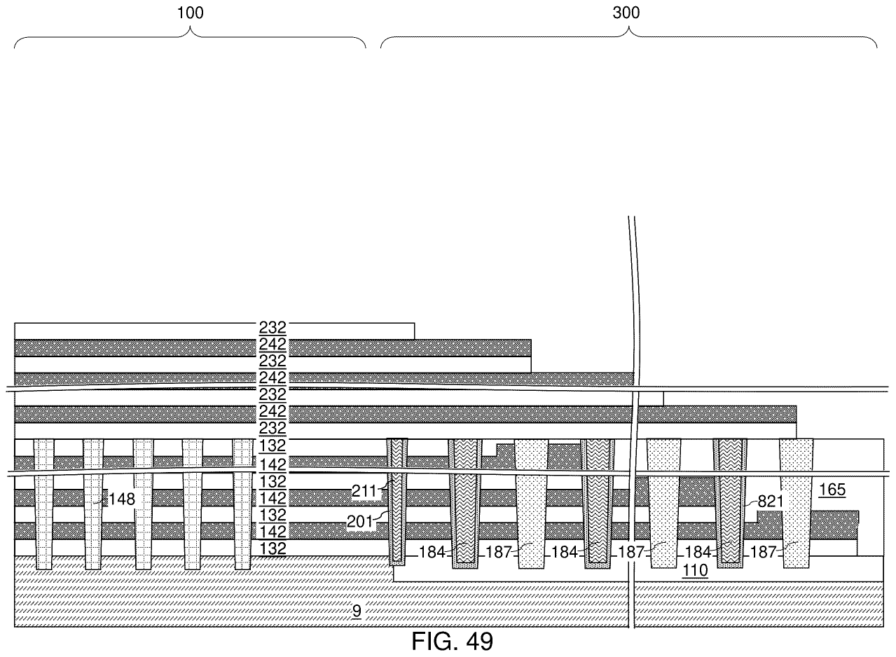

Referring to FIG. 49, the processing steps described with reference to FIG. 16 are used to form a second alternating stack of second insulating layers 232 and second sacrificial material layers 242 having second stepped surfaces.

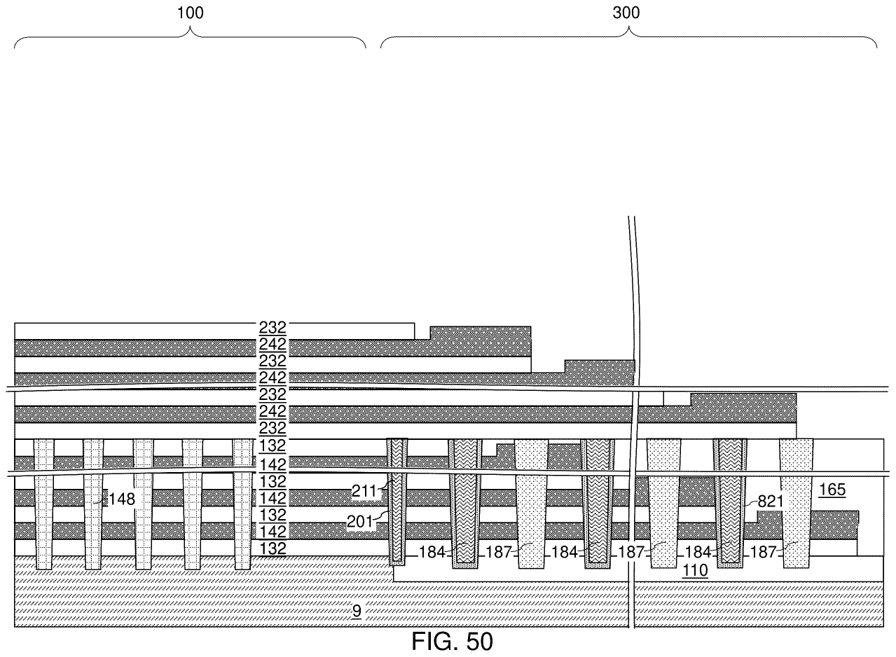

Referring to FIG. 50, the processing steps described with reference to FIGS. 3A-3C can be performed with any needed changes to locally thicken physically exposed portions of the second sacrificial material layers 242.

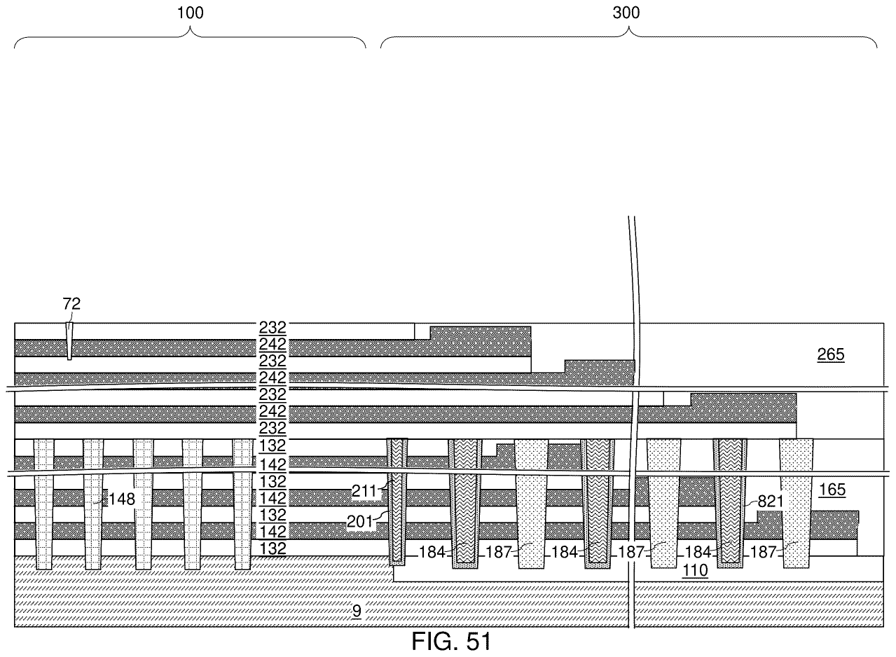

Referring to FIG. 51, the processing steps described with reference to FIG. 5 can be performed with any needed changes to form a second retro-stepped dielectric material portion 265. Optionally, drain-select-level isolation structures 72 can be formed in an upper portion of the second alternating stack (232, 242).

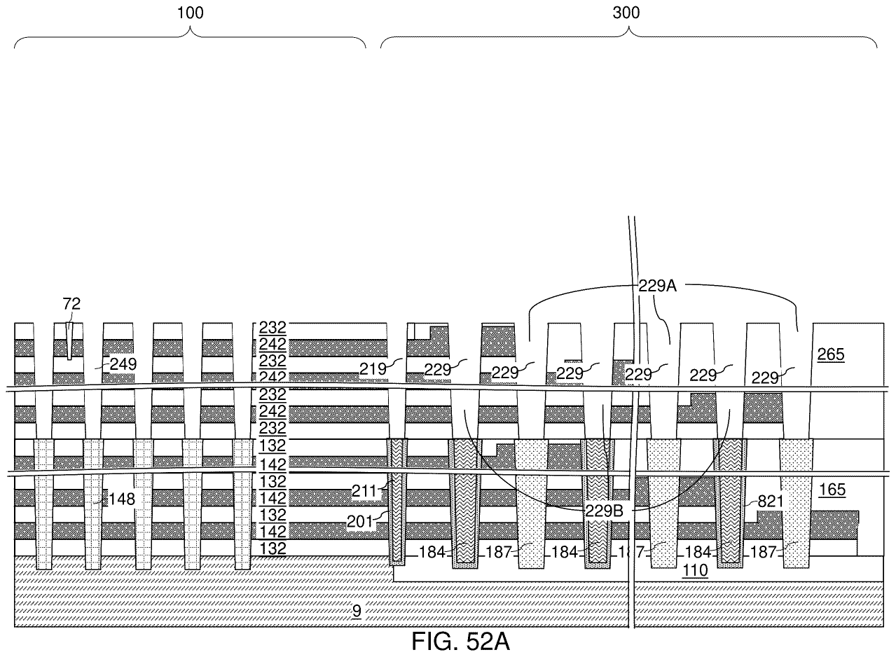

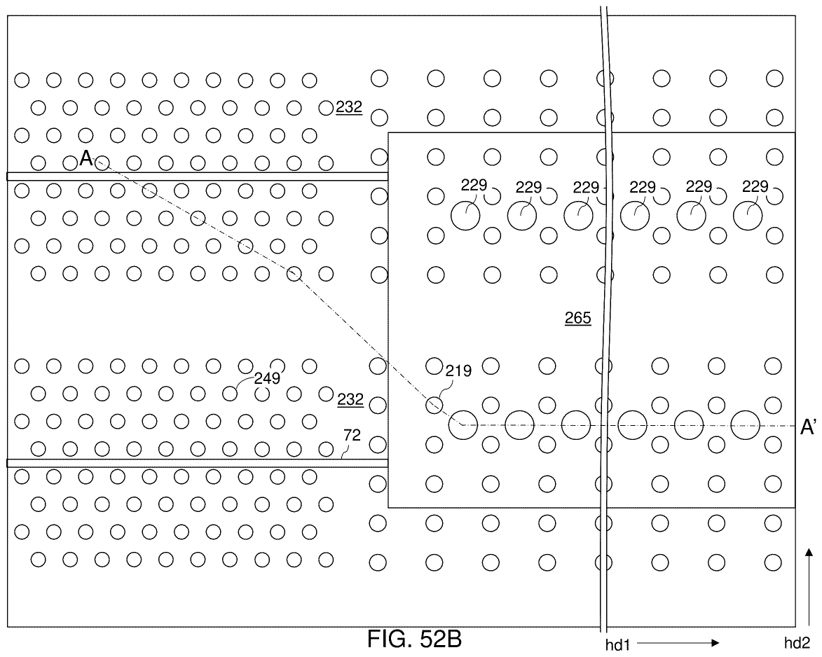

Referring to FIGS. 52A and 52B, various second-tier openings may be formed through the second alternating stack (232, 242). A photoresist layer (not shown) may be applied over the second alternating stack (232, 242), and may be lithographically patterned to form various openings therethrough. The pattern of openings in the photoresist layer may be the same as the various first-tier openings (149, 119, 129) described with reference to FIGS. 6A and 6B. The pattern of the opening in the photoresist layer can be transferred through the second alternating stack (232, 242) by a second anisotropic etch process to form the various second-tier openings concurrently. The various second-tier openings may include second-tier memory openings 249 formed in the memory array regions 100, second-tier support openings 219 formed in the contact region 300, and second-tier contact openings 229 formed in the contact region 300. Each of the second-tier memory openings 249 can be formed directly on a top surface of a first-tier sacrificial memory opening fill structure 148. Each of the second-tier support openings 219 can be formed directly on a top surface of a first-tier sacrificial support opening fill structure 118. Each of the second-tier contact opening 219 may be formed directly on a respective one of the first-tier sacrificial via fill material portions (184, 187). A first subset of the second-tier contact openings 229A may vertically extend through unthickened portions of the sacrificial material layers 242 and/or through respective vertically-extending surface segment of the second stepped surfaces such as segments of sidewalls of the second insulating layer 232 in contact with the second retro-stepped dielectric material portion 265. A second subset of the second-tier contact openings 229B may vertically extend through a center region of the thickened portion of a respective second sacrificial material layer 242.

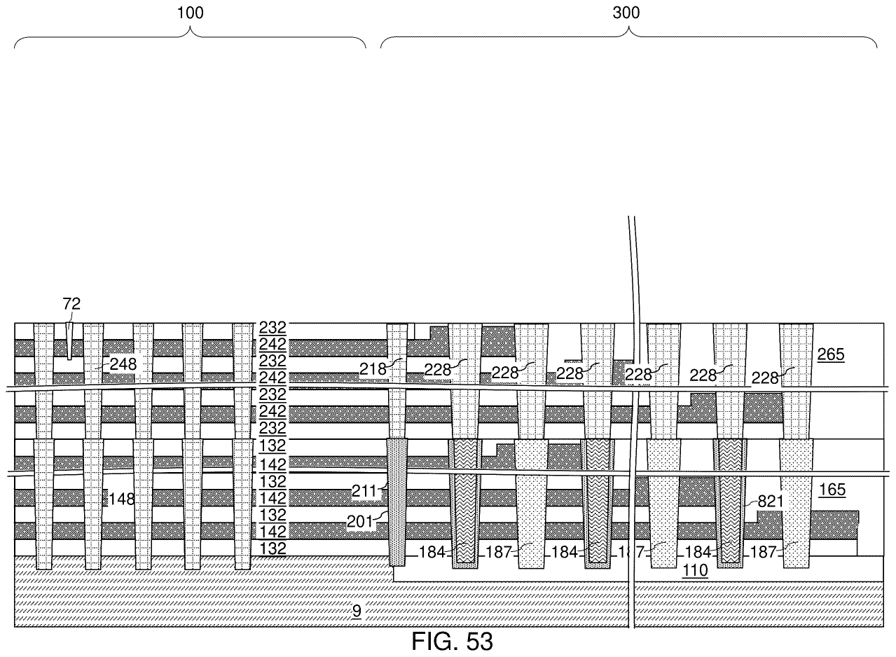

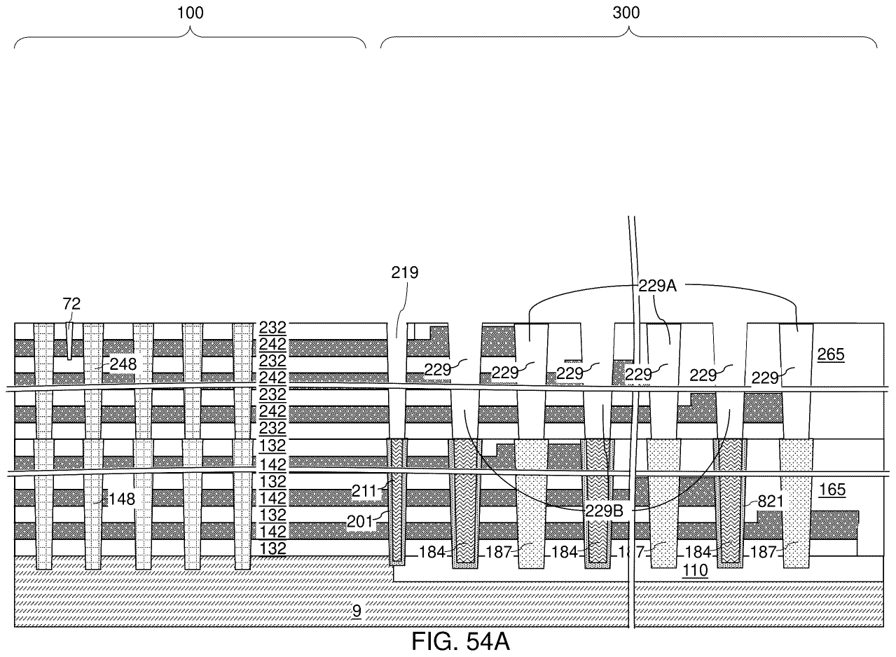

Referring to FIG. 53, a second-tier sacrificial fill material can be deposited in the second-tier openings (249, 219, 229). The second-tier sacrificial fill material includes a material that may be subsequently removed selectively to the materials of the second insulating layers 232 and the second sacrificial material layers 242. In one embodiment, the second-tier sacrificial fill material may include a semiconductor material, such as amorphous silicon, or a carbon-based material such as amorphous carbon. Optionally, a thin etch stop liner (such as a silicon oxide layer or a silicon nitride layer having a thickness in a range from 2 nm to 3 nm) may be used prior to depositing the second-tier sacrificial fill material. The second-tier sacrificial fill material may be deposited by a non-conformal deposition or a conformal deposition method. Excess portions of the second-tier sacrificial fill material can be removed from above the horizontal plane including the topmost surface of the second alternating stack (232, 242) by performing a planarization process such as a chemical mechanical polishing process or a recess etch process.

Second-tier sacrificial opening fill structures (248, 218, 228) may be formed in the various second-tier openings (249, 219, 229). The second-tier sacrificial opening fill structures (248, 218, 228) may comprise second-tier sacrificial memory opening fill structures 248, second-tier sacrificial support opening fill structures 218, and second-tier sacrificial contact opening fill structures 228.

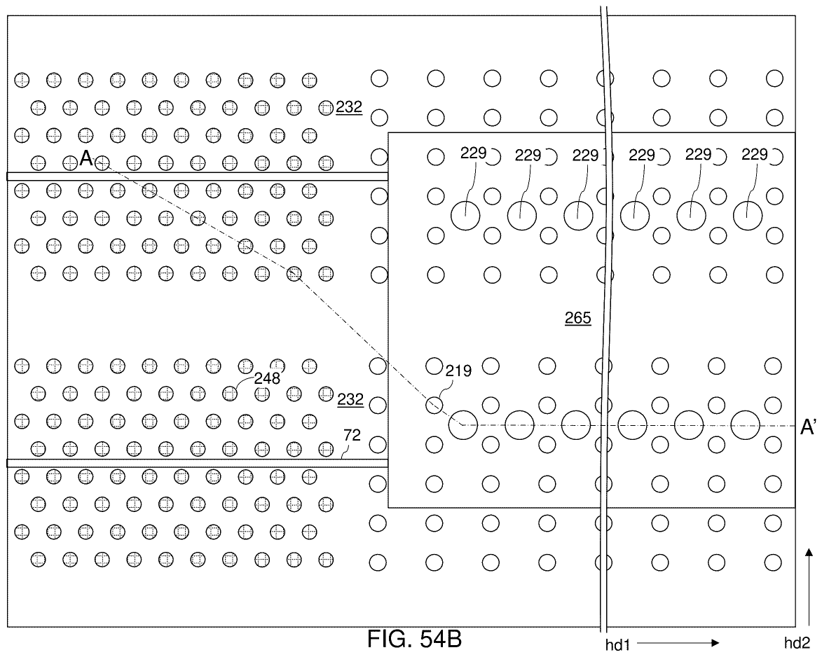

Referring to FIGS. 54A and 54B, an etch mask layer (not shown) such as a photoresist layer can be applied over the first exemplary structure, and can be patterned to cover the memory array region 100 without covering the contact region 300. The second-tier sacrificial support opening fill structures 218 and second-tier sacrificial contact opening fill structures 228 can be removed without removing the second-tier sacrificial memory opening fill structures 248. The etch mask layer can be subsequently removed. Second-tier voids are formed in the volumes from which the second-tier sacrificial support opening fill structures 218 and second-tier sacrificial contact opening fill structures 228 are removed.

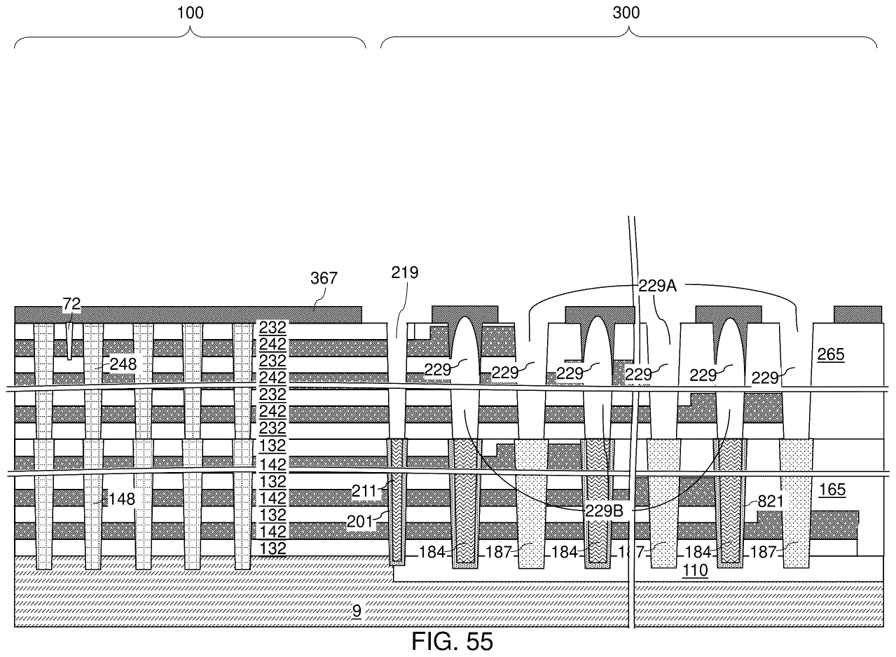

Referring to FIG. 55, masking patterns 367 can be formed, for example, by anisotropically depositing a masking material, and by patterning the deposited masking material. The masking material may comprise a hard mask material that may be subsequently removed selectively to the materials of the second insulating layers 232 and the second retro-stepped dielectric material portion 265. For example, the masking material may comprise silicon nitride. The anisotropic deposition process that deposits the masking material may comprise a directional deposition process, such as a plasma-enhanced chemical vapor deposition process. The masking material may be patterned, for example, by applying and patterning a photoresist layer over the masking material, and by performing an anisotropic etch process that etches unmasked portions of the masking material. The masking patterns 367 do not cover the second-tier support openings 219 or a first subset of the second-tier contact openings 229A that overlie a respective one of the first-tier pillar-shaped sacrificial via fill material portions 187. The masking patterns 367 cover the entirety of the memory array region 100 and a second subset of the second-tier contact openings 229B that overlie the first-tier pillar-shaped sacrificial via fill material portions 184.

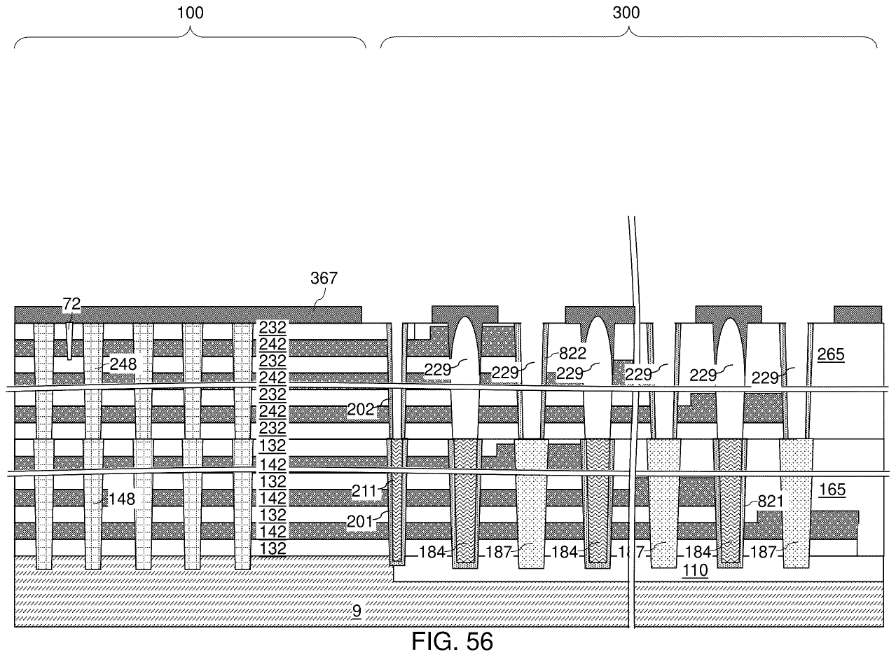

Referring to FIG. 56, a second dielectric spacer material layer can be formally deposited in peripheral regions of the first subset of the second-tier contact openings 229 and the second-tier support openings 219 and over the masking patterns 367. The second dielectric spacer material layer comprises a dielectric material that is different from the material of the second sacrificial material layers 232 and the second sacrificial material layers 242. In one embodiment, the second dielectric spacer material layer comprises silicon oxycarbide. An anisotropic etch process can be performed to remove horizontally-extending portions of the second dielectric spacer material layer. Remaining portions of the second dielectric spacer material layer that are formed in peripheral regions of the second-tier support openings 219 comprise second-tier support opening dielectric spacers 202. Remaining portions of the second dielectric spacer material layer that are formed in peripheral regions of the first subset of the second-tier contact openings 229A comprise second-tier contact opening dielectric spacers 822.

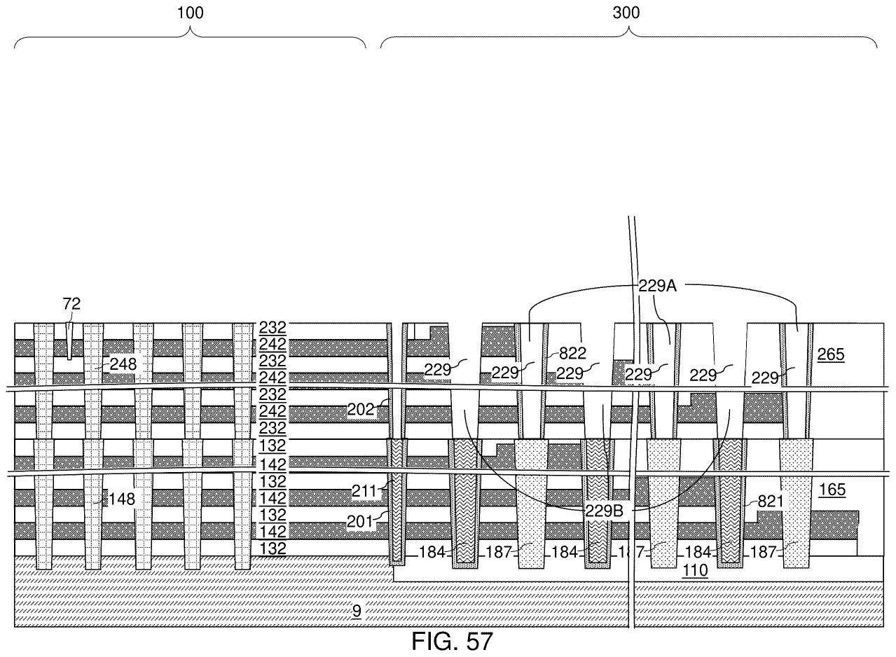

Referring to FIG. 57, an anisotropic etch process can be performed to remove the masking patterns 367 selectively to the materials of the second insulating layers 232 and the second retro-stepped dielectric material portion 265. For example, if the masking patterns 367 comprise silicon nitride and if the second insulating layers 232 and the second retro-stepped dielectric material portion 265 comprise silicon oxide, an anisotropic etch process that etches silicon nitride selectively to silicon oxide can be performed to remove the masking patterns 367. The second subset of the second-tier contact openings 229B are reopened.

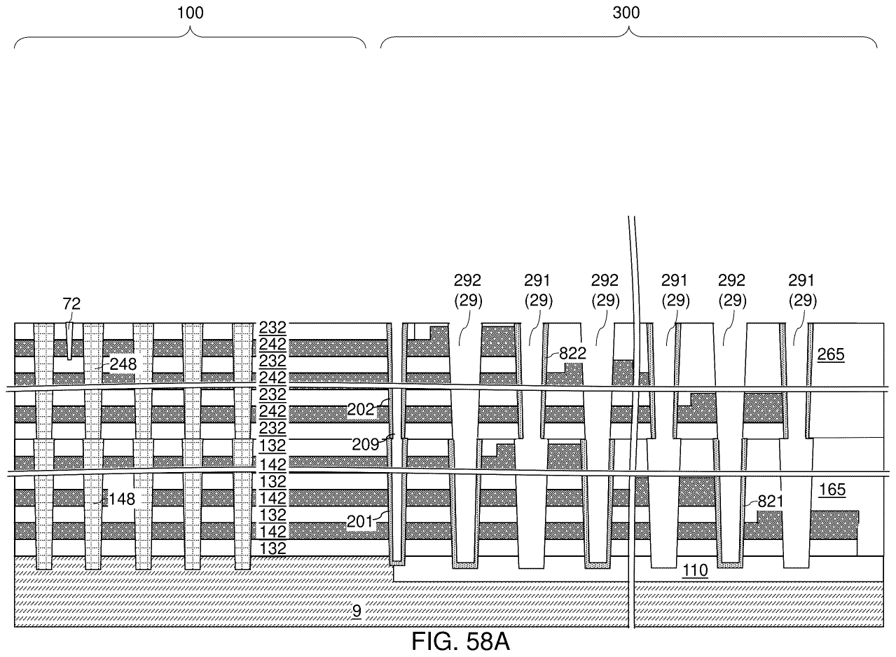

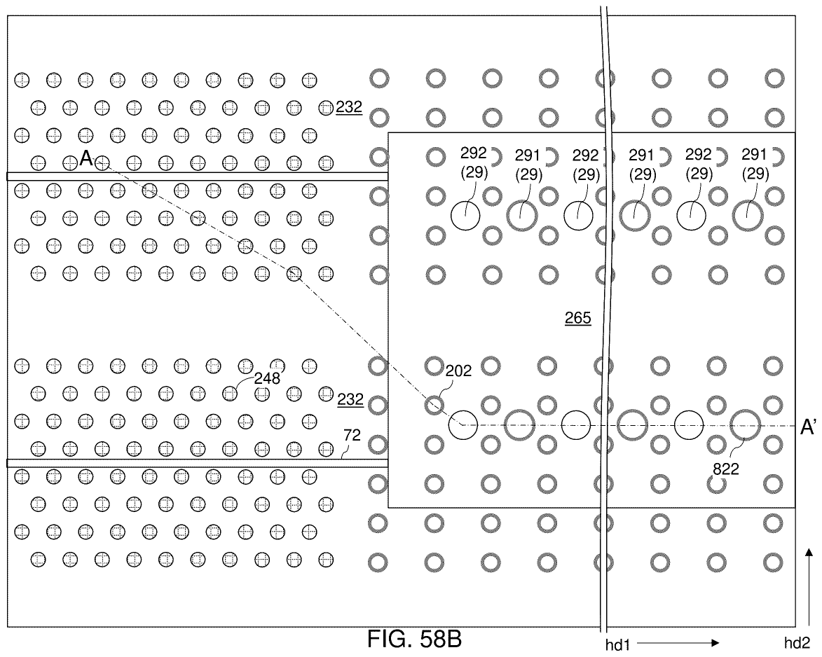

Referring to FIGS. 58A and 58B, a selective etch process can be performed to remove the first-tier sacrificial support opening fill material portions 211 and the first-tier pillar-shaped sacrificial via fill material portions (184, 187) without removing the dielectric spacers (821, 822), first-tier support opening dielectric spacers 201, second-tier support opening dielectric spacers 202, the alternating stacks {(132, 142), (232, 242)}, and the retro-stepped dielectric material portions (165, 265). For example, if the first-tier sacrificial support opening fill material portions 211 and the first-tier pillar-shaped sacrificial via fill material portions (184, 187) comprise semiconductor materials, such as amorphous silicon, a wet etch process using hot trimethyl-2 hydroxyethyl ammonium hydroxide (“hot TMY”) or tetramethyl ammonium hydroxide (TMAH) may be performed to remove the first-tier sacrificial support opening fill material portions 211 and the first-tier pillar-shaped sacrificial via fill material portions (184, 187).

Inter-tier contact via cavities 29 can be formed in the voids formed by removal of the first-tier pillar-shaped sacrificial via fill material portions (184, 187) and in the overlying voids through the second-tier structure. The inter-tier contact via cavities 29 may comprise first inter-tier contact via cavities 291 that comprise the voids formed by removal of the first-type first-tier pillar-shaped sacrificial via fill material portions 184 and overlying voids in the second-tier structure, and second inter-tier contact via cavities 292 that comprise the voids formed by removal of the second-type first-tier pillar-shaped sacrificial vial fill material portions 187 and overlying voids in the second-tier structure. The first inter-tier contact via cavities 291 each comprise a vertically adjacent pair of one of the first subset of the first-tier contact openings 129A and an overlying one of the first subset of the second-tier contact openings 229A. The second inter-tier contact via cavities 292 each comprise a vertically adjacent pair of one of the second subset of the first-tier contact openings 129B and an overlying one of the second subset of the second-tier contact openings 229B.

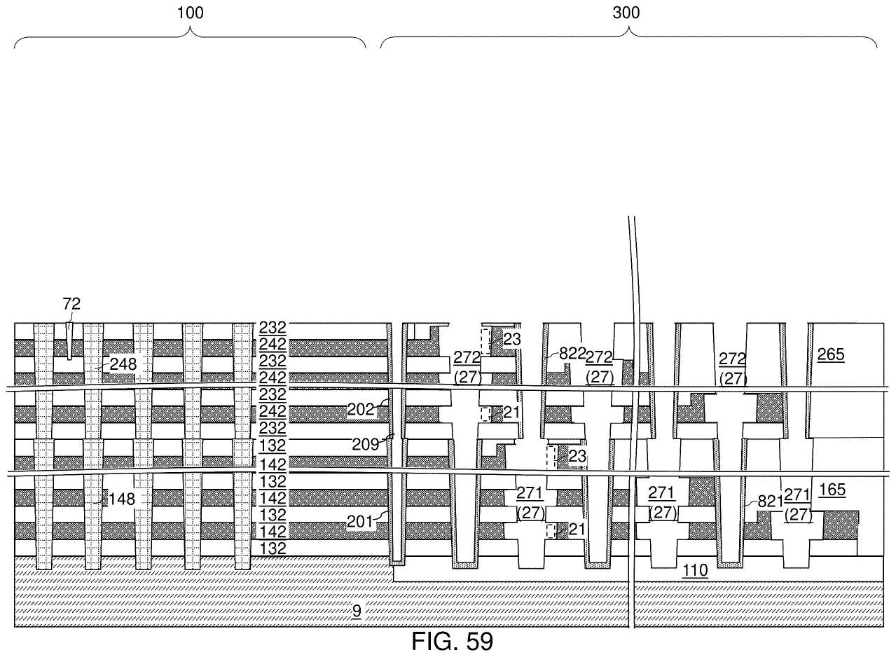

Referring to FIG. 59, an isotropic etch process can be performed to laterally recess the physically exposed sidewalls of the sacrificial material layers (142, 242) selectively to the materials of the insulating layers (132, 232) and the retro-stepped dielectric material portion (165, 265). Fin-shaped annular voids (21, 23) are formed at the levels of the first sacrificial material layers 142 around the first inter-tier contact via cavities 291. The first inter-tier contact via cavities 291 are converted into first finned contact via cavities 271. Additional fin-shaped annular voids (21, 23) are formed at the levels of the second sacrificial material layers 242 around the second inter-tier contact via cavities 292. The second inter-tier contact via cavities 292 are converted into second finned contact via cavities 272. The first finned contact via cavities 271 and the second finned contact via cavities 272 are collectively referred to as finned contact via cavities 27. The annular voids (21, 23) comprise taller annular voids 23 overlying one or more shorter annular voids 21 in a predominant portion of the finned contact via cavities 27.

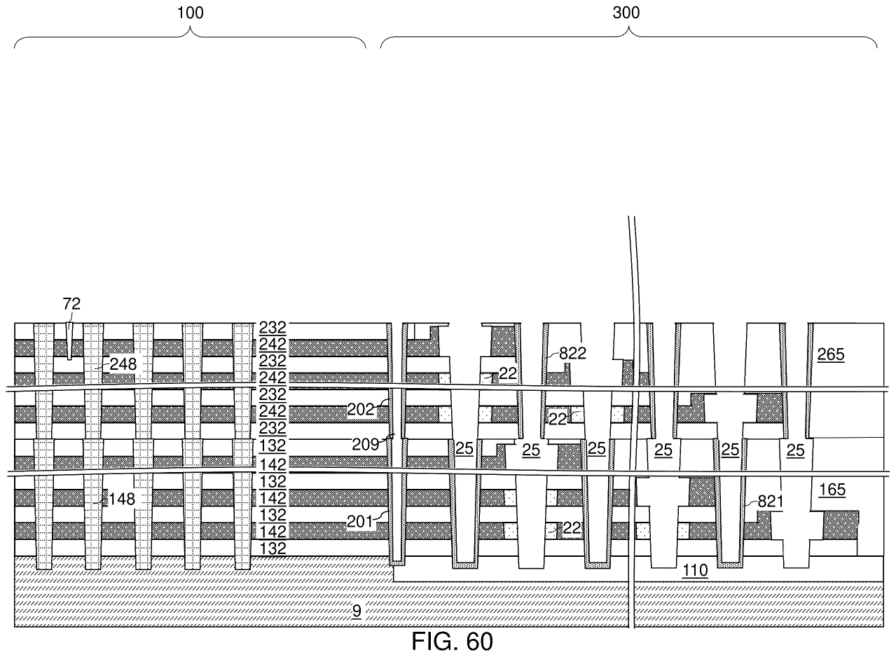

Referring to FIG. 60, an insulating spacer material layer, such as silicon oxide, can be conformally deposited in peripheral regions of the finned contact via cavities 27. The thickness of the insulating spacer material layer can be greater than one half of the thickness of unthickened portions of the sacrificial material layers (142, 242), and is less than one half of the thickness of the thickened portions of the sacrificial material layers (142, 242). The shorter first annular voids 21 having the same vertical extent as the unthickened portions of the sacrificial material layers (142, 242) are completely filled with portions of the insulating spacer material layer, while the taller second annular voids 23 having the same vertical extent as the thickened portions of the sacrificial material layers (142, 242) are only partially filled with portions of the insulating spacer material layer.

An isotropic recess etch process can be performed to isotropically etch portions of the insulating spacer material layer. The duration of the isotropic recess etch process can be selected such that the etch distance of the isotropic etch process for the material of the insulating spacer material layer is in a range from 100% to 120% of the thickness of the insulating spacer material layer. Portions of insulating spacer material layer located in the taller second annular voids 23 adjacent to the thickened portions of the first sacrificial material layers 142 can be removed. Remaining portions of the insulating spacer material layer that fill a respective shorter first annular void 21 adjacent to the unthickened portions of the sacrificial material layers 142 comprise annular insulating spacers 22. The remaining unfilled volume of each fined contact via cavity 27 is hereafter referred to as a finned contact via opening 25.

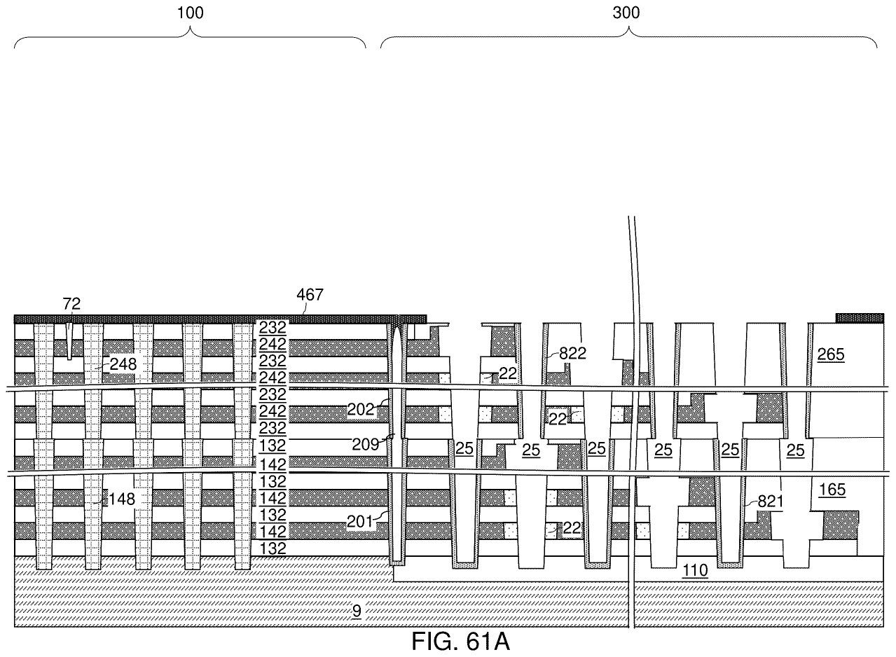

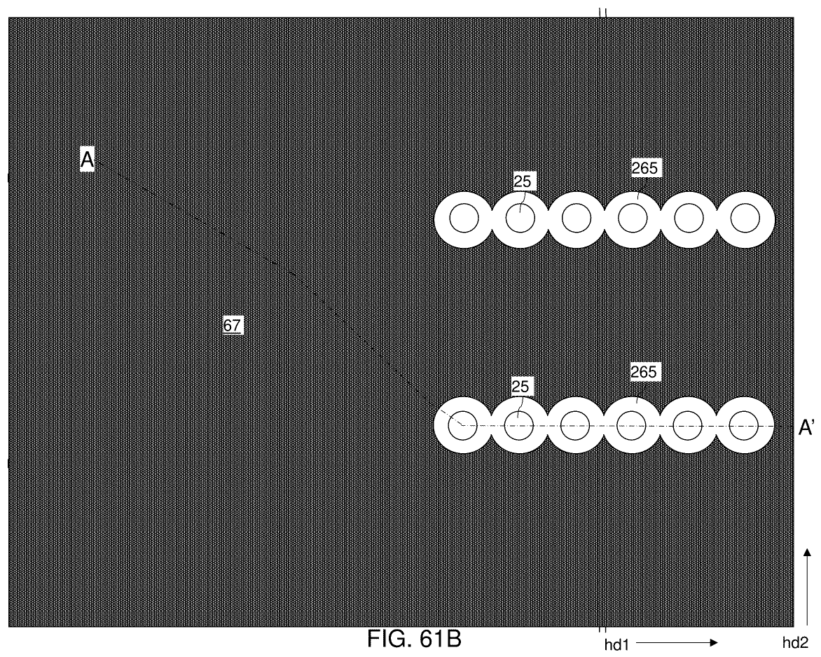

Referring to FIGS. 61A and 61B, an etch mask layer 467 can be formed, for example, by anisotropic deposition and patterning of an etch mask material, such as silicon nitride. The etch mask layer 467 may cover the memory array region 100 and areas of the support openings that contain a respective vertical stack of a first-tier support opening dielectric spacer 201 and a second-tier support opening dielectric spacer 202. A support cavity 209 may be formed within each support opening.

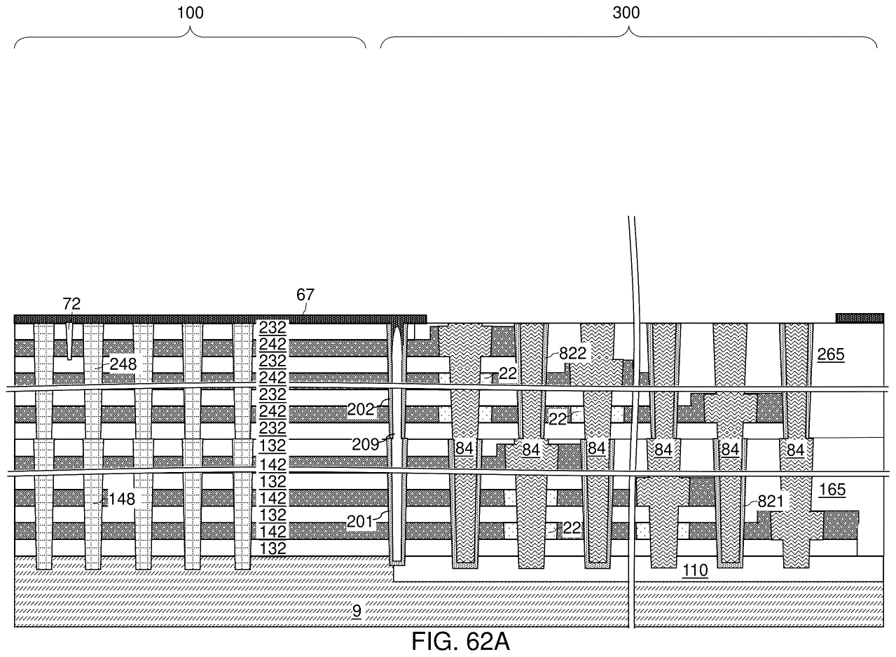

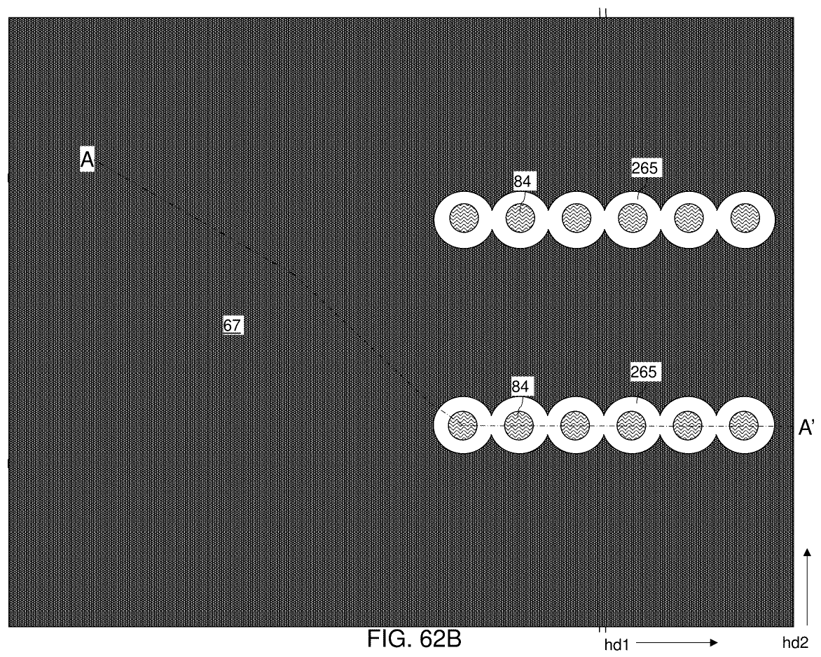

Referring to FIGS. 62A and 62B, a sacrificial via fill material can be deposited in the finned contact via opening 25. The sacrificial via fill material comprises a material that may be subsequently removed selectively to the materials of the dielectric spacers (821, 822), the insulating layers (132, 232), and the retro-stepped dielectric material portions (165, 265). For example, the sacrificial via fill material may comprise amorphous silicon or polysilicon. Excess portions of the sacrificial via fill material may be removed from above the horizontal plane including the topmost surface of the second alternating stack (232, 242) by performing a planarization process, which may comprise a recess etch process or a chemical mechanical polishing process. Remaining portions of the sacrificial via fill material that fill the finned contact via openings 25 comprise sacrificial contact via fill structures 84.

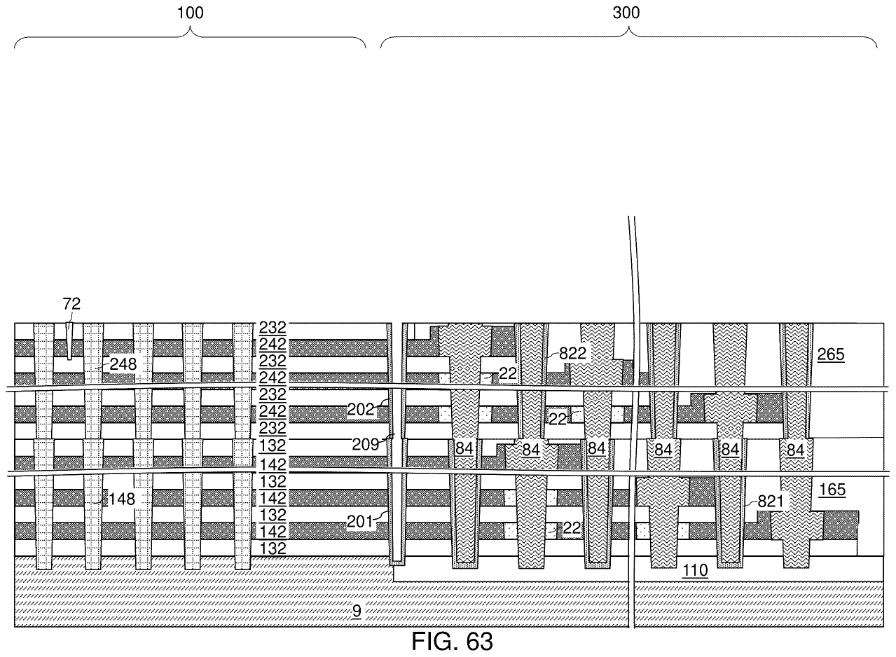

Referring to FIG. 63, the etch mask layer 467 can be removed selectively to the materials of the second insulating layers 232, the retro-stepped dielectric material portions (165, 265), and the sacrificial contact via fill structures 84 by performing a selective etch process such as an anisotropic etch process. For example, if the etch mask layer 467 comprises silicon nitride, an anisotropic etch process that etches silicon nitride selectively to silicon oxide and silicon oxycarbide may be performed.

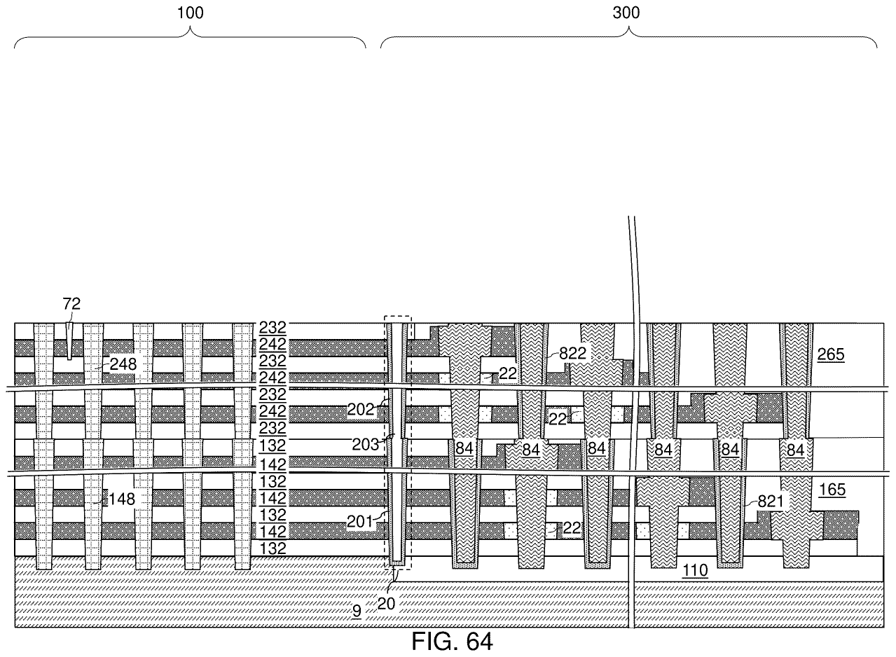

Referring to FIG. 64, a dielectric fill material, such as silicon oxide can be deposited in the support cavities 209. A planarization process can be performed to remove excess portions of the dielectric fill material from above the horizontal plane including the topmost surface of the second alternating stack (232, 242). Each contiguous set of a first-tier support opening dielectric spacer 201, a second-tier support opening dielectric spacers 202, and a dielectric fill material 203 constitutes a support pillar structure 20. Alternatively, the steps illustrated in FIGS. 61A-61B, 63 and 64 may be omitted, and each of the support pillar structures 20 may comprise the first-tier support opening dielectric spacer 201, the second-tier support opening dielectric spacers 202, and the sacrificial contact via fill structure 84 formed during the deposition step shown in FIGS. 62A-62B.

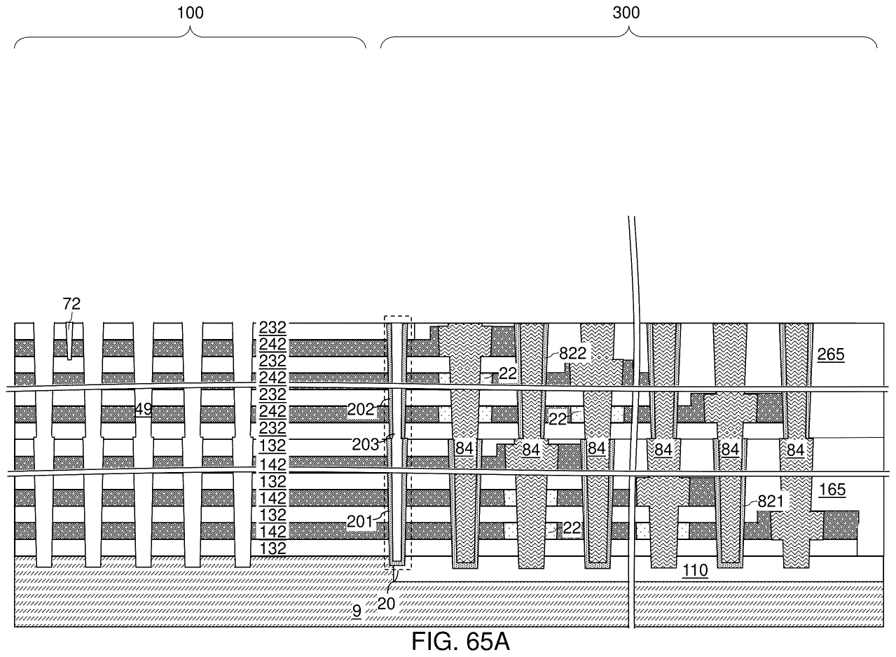

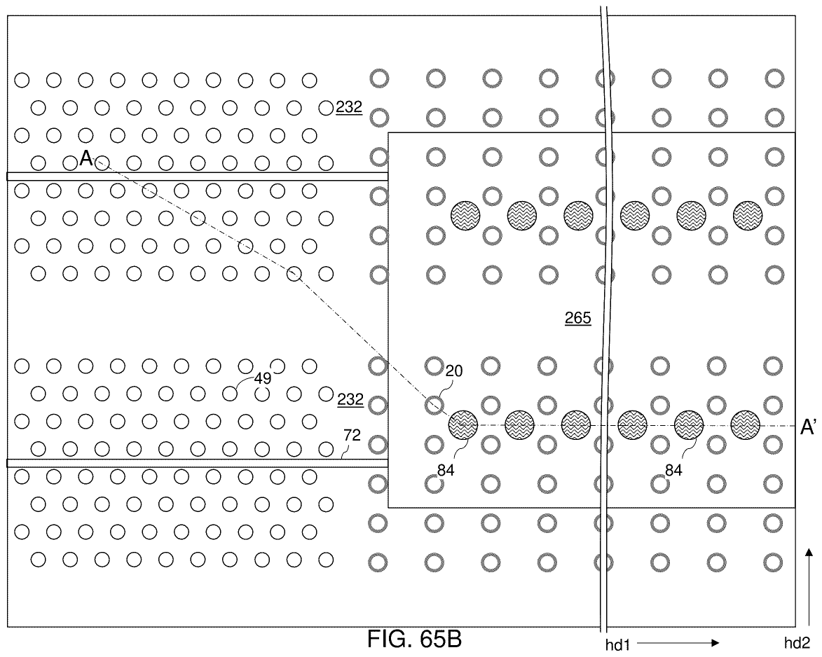

Referring to FIGS. 65A and 65B, the processing steps described with reference to FIGS. 32A and 32B can be performed to form memory openings 49.

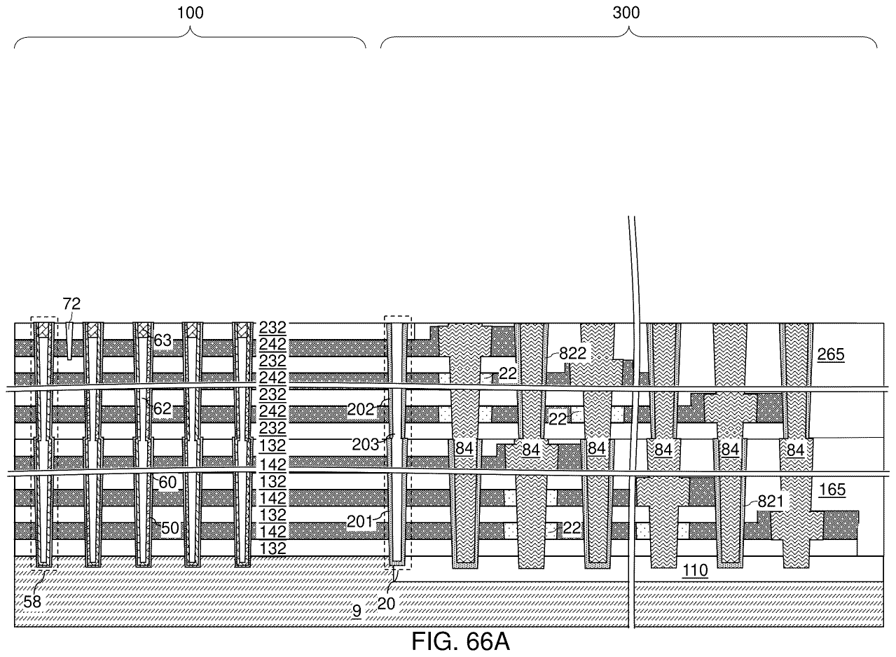

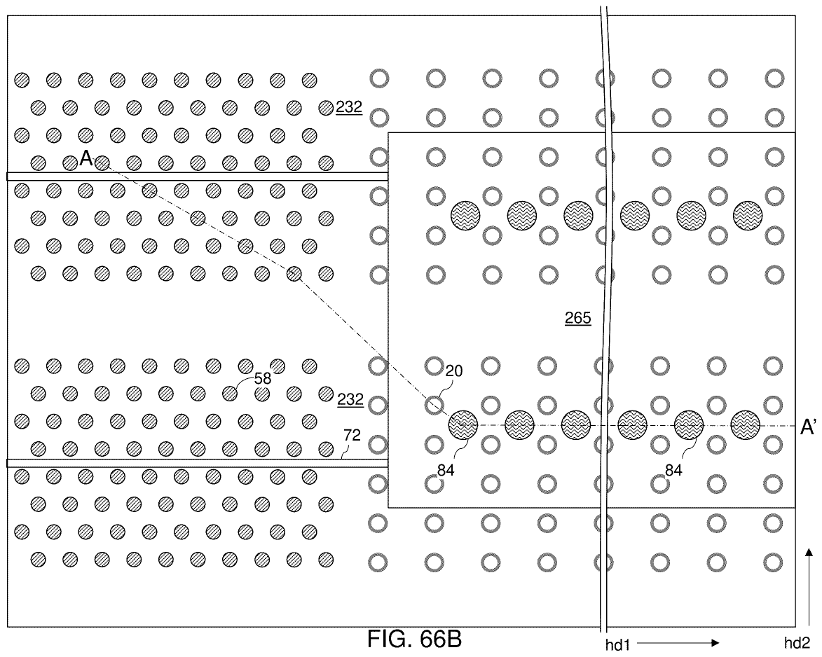

Referring to FIGS. 66A and 66B, the processing steps described with reference to FIGS. 33A-33E can be performed to form memory opening fill structures 58 in the memory openings 49.

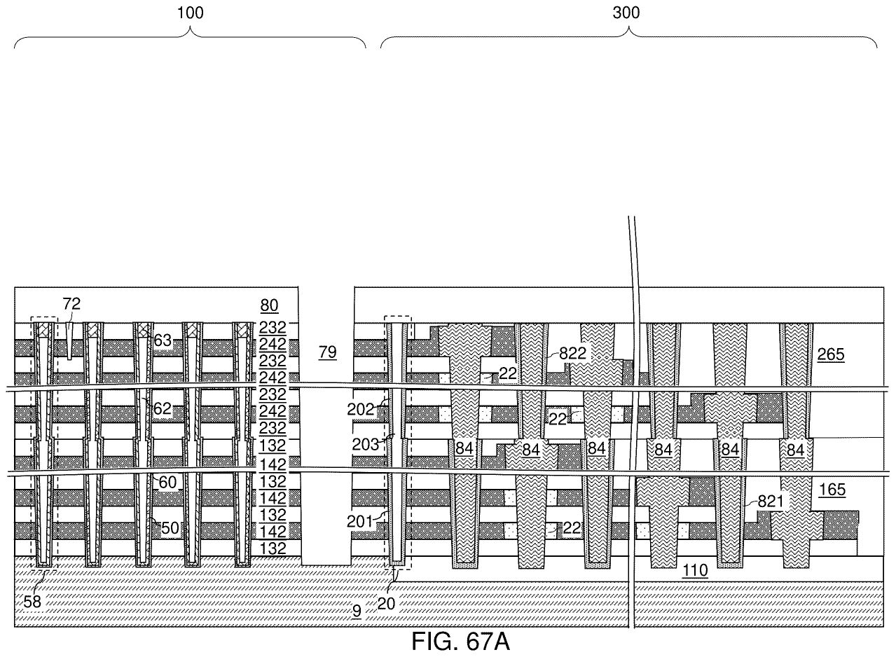

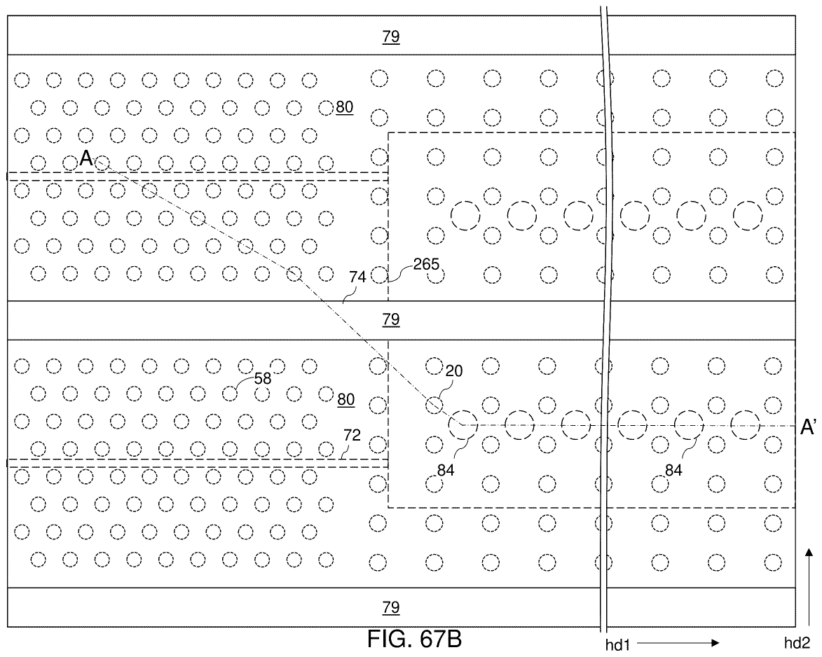

Referring to FIGS. 67A and 67B, the processing steps described with reference to FIGS. 35A and 35B can be performed to form a contact-level dielectric layer 80 and lateral isolation trenches 79.

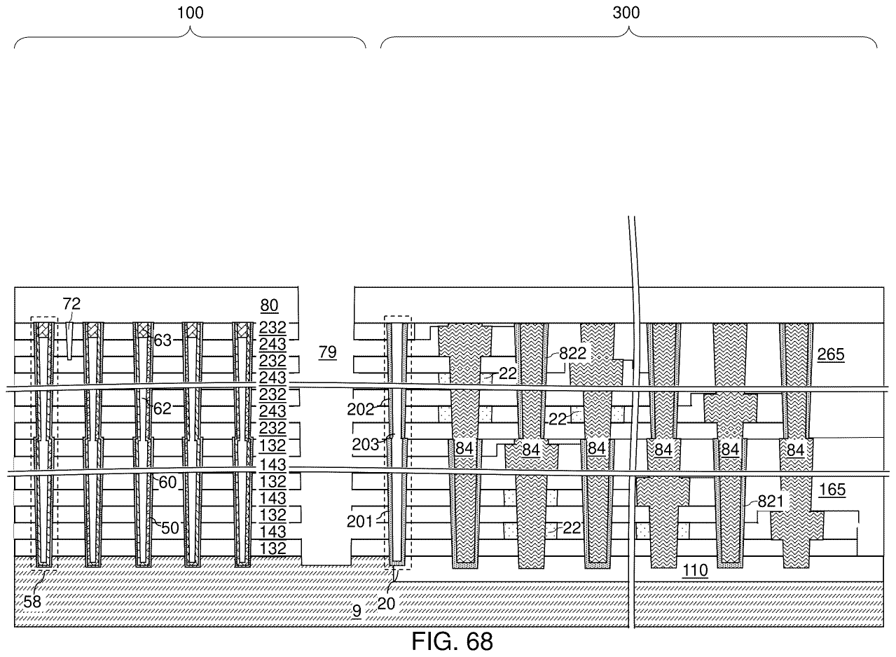

Referring to FIG. 68, the processing steps described with reference to FIG. 36 can be performed to form lateral recesses (143, 243).

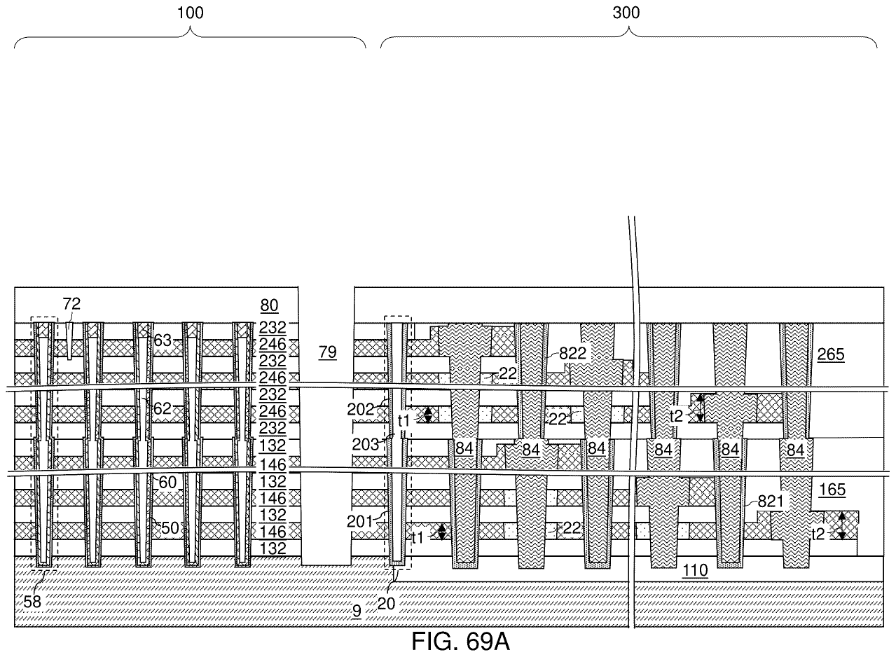

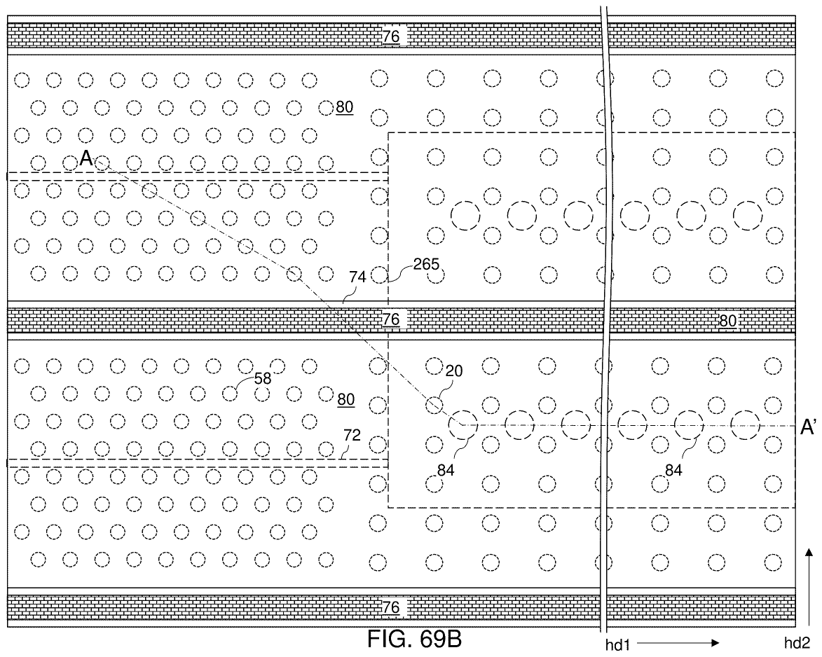

Referring to FIGS. 69A and 69B, the processing steps described with reference to FIGS. 37A and 37B can be performed to form an optional outer blocking dielectric layer and electrically conductive layers (146, 246).

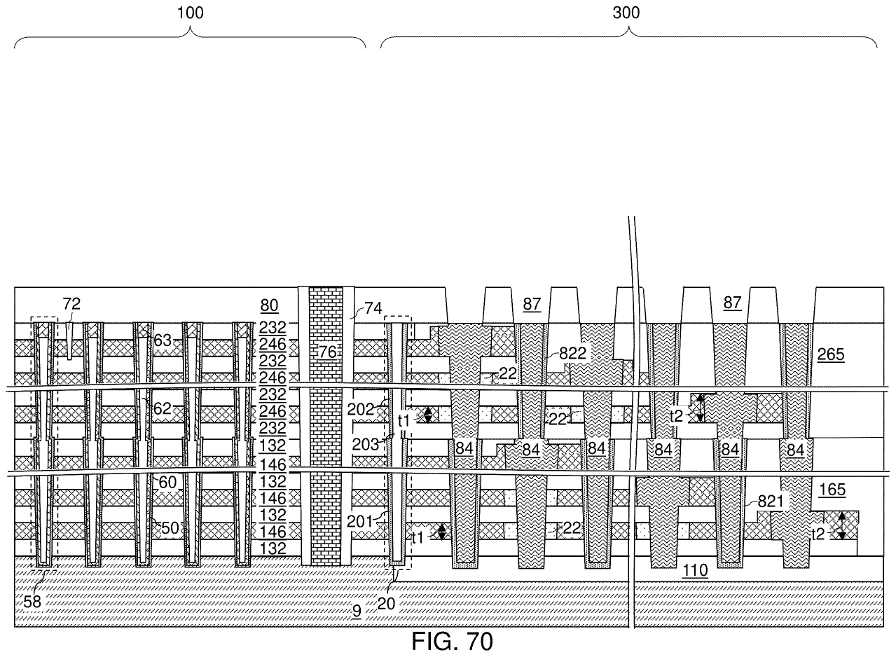

Referring to FIG. 70, the processing steps described with reference to FIG. 38 can be performed to form lateral isolation trench fill structures (74, 76). Subsequently, contact through-holes 87 can be formed through the contact-level dielectric layer 80 over the sacrificial contact via fill structures 84.

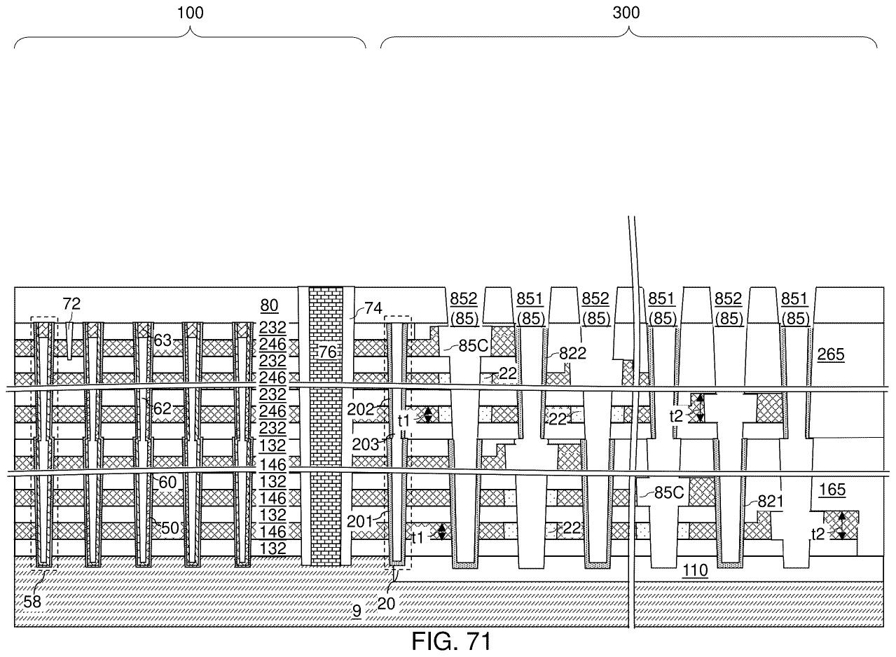

Referring to FIG. 71, a selective etch process can be performed to remove the sacrificial contact via fill structures 84 without removing the second dielectric spacers 822, the first dielectric spacers 821, the contact-level dielectric layer 80, the insulating layers (132, 232), the electrically conductive layers (146, 246), or the retro-stepped dielectric material portions (165, 265). Through-stack contact via cavities 85 are formed in the volumes from which the sacrificial contact via fill structures 84 are removed. The through-stack contact via cavities 85 comprise first-type through-stack contact via cavities 851 vertically extending through a portion of a first electrically conductive layer 146 having the second thickness t2, and second-type through-stack contact via cavities 852 vertically extending through a portion of a second electrically conductive layer 246 having the second thickness t2.

Each of the through-stack contact via cavities 85 comprises a respective first cylindrical cavity portion that vertically extends through the first alternating stack (132, 146), a second cylindrical cavity portion that vertically extends through the second alternating stack (232, 246), and a respective annular cavity portion 85C that laterally protrudes outward from the first cylindrical cavity portion or from the second cylindrical cavity portion. A cylindrical surface of a respective first electrically conductive layer 146 is physically exposed around the annular cavity portion 85C of each first-type through-stack contact via cavity 851. A cylindrical surface of a respective second electrically conductive layer 246 is physically exposed around the annular cavity portion 85C of each second-type through-stack contact via cavity 852.

A predominant fraction of the first-type through-stack contact via cavities 851 may be laterally surrounded by a respective set of at least one first annular insulating spacer 22 located at levels of a respective subset of the first electrically conductive layers 146. Each of the first-type through-stack via cavities 851 may be laterally surrounded by a respective second dielectric spacer 822, which can be a tubular dielectric spacer having a tubular configuration and vertically extending from a bottommost surface of the second-tier structure to a topmost surface of the second-tier structure. A predominant fraction of the second-type through-stack contact via cavities 852 may be laterally surrounded by a respective set of at least one second annular insulating spacer 22 located at levels of a respective subset of the second electrically conductive layers 246. Each of the second-type through-stack via cavities 852 may be laterally surrounded by a respective first dielectric spacer 821, which can be a tubular dielectric spacer having a tubular configuration and vertically extending from a bottommost surface of the first-tier structure to a topmost surface of the first-tier structure.

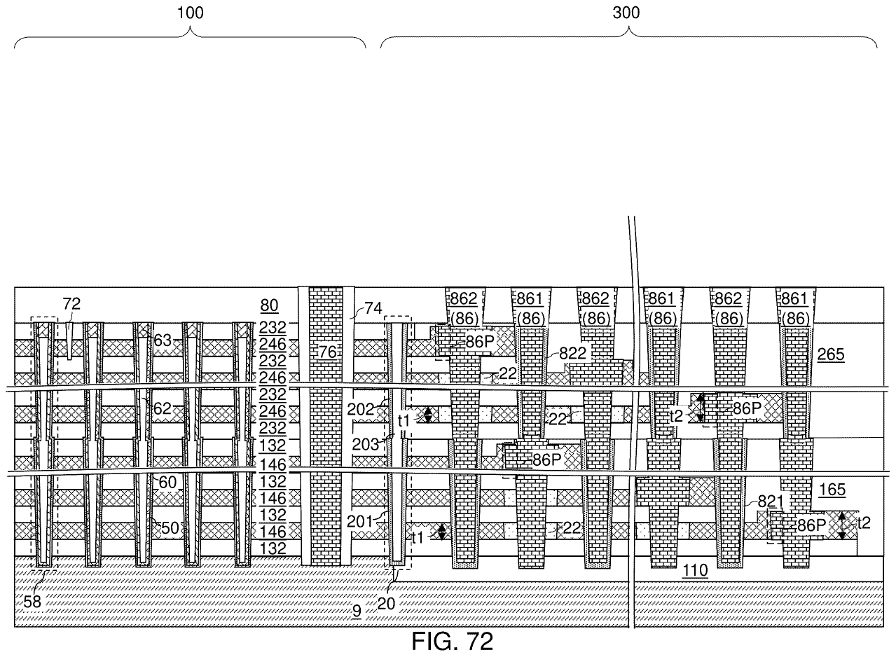

Referring to FIG. 72, the processing steps described with reference to FIG. 40 can be performed to form a through-stack contact via structure 86 in each of the through-stack contact via cavities 85. The through-stack contact via structures 86 comprise first through-stack contact via structures 861 that are formed in the first-type through-stack contact via cavities 851, and second through-stack contact via structures 862 that are formed in the second-type through-stack contact via cavities 852. Each first through-stack contact via structure 861 comprises a respective lateral protrusion portion 86P that contacts a respective cylindrical sidewall of a respective one of the first electrically conductive layers 146. Each second through-stack contact via structure 862 comprises a respective lateral protrusion portion 86P contacts a respective cylindrical sidewall of a respective one of the second electrically conductive layer 246.

Each first through-stack contact via structure 861 vertically extends at least from a first horizontal plane including a topmost surface of the second alternating stack (232, 246) and at least to a second horizontal plane including a bottommost surface of the first alternating stack (132, 146), and contacts a respective one of the first electrically conductive layers 146. A plurality of first through-stack contact via structures 861 can be formed on the inner cylindrical sidewall(s) of a set of at least one annular insulating spacer 22. Each first through-stack contact via structure 861 can be formed through the second retro-stepped dielectric material portion 265 and the first retro-stepped dielectric material portion 165.

The second exemplary structure comprises a first alternating stack (132, 146) of first insulating layers 132 and first electrically conductive layers 146 and having first stepped surfaces in a contact region 300; a second alternating stack (232, 246) of second insulating layers 232 and second electrically conductive layers 246 and having second stepped surfaces in the contact region 300; and a first through-stack contact via structure 861 vertically extending through the second stepped surfaces and a subset of the second electrically conductive layers 246 and contacting one of the first electrically conductive layers 146. In one embodiment, the first through-stack contact via structure 861 is electrically isolated from each of the second electrically conductive layers 246. In one embodiment, the first through-stack contact via structure 861 is electrically isolated from all of the first electrically conductive layers 146 except said one of the first electrically conductive layers 146. In one embodiment, the first through-stack contact via structure 861 is in contact with a cylindrical sidewall of said one of the first electrically conductive layers 146. In one embodiment, the first through-stack contact via structure 861 vertically extends at least from a horizontal plane including a topmost surface of the second alternating stack (232, 242) to a horizontal plane including a bottommost surface of the first alternating stack (132, 146).

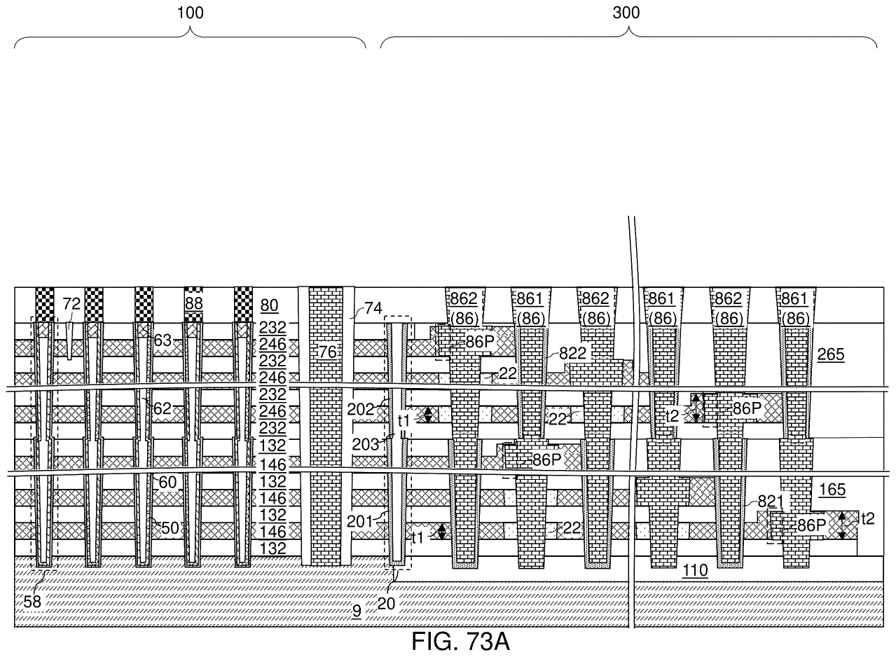

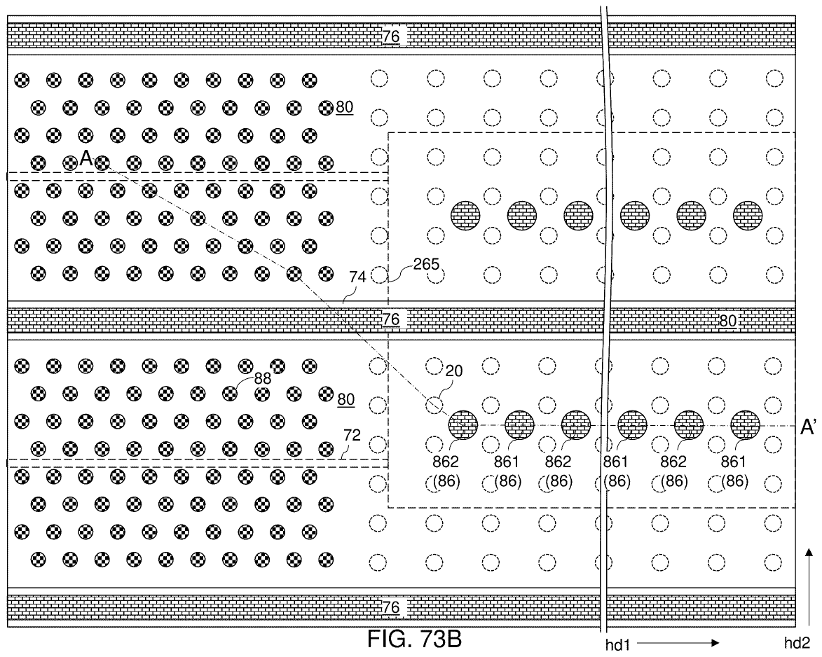

Referring to FIGS. 73A and 73B, the processing steps described with reference to FIGS. 41A and 41B can be performed to form drain contact via structures 88.

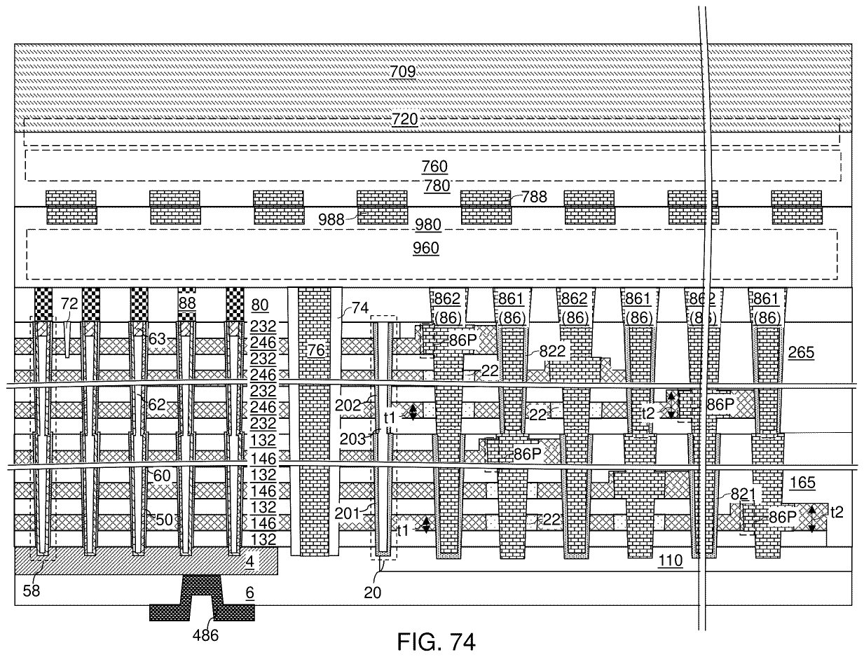

Referring to FIG. 74, the processing steps described with reference to FIGS. 42-46 may be subsequently performed.

Referring to all drawings and according to various embodiments of the present disclosure, a device structure is provided, which comprises: a first alternating stack (132, 146) of first insulating layers 132 and first electrically conductive layers 146 having first stepped surfaces in a contact region 300; a second alternating stack (232, 246) of second insulating layers 232 and second electrically conductive layers 246 having second stepped surfaces in the contact region 300; and a first through-stack contact via structure 861 vertically extending through at least a portion of the second stepped surfaces and a subset of the second electrically conductive layers 246 and contacting a sidewall of one of the first electrically conductive layers 146.

In one embodiment, the first through-stack contact via structure 861 is electrically isolated from each of the second electrically conductive layers 246. In one embodiment, the first through-stack contact via structure 861 is electrically isolated from all of the first electrically conductive layers 146 except said one of the first electrically conductive layers 146. In one embodiment, the sidewall is a cylindrical sidewall of said one of the first electrically conductive layers 146. In one embodiment, the first through-stack contact via structure 861 vertically extends at least from a horizontal plane including a topmost surface of the second alternating stack (232, 246) to a horizontal plane including a bottommost surface of the first alternating stack (132, 146).

In one embodiment, the device structure comprises: memory openings 49 vertically extending through each layer within the first alternating stack (132, 146) and the second alternating stack (232, 246) and located in a memory array region 100 that is laterally offset from the contact region 300; and memory opening fill structures 58 located in the memory openings 49, wherein each of the memory opening fill structures 58 comprises a respective vertical stack of memory elements (such as portions of a memory material layer 54 located at the levels of the electrically conductive layers (146, 246)) and a vertical semiconductor channel 60. In one embodiment, said one of the first electrically conductive layers 146 has a first thickness t1 in the memory array region 100 and in an area of the contact region 300 that is distal from the first through-stack contact via structure 861; and said one of the first electrically conductive layers 146 has a second thickness that is greater than the first thickness in proximity to the first through-stack contact via structure 861.

In one embodiment, the first through-stack contact via structure 861 comprises: a first pillar portion that vertically extends from a horizontal plane including a topmost surface of the first alternating stack (132, 146) at least to a horizontal plane including a bottommost surface of the first alternating stack (132, 146); and an annular lateral protrusion portion 86P that laterally protrudes from the first pillar portion and contacts the sidewall of said one of the first electrically conductive layers 146. In one embodiment, the annular lateral protrusion portion 86P has a uniform vertical extent that is the same as the second thickness t2.

In one embodiment, the first through-stack contact via structure 861 further comprises a second pillar portion that vertically extends from the horizontal plane including the bottommost surface of the second alternating stack (232, 246) at least to a horizontal plane including a topmost surface of the second alternating stack (232, 246). In one embodiment, the first through-stack contact via structure 861 comprises an annular surface having an inner periphery that coincides with a top periphery of the first pillar portion and having an outer periphery that coincides with a bottom periphery of the second pillar portion.

In one embodiment, an entirety of an outer sidewall of the second pillar portion is in contact with a tubular insulating spacer (such as a second insulating spacer 822) that extends vertically from the horizontal plane including the topmost surface of the first alternating stack (132, 146) to the horizontal plane including the topmost surface of the second alternating stack (232, 246). In the second embodiment, the tubular insulating spacer comprises silicon oxycarbide.

In one embodiment, the first through-stack contact via structure 861 vertically extends through at least one first electrically conductive layer 146 that underlies said one of the first electrically conductive layers 146; and each of the at least one first electrically conductive layer 146 is electrically isolated from the first through-stack contact via structure 861 by a respective annular insulating spacer 22.

In one embodiment, the device structure comprises a second through-stack contact via structure 862 vertically extending through the first stepped surfaces and a subset of the first electrically conductive layers 146 and contacting one of the second electrically conductive layers 246. In one embodiment, the second stepped surfaces have an areal overlap with the first stepped surfaces in a plan view along a vertical direction.

In various embodiments, the second-tier staircase overlies the first-tier staircase, and the first through-stack contact via structures 861 vertically extend through the second-tier staircase to contact a respective one of the first electrically conductive layers 146. This reduces the lateral dimension of the staircase regions (i.e., the contact regions 300) and increases the device density per area of the substrate.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A device structure, comprising:
a first alternating stack of first insulating layers and first electrically conductive layers having first stepped surfaces in a contact region;
a second alternating stack of second insulating layers and second electrically conductive layers having second stepped surfaces in the contact region; and
a first through-stack contact via structure vertically extending through at least a portion of the second stepped surfaces and a subset of the second electrically conductive layers and contacting a sidewall of one of the first electrically conductive layers.

2. The device structure of claim 1, wherein:
the first through-stack contact via structure is electrically isolated from each of the second electrically conductive layers;
the first through-stack contact via structure is electrically isolated from all of the first electrically conductive layers except said one of the first electrically conductive layers; and
the sidewall comprises a cylindrical sidewall.

3. The device structure of claim 1, wherein the first through-stack contact via structure vertically extends at least from a horizontal plane including a topmost surface of the second alternating stack to a horizontal plane including a bottommost surface of the first alternating stack.

4. The device structure of claim 1, further comprising:
memory openings vertically extending through each layer within the first alternating stack and the second alternating stack and located in a memory array region that is laterally offset from the contact region; and
memory opening fill structures located in the memory openings, wherein each of the memory opening fill structures comprises a respective vertical stack of memory elements and a vertical semiconductor channel.

5. The device structure of claim 4, wherein:
said one of the first electrically conductive layers has a first thickness in the memory array region and in an area of the contact region that is distal from the first through-stack contact via structure; and
said one of the first electrically conductive layers has a second thickness that is greater than the first thickness in proximity to the first through-stack contact via structure.

6. The device structure of claim 5, wherein the first through-stack contact via structure comprises:
a first pillar portion that vertically extends from a horizontal plane including a topmost surface of the first alternating stack at least to a horizontal plane including a bottommost surface of the first alternating stack; and
an annular lateral protrusion portion that laterally protrudes from the first pillar portion and contacts the sidewall of said one of the first electrically conductive layers, wherein the annular lateral protrusion portion has a uniform vertical extent that is the same as the second thickness.

7. The device structure of claim 6, wherein:
the first through-stack contact via structure further comprises a second pillar portion that vertically extends from the horizontal plane including a bottommost surface of the second alternating stack at least to a horizontal plane including a topmost surface of the second alternating stack;
the first through-stack contact via structure comprises an annular surface having an inner periphery that coincides with a top periphery of the first pillar portion and having an outer periphery that coincides with a bottom periphery of the second pillar portion; and
an entirety of an outer sidewall of the second pillar portion is in contact with a tubular insulating spacer that extends vertically from the horizontal plane including the topmost surface of the first alternating stack to the horizontal plane including the topmost surface of the second alternating stack.

8. The device structure of claim 7, wherein the tubular insulating spacer comprises silicon oxycarbide.

9. The device structure of claim 1, wherein:
the first through-stack contact via structure vertically extends through at least one first electrically conductive layer that underlies said one of the first electrically conductive layers; and
each of the at least one first electrically conductive layer is electrically isolated from the first through-stack contact via structure by a respective annular insulating spacer.

10. The device structure of claim 1, further comprising a second through-stack contact via structure vertically extending through at least a portion of the first stepped surfaces and a subset of the second electrically conductive layers and contacting one of the second electrically conductive layers.

11. The device structure of claim 1, wherein the second stepped surfaces have an areal overlap with the first stepped surfaces in a plan view along a vertical direction.

12. A device structure, comprising:
a first alternating stack of first insulating layers and first electrically conductive layers having first stepped surfaces in a contact region;
a second alternating stack of second insulating layers and second electrically conductive layers second stepped surfaces in the contact region;
a first through-stack contact via structure vertically extending through at least a portion of the second stepped surfaces and a subset of the second electrically conductive layers and contacting one of the first electrically conductive layers; and
a second through-stack contact via structure vertically extending through at least a portion of the first stepped surfaces and a subset of the second electrically conductive layers and contacting one of the second electrically conductive layers.

13. The device structure of claim 12, wherein the second stepped surfaces have an areal overlap with the first stepped surfaces in a plan view along a vertical direction.

14. The device structure of claim 12, further comprising:
memory openings vertically extending through each layer within the first alternating stack and the second alternating stack and located in a memory array region that is laterally offset from the contact region; and
memory opening fill structures located in the memory openings, wherein each of the memory opening fill structures comprises a respective vertical stack of memory elements and a vertical semiconductor channel.

15. The device structure of claim 12, wherein:
the first through-stack contact via structure is electrically isolated from each of the second electrically conductive layers; and
the first through-stack contact via structure is electrically isolated from all of the first electrically conductive layers except said one of the first electrically conductive layers.

16. A method of forming a device structure, comprising:
forming a first alternating stack of first insulating layers and first sacrificial material layers over a substrate;
forming first stepped surfaces by patterning the first alternating stack in a contact region;
forming a second alternating stack of second insulating layers and second sacrificial material layers over the first alternating stack;
forming second stepped surfaces by patterning the second alternating stack in the contact region such that the second stepped surfaces have an areal overlap with the first stepped surfaces in a plan view along a vertical direction;
replacing the first sacrificial material layers and the second sacrificial material layers with first electrically conductive layers and second electrically conductive layers, respectively; and
forming a first through-stack contact via structure, wherein the first through-stack contact via structure vertically extends at least from a first horizontal plane including a topmost surface of the second alternating stack and at least to a second horizontal plane including a bottommost surface of the first alternating stack, and contacts one of the first electrically conductive layers.

17. The method of claim 16, wherein:
the first through-stack contact via structure contacts a sidewall of said one of the first electrically conductive layers;
one of the first sacrificial material layers is replaced with said one of the first electrically conductive layers;
said one of the first sacrificial material layers overlies an underlying first sacrificial material layer which is a subset of the first sacrificial material layers prior to replacement with said one of the first electrically conductive layers;
the method further comprises forming an annular insulating spacer in a peripheral region of an opening through the underlying first sacrificial material layer prior to replacement with said one of the first electrically conductive layers; and
the first through-stack contact via structure is formed on an inner cylindrical sidewall of the annular insulating spacer.

18. The method of claim 16, further comprising:
forming a first retro-stepped dielectric material portion over the first stepped surfaces, wherein the second alternating stack is formed over the first retro-stepped dielectric material portion; and
forming a second retro-stepped dielectric material portion over the second stepped surfaces, wherein the first through-stack contact via structure is formed through the second retro-stepped dielectric material portion and the first retro-stepped dielectric material portion.

19. The method of claim 18, further comprising:
forming a finned sacrificial via fill material portion through the first retro-stepped dielectric material portion and the first alternating stack;
forming a second-tier via cavity over the finned sacrificial via fill material portion;
forming a first-tier void by removing the finned sacrificial via fill material portion; and
forming the first through-stack contact via structure within volumes of the first-tier void and the second-tier via cavity.

20. The method of claim 19, wherein:
at least one underlying first sacrificial material layer underlies said one of the first sacrificial material layers; and
the method further comprises forming at least one annular insulating spacer within the at least one underlying first sacrificial material layer, and forming a tubular insulating spacer in a peripheral region of the second-tier via cavity.
